(19) United States
(12) Patent Application Publication
(10) Pub. No.: US 2025/0072212 A1
(43) Pub. Date: Feb. 27, 2025

(54) ELECTRONIC DEVICE

(71) Applicant: SEMICONDUCTOR ENERGY LABORATORY CO., LTD., Atsugi-shi, Kanagawa-ken (JP)

(72) Inventors: Daiki NAKAMURA, Atsugi-shi, Kanagawa (JP); Hisao IKEDA, Zama, Kanagawa (JP); Ryo HATSUMI, Hadano, Kanagawa (JP); Takeya HIROSE, Atsugi-shi, Kanagawa (JP); Yosuke TSUKAMOTO, Atsugi-shi, Kanagawa (JP)

(21) Appl. No.: 18/723,662

(22) PCT Filed: Dec. 15, 2022
(86) PCT No.: PCT/IB2022/062261

§ 371 Date: Jun. 24, 2024

(30) Foreign Application Priority Data
Dec. 29, 2021 (JP) 2021-215436

(51) Int. Cl. H10K 59/121; H10K 59/35

(52) U.S. Cl. CPC H10K 59/121; H10K 59/353

(57) ABSTRACT

An electronic device with low power consumption is provided. The electronic device includes a first display device and a second display device. The first display device includes a first display portion, and the second display device includes a second display portion. A plurality of first pixels are arranged in the first display portion, and a plurality of second pixels are arranged in the second display portion. The first display device overlaps with the second display device. The second display portion is provided to surround at least part of the first display portion in a plan view. The area occupied by each of the first pixels is smaller than the area occupied by each of the second pixels.

### TECHNICAL FIELD

One embodiment of the present invention relates to an electronic device. One embodiment of the present invention relates to a wearable electronic device including a display apparatus.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof.

### BACKGROUND ART

In recent years, HMD (Head Mounted Display)-type electronic devices suitable for applications such as virtual reality (VR) and augmented reality (AR) have been widely used. HMDs are capable of displaying an image showing 360-degree view of the user in accordance with the motion of the user's head or the user's gaze or operation; thus, the user can have a high sense of immersion and a high realistic sensation.

When the pixel density of the HMD is higher, an HMD can display a higher-resolution image and the user is less likely to see a pixel. Accordingly, the user of the HMD is less likely to feel graininess, so that the user can have a high sense of immersion and a realistic sensation. On the other hand, when the pixel density of the HMD is increased, the area occupied by the display portion of the HMD is difficult to increase; thus, for example, displaying an image showing 360-degree view of the user is difficult in some cases.

Patent Document 1 discloses a display device including a first display, a second display having a lower pixel density than the first display, and an optical combiner. In the case of this display device, the user can see an image when light emitted from the first display and reflected by the optical combiner and light emitted from the second display and transmitted through the optical combiner enter the eyes of the user of the display device. The first display displays a first image seen at the center of the visual field of the display device of the user and its vicinity, and the second display displays a second image displayed around the first image. In the display device disclosed in Patent Document 1, the pixel density of the second display is lower than the pixel density of the first display, whereby the area occupied by the whole display portion can be increased without making the user of the display device feel a decrease in the display quality as compared with the case where the pixel density of the second display is equal to the pixel density of the first display.

### REFERENCE

### Patent Document

[Patent Document 1] United States Patent Application Publication No. 2020/0033613

### SUMMARY OF THE INVENTION

### Problems to be Solved by the Invention

In the structure disclosed in Patent Document 1, light emitted from the first display and transmitted through the optical combiner and light emitted from the second display and reflected by the optical combiner are lost. When the luminance of light emitted from the first display and the second display is increased to cover the loss, the power consumption of the first display and the second display is increased.

An object of one embodiment of the present invention is to provide an electronic device with low power consumption. Another object of one embodiment of the present invention is to provide an electronic device that allows the user to see an image with high luminance. Another object of one embodiment of the present invention is to provide an electronic device including a display device that displays a high-quality image. Another object of one embodiment of the present invention is to provide an electronic device including a display device capable of high-speed driving. Another object of one embodiment of the present invention is to provide a small electronic device. Another object of one embodiment of the present invention is to provide a highly reliable electronic device. Another object of one embodiment of the present invention is to provide a novel electronic device.

Note that the description of these objects does not preclude the existence of other objects. Note that one embodiment of the present invention does not need to achieve all of these objects. Note that objects other than these can be derived from the descriptions of the specification, the drawings, the claims, and the like.

### Means for Solving the Problems

One embodiment of the present invention is an electronic device including a first display device and a second display device. The first display device includes a first display portion. The second display device includes a second display portion. A plurality of first pixels are arranged in the first display portion. A plurality of second pixels are arranged in the second display portion. The first display device overlaps with the second display device. The second display portion is provided to surround at least part of the first display portion in a plan view. An area occupied by each of the first pixels is smaller than an area occupied by each of the second pixels.

Another embodiment of the present invention is an electronic device including a first display device and a second display device. The first display device includes a first substrate, a first display portion over the first substrate, and a second substrate over the first display portion. The second display device includes a third substrate, a second display portion over the third substrate, and a fourth substrate over the second display portion. A plurality of first pixels are arranged in the first display portion. A plurality of second pixels are arranged in the second display portion. The second substrate overlaps with the third substrate. The second substrate, the third substrate, and the fourth substrate transmit light emitted from the first pixel. The second display portion is provided to surround at least part of the first display portion in a plan view. An area occupied by each of the first pixels is smaller than an area occupied by each of the second pixels.

Alternatively, in the above embodiment, the first substrate may be a semiconductor substrate.

Alternatively, in the above embodiment, the thickness of the third substrate may be smaller than the thickness of the first substrate.

Alternatively, in any of the above embodiments, the third substrate may have flexibility.

Alternatively, in any of the above embodiments, an adhesive layer may be provided between the second substrate and the third substrate.

Alternatively, in any of the above embodiments, the second display portion may include a region not overlapping with the first display portion.

Alternatively, in any of the above embodiments, the second display device may include a third display portion, the third display portion may overlap with the first display portion, and the third display portion may transmit light emitted from the first pixel.

Alternatively, in any of the above embodiments, the electronic device includes a communication circuit, a control circuit, a first source driver circuit, and a second source driver circuit. The first source driver circuit is electrically connected to a first pixel. The second source driver circuit is electrically connected to a second pixel. The communication circuit has a function of receiving image data. The control circuit has a function of generating a first data representing luminance of light emitted from the first pixel and a second data representing luminance of light emitted from the second pixel based on the image data, and supplying the first data to the first source driver circuit and the second data to the second source driver circuit.

Alternatively, in any of the above embodiments, the first pixel includes a first light-emitting element. The second pixel includes a second light-emitting element. The first light-emitting element includes a first pixel electrode and a first EL layer over the first pixel electrode. The first EL layer covers an end portion of the first pixel electrode. The second light-emitting element includes a second pixel electrode and a second EL layer over the second pixel electrode. An insulating layer covering an end portion of the second pixel electrode is provided between the second pixel electrode and the second EL layer.

### Effect of the Invention

According to one embodiment of the present invention, an electronic device with low power consumption can be provided. According to another embodiment of the present invention, an electronic device that allows the user to see an image with high luminance can be provided. According to another embodiment of the present invention, an electronic device including a display device that displays a high-quality image can be provided. According to another embodiment of the present invention, an electronic device including a display device capable of high-speed driving can be provided. According to another embodiment of the present invention, a small electronic device can be provided. According to another embodiment of the present invention, a highly reliable electronic device can be provided. According to another embodiment of the present invention, a novel electronic device can be provided.

Note that the description of these effects does not preclude the existence of other effects. Note that one embodiment of the present invention does not need to have all of these effects. Note that effects other than these can be derived from the descriptions of the specification, the drawings, the claims, and the like.

### BRIEF DESCRIPTION OF THE DRAWINGS

FIG. 1A is a perspective view illustrating a structure example of an electronic device. FIG. 1B is a perspective view illustrating a structure example of a display portion.

FIG. 2A to FIG. 2C are cross-sectional views illustrating structure examples of a display device.

FIG. 3A to FIG. 3C are cross-sectional views illustrating structure examples of a display device.

FIG. 4A and FIG. 4B are cross-sectional views illustrating structure examples of a display device.

FIG. 5A and FIG. 5B are block diagrams each illustrating a structure example of a display device.

FIG. 6A and FIG. 6B are perspective views illustrating structure examples of a display device.

FIG. 7 is a perspective view illustrating a structure example of a display device.

FIG. 8 is a block diagram illustrating a structure example of an electronic device.

FIG. 9A to FIG. 9C are cross-sectional views illustrating structure examples of a display device.

FIG. 10A to FIG. 10C are cross-sectional views illustrating a structure example of a display device.

FIG. 11A to FIG. 11D are cross-sectional views illustrating an example of a fabricating method of a display device.

FIG. 12A to FIG. 12F are cross-sectional views illustrating an example of a fabricating method of a display device.

FIG. 13A to FIG. 13D are cross-sectional views illustrating an example of a fabricating method of a display device.

FIG. 14A to FIG. 14D are cross-sectional views illustrating an example of a fabricating method of a display device.

FIG. 15A to FIG. 15G are plan views each illustrating a structure example of a pixel.

FIG. 16A to FIG. 16K are plan views each illustrating a structure example of a pixel.

FIG. 17 is a perspective view illustrating a structure example of a display module.

FIG. 18A and FIG. 18B are cross-sectional views illustrating structure examples of a display device.

FIG. 19 is a cross-sectional view illustrating a structure example of a display device.

FIG. 20 is a cross-sectional view illustrating a structure example of a display device.

FIG. 21 is a cross-sectional view illustrating a structure example of a display device.

FIG. 22 is a cross-sectional view illustrating a structure example of a display device.

FIG. 23 is a cross-sectional view illustrating a structure example of a display device.

FIG. 24 is a perspective view illustrating a structure example of a display device.

FIG. 25A is a cross-sectional view illustrating a structure example of a display device. FIG. 25B and FIG. 25C are cross-sectional views illustrating a structure example of a transistor.

FIG. 26 is a cross-sectional view illustrating a structure example of a display device.

FIG. 27 is a cross-sectional view illustrating a structure example of a display device.

FIG. 28 is a cross-sectional view illustrating a structure example of a display device.

FIG. 29 is a cross-sectional view illustrating a structure example of a display device.

FIG. 30 is a cross-sectional view illustrating a structure example of a display device.

FIG. 31A to FIG. 31F are cross-sectional views illustrating structure examples of a light-emitting element.

FIG. 32A to FIG. 32C are cross-sectional views illustrating structure examples of a light-emitting element.

### MODE FOR CARRYING OUT THE INVENTION

Embodiments are described below with reference to the drawings. However, the embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

Note that in structures of the invention described below, the same portions or portions having similar functions are denoted by the same reference numerals in different drawings, and description thereof is not repeated. Furthermore, the same hatch pattern is used for the portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

The term “film” and the term “layer” can be interchanged with each other depending on the case or circumstances. For example, the term “conductive layer” can be changed into the term “conductive film” in some cases. For another example, the term “insulating film” can be changed into the term “insulating layer” in some cases. For another example, the term “semiconductor film” can be changed into the term “semiconductor layer” in some cases.

In this specification and the like, terms for describing positioning, such as “over,” “under,” “above,” and “below,” are sometimes used for convenience to describe the positional relation between components with reference to drawings. The positional relationship between components is changed as appropriate in accordance with a direction in which each component is described. Thus, the positional relation is not limited to the terms described in this specification and the like, and can be described with another term as appropriate depending on the situation. For example, the expression “an insulating layer positioned over a conductive layer” can be replaced with the expression “an insulating layer positioned under a conductive layer” when the direction of a drawing illustrating these components is rotated by 180°.

Furthermore, unless otherwise specified, an off-state current in this specification and the like refers to a drain current of a transistor in an off state (also referred to as a non-conduction state or a cutoff state). Unless otherwise specified, an off state refers to, in an n-channel transistor, a state where a voltage V_{gs} between its gate and source is lower than a threshold voltage Vₜₕ (in a p-channel transistor, higher than Vₜₕ).

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, in this specification and the like, an “OS transistor” can also be referred to as a transistor including an oxide or an oxide semiconductor.

### Embodiment 1

In this embodiment, electronic devices, display devices, and the like of embodiments of the present invention will be described. For example, one embodiment of the present invention can be suitably used for a wearable electronic device for VR or AR applications, specifically, for HMD.

The electronic device of one embodiment of the present invention includes a first display device and a second display device. The first display device and the second display device each include a display portion, and pixels are arranged in a matrix in the display portion. The pixel includes a light-emitting element (also referred to as a light-emitting device) that emits visible light and the light-emitting element emits light with luminance corresponding to image data, so that an image can be displayed on the display portion.

In this specification and the like, visible light refers to light with a wavelength longer than or equal to 380 nm and shorter than 780 nm. Infrared light refers to light with a wavelength longer than or equal to 780 nm. Near-infrared light refers to light with a wavelength longer than or equal to 780 nm and shorter than or equal to 2500 nm. Furthermore, when the peak wavelength of light emitted from the light-emitting element is in the range of visible light, the expression “the light-emitting element emits visible light” is used; when the peak wavelength of light emitted from the light-emitting element is in the range of infrared light, the expression “the light-emitting element emits infrared light” is used; and when the peak wavelength of light emitted from the light-emitting element is in the range of near-infrared light, the expression “the light-emitting element emits near-infrared light” is used.

In this specification and the like, the light-emitting element includes an EL layer between a pair of electrodes. The EL layer includes at least a light-emitting layer. Examples of the layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In one embodiment of the present invention, the first display device is provided to overlap with the second display device. The display portion included in the second display device is provided to surround the display portion included in the first display device in a plan view. Accordingly, the first display device can display, for example, a first image which is seen at the center of the visual field of the user of the electronic device and its vicinity, and the second display device can display a second image displayed around the first image. Here, light emitted from the first display device passes through the second display device; thus, a region of the second display device overlapping with the display portion of the first display device transmits the light emitted from the first display device.

In this specification and the like, in the case where the expression “A transmits light B” is used, the transmittance of light B through A is greater than or equal to 5%.

A human recognizes an image at the center of their visual field and its vicinity minutely and recognizes an image outside the vicinity more roughly. For example, a human recognizes an image in the central visual field and the effective visual field minutely and recognizes an image in the peripheral visual field more roughly. Thus, the user of the electronic device rarely perceives a decrease in the display quality, e.g., rarely perceives graininess, even when the resolution of the second image is lower than the resolution of the first image. On the other hand, when the resolution of the second image is low, the pixel density of the second display device can be low, and thus, the area occupied by the whole display portion can be increased, for example. Accordingly, when the resolution of the second image is lower than the resolution of the first image, the area occupied by the whole display portion of the electronic device can be increased without making the user of the electronic device perceive a decrease in the display quality as compared with the case where the whole image displayed by the electronic device has uniform resolution.

When the first display device is provided to overlap with the second display device, loss of light emitted from the display device, such as loss of light emitted from the first display device, can be reduced as compared with the case, for example, where the first display device does not overlap with the second display device and the first image and the second image are combined using an optical combiner such as a half mirror. Thus, the electronic device of one embodiment of the present invention can be an electronic device with low power consumption. The user of the electronic device of one embodiment of the present invention can see an image with high luminance.

### <Structure Example of Electronic Device>

FIG. TA is an external view illustrating a structure example of an electronic device 10 of one embodiment of the present invention. The electronic device 10 can be an HMD. Moreover, the electronic device 10 can also be referred to as a goggle-type electronic device. Alternatively, the electronic device 10 may be referred to as a glasses-type electronic device.

The electronic device 10 includes a housing 31, a fixing unit 32, a pair of lenses 35 (a lens 35L and a lens 35R), a pair of frames 36 (a frame 36L and a frame 36R), and a pair of display portions 37 (a display portion 37L and a display portion 37R). The electronic device 10 can include a communication circuit 57 and a control circuit 59.

In the electronic device 10, the communication circuit 57 receives image data from the outside of the electronic device 10, for example. The communication circuit 57 supplies the received image data to the control circuit 59. On the basis of the received image data, the control circuit 59 performs control for displaying an image on the display portion 37. The image displayed on the display portion 37 is enlarged by the lens 35 and is seen by the user of the electronic device 10.

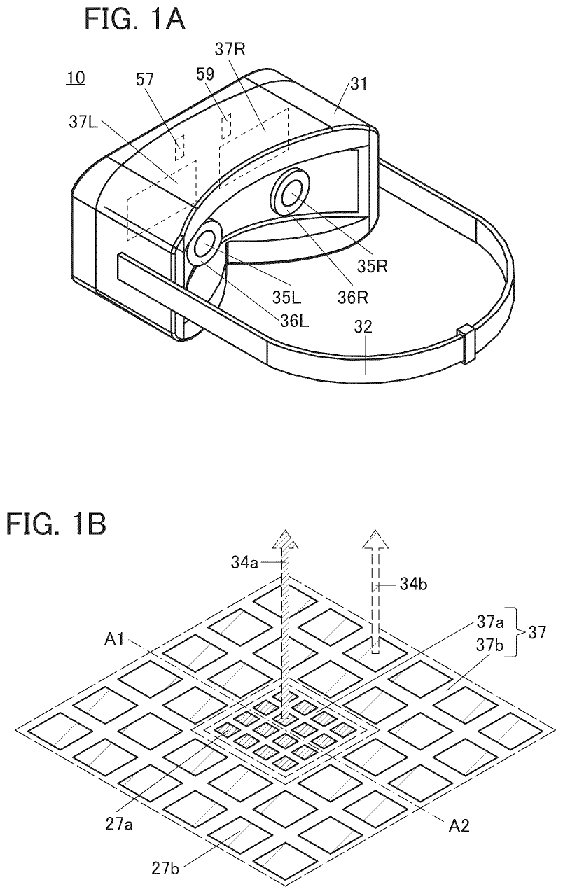

FIG. 1B is a perspective view illustrating a structure example of the display portion 37. Here, the structure illustrated in FIG. 1B can be applied to the display portion 37L and the display portion 37R.

The display portion 37 includes a display portion 37a and a display portion 37b. The display portion 37a can be the center of the display portion 37 and its vicinity region, and the display portion 37b can be a region around the display portion 37a. That is, the display portion 37b is provided to surround the display portion 37a in a plan view. Accordingly, the user of the electronic device 10 can see an image displayed on the display portion 37a at the center of their visual field and its vicinity and can see an image displayed on the display portion 37b at the peripheral visual field. Note that the center of the display portion 37 may be positioned not in the display portion 37a but in the display portion 37b. The display portion 37b does not necessarily surround the display portion 37a entirely. For example, in the case where the shape of the display portion 37a is a rectangular shape, the display portion 37b does not necessarily surround all of the four sides of the display portion 37a. For example, the display portion 37b can surround three of the four sides of the display portion 37a. Alternatively, the display portion 37b may surround two of the four sides of the display portion 37a entirely and surround the other two sides partially.

A plurality of pixels 27a are arranged in the display portion 37a, and the pixels 27a are arranged in a matrix, for example. A plurality of pixels 27b are arranged in the display portion 37b. Pixels 27 (the pixel 27a and the pixel 27b) each include a light-emitting element emitting visible light; light emitted from the light-emitting element is emitted from the pixels 27 as light 34 (light 34a and light 34b), so that an image can be displayed on the display portion 37. Note that light emitted from the pixel 27a is referred to as the light 34a, and light emitted from the pixel 27b is referred to as the light 34b.

As the light-emitting element, an OLED (Organic Light Emitting Diode) or a QLED (Quantum-dot Light Emitting Diode) is preferably used, for example. Examples of a light-emitting substance contained in the light-emitting element include a substance exhibiting fluorescence (a fluorescent material), a substance exhibiting phosphorescence (a phosphorescent material), a substance exhibiting thermally activated delayed fluorescence (a thermally activated delayed fluorescence (TADF) material), and an inorganic compound (e.g., a quantum dot material). An LED such as a micro-LED (Light Emitting Diode) can be used as the light-emitting element.

The pixel 27 is provided with a pixel circuit having a function of controlling the driving of the light-emitting element. The pixel circuit includes a transistor. Thus, the pixel 27 can be driven by an active matrix method.

As illustrated in FIG. 1B, the pixel density of the display portion 37a is higher than the pixel density of the display portion 37b. For example, the area occupied by each of the pixels 27a provided in the display portion 37a is smaller than the area occupied by each of the pixels 27b provided in the display portion 37b. The distance between the pixels 27a that are adjacent to each other is shorter than the distance between the pixels 27b that are adjacent to each other. As described above, the display portion 37a can display an image seen at the center of the visual field of the user of the electronic device 10 and its vicinity, and the display portion 37b can display an image seen in the peripheral visual field. Here, a human recognizes an image at the center of their visual field and its vicinity minutely and recognizes an image outside the vicinity more roughly. For example, a human recognizes an image in the central visual field and the effective visual field minutely and recognizes an image in the peripheral visual field more roughly. Thus, the user of the electronic device 10 rarely perceives a decrease in the display quality, e.g., rarely perceives graininess, even when the pixel density of the display portion 37b is lower than the pixel density of the display portion 37a and the resolution of an image displayed on the display portion 37b is lower than the resolution of an image displayed on the display portion 37a. On the other hand, when the pixel density of the display portion 37b is low, the area occupied by the whole display portion 37 can be increased, for example. Accordingly, when the pixel density of the display portion 37b is lower than the pixel density of the display portion 37a, the area occupied by the display portion 37 can be increased without making the user of the electronic device perceive a decrease in the display quality as compared with the case where the whole display portion 37 has uniform pixel density.

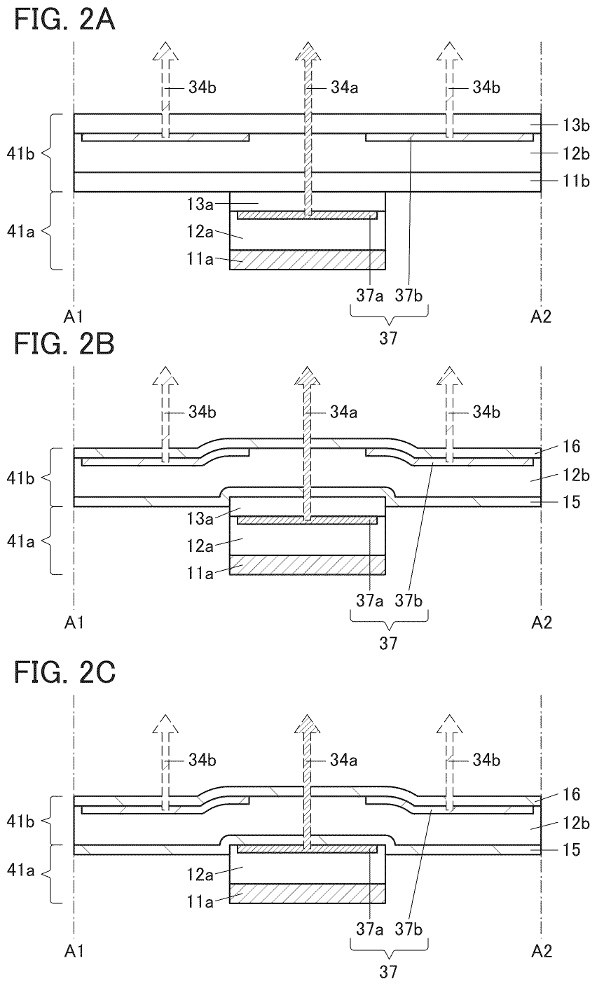

FIG. 2A is a cross-sectional view illustrating a structure example along a dashed-dotted line A1-A2 in FIG. 1B, and is a cross-sectional view illustrating a structure example of a display device including the display portion 37. As illustrated in FIG. 2A, the display portion 37a is included in a display device 41a, and the display portion 37b is included in a display device 41b.

The display device 41a includes a substrate 11a, a layer 12a over the substrate 11a, and a substrate 13a over the layer 12a, and the display portion 37a is provided in the layer 12a. The display device 41b includes a substrate 11b, a layer 12b over the substrate 11b, and a substrate 13b over the layer 12b, and the display portion 37b is provided in the layer 12b. For example, the layer 12a is provided with a driver circuit for driving the display device 41a and the layer 12b is provided with a driver circuit for driving the display device 41b. Since these driver circuits are each provided with a transistor, for example, the layer 12a and the layer 12b include transistors.

The display device 41b is provided over the display device 41a. The display device 41a overlaps with the display device 41b. Specifically, the substrate 13a overlaps with the substrate 11b, for example. For example, the substrate 13a includes a region in contact with the substrate 11b, and the display device 41a is fixed under the display device 41b. For example, when a first housing and a second housing are attached to the display device 41a and the display device 41b, respectively, the display device 41a can be fixed under the display device 41b by engaging the first housing and the second housing. The display device 41b includes a region not overlapping with the display device 41a. Specifically, the substrate 11b includes a region not overlapping with the substrate 13a, for example.

The display portion 37a can display an image by emitting the light 34a. The display portion 37b can display an image by emitting the light 34b. The light 34a passes through the substrate 13a, the substrate 11b, the layer 12b, and the substrate 13b. The light 34b passes through the substrate 13b. Accordingly, the substrate 13a, the substrate 11b, the layer 12b, and the substrate 13b transmit the light 34a. The substrate 13b transmits the light 34b. Here, a structure can be employed in which the substrate 11a does not transmit the light 34a or the light 34b. Thus, a structure can be employed in which the substrate 11a does not transmit visible light, for example. Meanwhile, the substrate 11b, the substrate 13a, and the substrate 13b transmit visible light, for example.

The display portion 37a is provided to include a region not overlapping with the display portion 37b. Accordingly, the light 34a entering the display device 41b can be extracted to the outside of the display device 41b even if the display portion 37b does not transmit the light 34a or the transmittance of the light 34a in the display portion 37b is lower than the transmittance of the light 34a in a region of the layer 12b where the display portion 37b is not provided. Thus, the user of the electronic device 10 including the display device 41a and the display device 41b can see an image displayed on the display portion 37a.

Note that part of the display portion 37a may overlap with the display portion 37b. Specifically, an end portion of the display portion 37a may overlap with the display portion 37b, and an end portion of the display portion 37b may overlap with the display portion 37a. Such a structure can prevent a region where the display portion 37 is not provided from being formed between the display portion 37a and the display portion 37b. Thus, a boundary between the display portion 37a and the display portion 37b can be inhibited from being seen by the user of the electronic device 10. Here, even if part of the display portion 37a overlaps with the display portion 37b, the display portion 37b can be regarded as being provided so as to surround the display portion 37a as long as a region of the display portion 37b that does not overlap with the display portion 37a surrounds the display portion 37a in a plan view.

As described above, in the electronic device 10, the display device 41a is provided to overlap with the display device 41b, and the display portion 37b of the display device 41b is provided to surround the display portion 37a of the display device 41a in a plan view. Accordingly, loss of the light 34a can be reduced as compared with the case where the display device 41a does not overlap with the display device 41b and an image displayed on the display portion 37a and an image displayed on the display portion 37b are combined with an optical combiner such as a half mirror. In addition, loss of the light 34b can be reduced in some cases. Thus, the electronic device 10 can be an electronic device with low power consumption. The user of the electronic device 10 can see an image with high luminance.

Materials that can be used for the substrate 11a, the substrate 11b, the substrate 13a, or the substrate 13b will be described below.

As described above, a structure can be employed in which the substrate 11a does not transmit visible light, for example. Thus, a semiconductor substrate can be used as the substrate 11a, for example. Specifically, as the substrate 11a, a single crystal semiconductor substrate or a polycrystalline semiconductor substrate using silicon, silicon carbide, or the like as a material, a compound semiconductor substrate of silicon germanium or the like, an SOI substrate, or the like can be used.

As described above, the substrate 13a, the substrate 11b, and the substrate 13b transmit visible light, for example. Thus, a glass substrate, a quartz substrate, a sapphire substrate, a plastic substrate, or the like is used as the substrate 13a, the substrate 11b, and the substrate 13b, for example. Note that a glass substrate, a quartz substrate, a sapphire substrate, a plastic substrate, or the like, which is an insulating substrate, can also be used as the substrate 11a.

The thicknesses of the substrate 11a, the substrate 13a, the substrate 11b, and the substrate 13b can each be greater than or equal to 50 μm and less than or equal to 2 mm, and are each preferably greater than or equal to 50 μm and less than or equal to 1 mm, further preferably greater than or equal to 50 μm and less than or equal to 500 μm, still further preferably greater than or equal to 50 μm and less than or equal to 300 μm.

A variety of optical members can be arranged on a surface of the substrate 13a opposite to the display portion 37a and a surface of the substrate 13b opposite to the display portion 37b. Examples of the optical members include a polarizing plate, a retardation plate, a light diffusion layer (e.g., a diffusion film), an anti-reflective layer, and a light-condensing film.

FIG. 2B illustrates a modification example of the structure illustrated in FIG. 2A, which is different from the structure illustrated in FIG. 2A in that the display device 41b includes a substrate 15 instead of the substrate 11b and includes a substrate 16 instead of the substrate 13b.

The substrate 15 and the substrate 16 have flexibility. Thus, the display device 41b illustrated in FIG. 2B has flexibility. Therefore, the display device 41b illustrated in FIG. 2B can be regarded as a flexible display.

A flexible substrate can be thinner than a substrate without flexibility. Thus, each of the thicknesses of the substrate 15 and the substrate 16 can be smaller than the thickness of the substrate 11a, for example. When the display device 41b is a flexible display as described above, the difference between the height of the display portion 37b and the height of the display portion 37a relative to a surface of the substrate 11a can be reduced, for example. Accordingly, the difference between the distance from the eyes of the user of the electronic device 10 to the display portion 37a and the distance from the eyes of the user of the electronic device 10 to the display portion 37b can be reduced, which can inhibit one or both of an image displayed on the display portion 37a and an image displayed on the display portion 37b from being blurred. Thus, the user of the electronic device 10 can see a high-quality image.

Furthermore, reducing the difference between the height of the display portion 37b and the height of the display portion 37a relative to the surface of the substrate 11a can inhibit the light 34a emitted from the display portion 37a included in the display device 41a from entering the display portion 37b. For example, in the case where an electrode of the light-emitting element included in the display portion 37b reflects visible light, the light 34a entering the display portion 37b is reflected by the electrode and is not extracted to the outside of the display device 41b; thus, the light extraction efficiency of the display device 41a can be increased by inhibiting the light 34a from entering the display portion 37b.

Note that in the display device illustrated in FIG. 2B, the substrate 13b illustrated in FIG. 2A may be provided instead of the substrate 16. That is, only a substrate provided between the display portion 37a and the display portion 37b among the substrates included in the display device 41b may have flexibility. The substrate 13a included in the display device 41a may have flexibility. For example, the thickness of the substrate 11b illustrated in FIG. 2A may be smaller than the thickness of the substrate 11a. That is, the display device 41b may include a substrate without flexibility and the thickness of the substrate may be smaller than the thickness of the substrate 11a. Alternatively, the substrate 13a may be a substrate without flexibility and the thickness of the substrate 13a may be smaller than the thickness of the substrate 11a.

For a substrate having flexibility, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. In addition, glass that is thin enough to have flexibility may be used. Here, when the above-described material is used for the substrate, the substrate can transmit visible light.

The thickness of the flexible substrate is set in the range where both flexibility and mechanical strength can be achieved. The thickness of the flexible substrate can be greater than or equal to 1 μm and less than or equal to 300 μm, and is preferably greater than or equal to 10 μm and less than or equal to 300 μm, further preferably greater than or equal to 10 μm and less than or equal to 100 μm, still further preferably greater than or equal to 10 μm and less than or equal to 50 μm, for example. Note that the thickness of the substrate 11b illustrated in FIG. 2A may be within this range. That is, the display device 41b may include the substrate without flexibility and the thickness of the substrate may be within the above range.

In structures described below, the substrate 11b can be replaced with the substrate 15, and the substrate 13b can be replaced with the substrate 16 in some cases.

FIG. 2C illustrates a modification example of the structure illustrated in FIG. 2B, which is different from the structure illustrated in FIG. 2B in that the display device 41a does not include the substrate 13a. For example, any of the variety of optical members can be provided directly on the layer 12a, and the display device 41b can be provided thereover.

When the substrate 13a is omitted, the difference between the height of the display portion 37b and the height of the display portion 37a relative to the surface of the substrate 11a can be small, for example. Thus, the user of the electronic device 10 can see a high-quality image. Furthermore, the light 34a can be inhibited from entering the display portion 37b and the light extraction efficiency of the display device 41a can be increased. In the display device 41b illustrated in FIG. 2C, the substrate 11b may be provided instead of the substrate 15, and the substrate 13b may be provided instead of the substrate 16. That is, even when the display device 41a is not provided with the substrate 13a, a substrate provided in the display device 41b is not necessarily flexible.

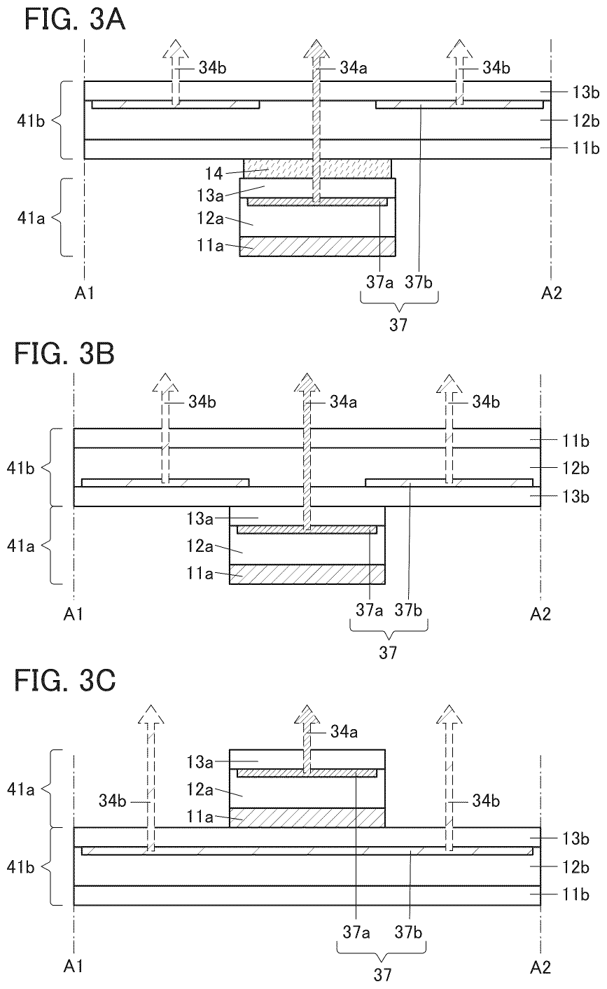

FIG. 3A illustrates a modification example of the structure illustrated in FIG. 2A, which is different from the structure illustrated in FIG. 2A in that an adhesive layer 14 is provided between the substrate 13a and the substrate 11b. The adhesive layer 14 transmits the light 34a. The adhesive layer 14 transmits visible light, for example.

When the display device 41a and the display device 41b are bonded to each other with the adhesive layer 14, formation of a gap between the display device 41a and the display device 41b can be inhibited. Thus, the light 34a emitted from the display device 41a can be inhibited from being reflected or refracted by the gap. Thus, the display device 41a can display a high-quality image.

Accordingly, the adhesive layer 14 is preferably provided in a region that is over the substrate 13a and that does not overlap with the display portion 37b. In contrast, the adhesive layer 14 is not necessarily provided in a region that is over the substrate 13a and that does not overlap with the display portion 37b.

For the adhesive layer 14, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. An adhesive sheet may be used, for example.

FIG. 3B illustrates a modification example of the structure illustrated in FIG. 2A, which is different from the structure illustrated in FIG. 2A in that the substrate 13b is provided over the display device 41a, the layer 12b including the display portion 37b is provided over the substrate 13b, and the substrate 11b is provided over the layer 12b.

For example, in the display device 41b illustrated in FIG. 2A, a driver circuit is provided below the display portion 37b. Meanwhile, in the display device 41b illustrated in FIG. 3B, a driver circuit is provided above the display portion 37b. For example, in the display device 41b illustrated in FIG. 2A, the light 34b emitted from the display portion 37b passes through the substrate 13b. Meanwhile, in the display device 41b illustrated in FIG. 3B, the light 34b passes through the substrate 11b. For example, the display device 41b illustrated in FIG. 2A is a top-emission display device, and the display device 41b illustrated in FIG. 3B is a bottom-emission display device.

FIG. 3C illustrates a modification example of the structure illustrated in FIG. 2A, which is different from the structure illustrated in FIG. 2A in that the display device 41a is provided over the display device 41b. As described above, a structure in which the substrate 11a does not transmit visible light can be employed, for example. Thus, the display portion 37b can be provided to overlap with the whole display portion 37a, for example. A structure in which the substrate 11b does not transmit visible light can be employed, for example.

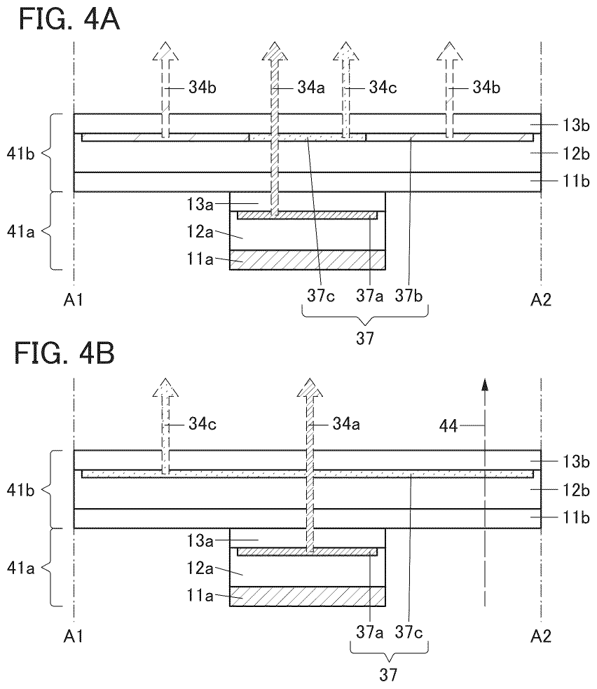

FIG. 4A illustrates a modification example of the structure illustrated in FIG. 2A, which is different from the structure illustrated in FIG. 2A in that a display portion 37c is provided in the layer 12b of the display device 41b. The display portion 37c is provided to overlap with the display portion 37a included in the display device 41a. In the structure illustrated in FIG. 4A, the display portion 37 includes the display portion 37a, the display portion 37b, and the display portion 37c. Although not illustrated, in the display portion 37c, a plurality of pixels are arranged and the pixels are arranged in a matrix, for example. The pixel includes a light-emitting element emitting visible light; when light emitted from the light-emitting element is emitted from the pixel as light 34c, an image can be displayed on the display portion 37c. Here, the pixel density of the display portion 37c can be lower than the pixel density of the display portion 37a, and can be equivalent to the pixel density of the display portion 37b. Thus, the resolution of an image displayed on the display portion 37c can be lower than the resolution of an image displayed on the display portion 37a and can be equivalent to the resolution of an image displayed on the display portion 37b.

The light 34c passes through the substrate 13b. The above pixels each include a pixel circuit having a function of controlling driving of the light-emitting element. As described above, the pixel circuit includes a transistor.

In the structure illustrated in FIG. 4A, the light 34a emitted from the display portion 37a enters the display portion 37c. Thus, a structure is employed in which the display portion 37c transmits the light 34a; specifically, a structure is employed in which the display portion 37c has higher transmittance of the light 34a than the display portion 37b. For example, a structure is employed in which the display portion 37c transmits visible light; specifically, a structure is employed in which the display portion 37c has higher transmittance of visible light than the display portion 37b. For example, an electrode included in a light-emitting element provided in the display portion 37c transmits the light 34a. A layer included in the transistor of the pixel circuit provided in the display portion 37c transmits the light 34a. In the case where the pixel circuit includes a capacitor, for example, a layer included in the capacitor transmits the light 34a. Furthermore, a wiring provided in the display portion 37c also transmits the light 34a, for example. Thus, the display portion 37c can transmit the light 34a.

Accordingly, with the structure illustrated in FIG. 4A, the user of the electronic device 10 can see an image that is displayed on the display portion 37c of the display device 41b and that is superimposed on an image displayed on the display portion 37a of the display device 41a. Here, it is preferable to display an image on the display portion 37a and the display portion 37c in view of the fact that the resolution of an image which the display portion 37c can display is lower than the resolution of an image which the display portion 37a. For example, marks such as a cursor showing a point to be focused on in an image displayed on the display portion 37a can be displayed on the display portion 37c.

FIG. 4B illustrates a modification example of the structure illustrated in FIG. 4A, which is different from the structure illustrated in FIG. 4A in that the display portion 37c includes a region not overlapping with the display portion 37a. Although FIG. 4B illustrates an example in which the display device 41b does not include the display portion 37b, the display device 41b may include the display portion 37b. For example, the display portion 37b may be provided in a region not overlapping with the display device 41a. Note that in the structure illustrated in FIG. 4B, a region of the display portion 37c not overlapping with the display device 41a transmits light 44 that is external light in some cases.

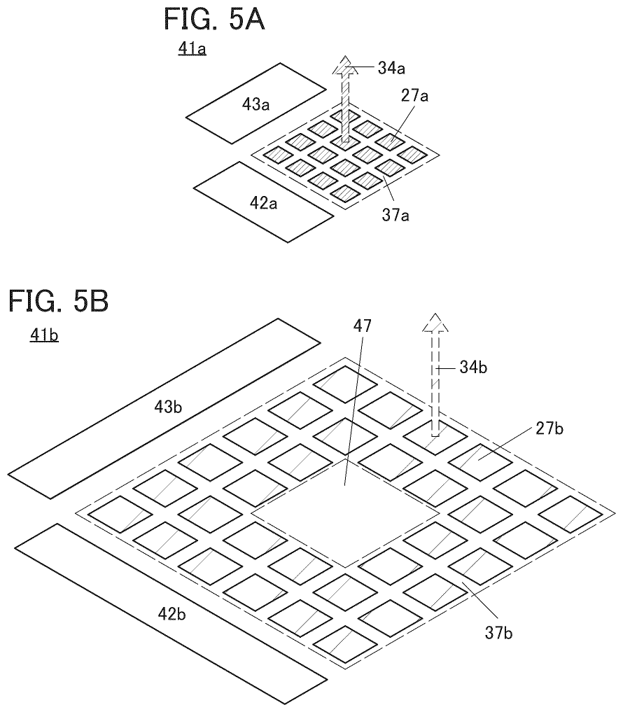

FIG. 5A is a block diagram illustrating a structure example of the display device 41a including the display portion 37a. As described above, the plurality of pixels 27a are arranged in the display portion 37a, and the pixels 27a are arranged in a matrix, for example. The display device 41a includes a gate driver circuit 42a and a source driver circuit 43a. Although not illustrated in FIG. 5A, the gate driver circuit 42a and the source driver circuit 43a are electrically connected to the pixel 27a. The gate driver circuit 42a and the source driver circuit 43a are driver circuits of the display device 41a.

In the display device 41a, the source driver circuit 43a can write image data to the pixel 27a selected by the gate driver circuit 42a. By writing the image data to the pixel 27a, the pixel 27a emits the light 34a with luminance corresponding to the image data. Accordingly, an image can be displayed on the display portion 37a.

FIG. 5B is a block diagram illustrating a structure example of the display device 41b including the display portion 37b. As described above, the plurality of pixels 27b are arranged in the display portion 37b. Here, a region 47 where the pixels 27b are not arranged is provided in the display device 41b, and the display portion 37b is provided to surround the region 47. The region 47 is a region overlapping with the display portion 37a of the display device 41a. Note that in the case where the display device 41b has the structure illustrated in FIG. 4A, the display portion 37c is provided in the region 47. In the case where the display device 41b has the structure illustrated in FIG. 4B, the display portion 37c is provided instead of the display portion 37b and is also provided in the region 47.

The display device 41b includes a gate driver circuit 42b and a source driver circuit 43b. Although not illustrated in FIG. 5B, the gate driver circuit 42b and the source driver circuit 43b are electrically connected to the pixel 27b. The gate driver circuit 42b and the source driver circuit 43b are driver circuits of the display device 41b.

In the display device 41b, the source driver circuit 43b can write image data to the pixel 27b selected by the gate driver circuit 42b. By writing the image data to the pixel 27b, the pixel 27b emits the light 34b with luminance corresponding to the image data, whereby an image can be displayed on the display portion 37b.

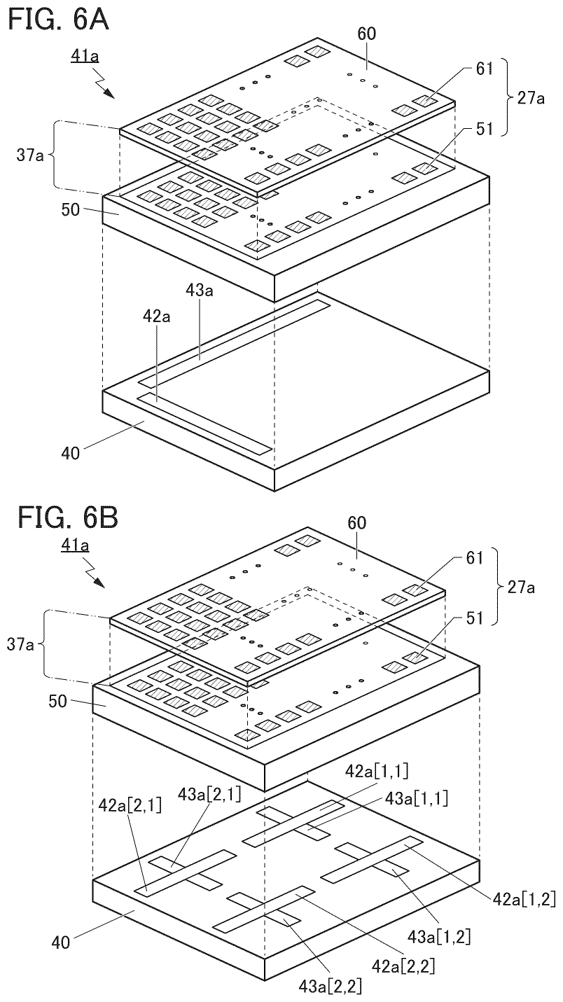

FIG. 6A is a perspective view illustrating a structure example of the display device 41a. As illustrated in FIG. 6A, the display device 41a can include a layer 40, a layer 50 over the layer 40, and a layer 60 over the layer 50.

A plurality of pixel circuits 51 are arranged in the layer 50, and a plurality of light-emitting elements 61 are arranged in the layer 60. The pixel circuit 51 and the light-emitting element 61 are electrically connected to each other and function as the pixel 27a. Thus, a region where the plurality of pixel circuits 51 provided in the layer 50 and the plurality of light-emitting elements 61 provided in the layer 60 overlap with each other functions as the display portion 37a.

The gate driver circuit 42a and the source driver circuit 43a are provided in the layer 40. When the gate driver circuit 42a and the source driver circuit 43a are provided in the layer different from the layer in which the pixel circuit 51 is provided, the gate driver circuit 42a and the source driver circuit 43a can be provided to overlap with the display portion 37a. Thus, the width of the bezel around the display portion 37a can be narrowed as compared with the case where the gate driver circuit 42a and the source driver circuit 43a are provided not to overlap with the display portion 37a. Thus, the area occupied by the display portion 37a can be increased.

In addition, when the pixel circuit 51, and the gate driver circuit 42a and the source driver circuit 43a are stacked, wirings electrically connecting them can be shortened. Thus, wiring resistance and parasitic capacitance are reduced. Thus, for example, the time taken for charging and discharging a wiring can be shortened, so that the display device 41a can be driven at high speed. Furthermore, the power consumption of the electronic device 10 can be reduced because the power consumption of the display device 41a can be reduced.

Note that the gate driver circuit 42a and the source driver circuit 43a may be provided in the same layer as the pixel circuit 51. In this case, transistors included in the gate driver circuit 42a and transistors included in the source driver circuit 43a can be formed in the same step as transistors included in the pixel circuit 51, for example. Alternatively, some of the transistors included in the gate driver circuit 42a and some of the transistors included in the source driver circuit 43a may be provided in the layer 50, for example. That is, the gate driver circuit 42a and the source driver circuit 43a may be provided in both the layer 40 and the layer 50. Alternatively, one of the gate driver circuit 42a and the source driver circuit 43a may be provided in the layer 40, and the other of the gate driver circuit 42a and the source driver circuit 43a may be provided in the layer 50.

FIG. 6B illustrates a modification example of the structure illustrated in FIG. 6A, in which a plurality of the gate driver circuits 42a and a plurality of the source driver circuits 43a are provided. FIG. 6B illustrates an example in which the gate driver circuits 42a in two rows and two columns and the source driver circuits 43a in two rows and two columns are provided.

In FIG. 6B, the gate driver circuits 42a in two rows and two columns are denoted as a gate driver circuit 42a[1,1], a gate driver circuit 42a[1,2], a gate driver circuit 42a[2,1], and a gate driver circuit 42a[2,2] to be distinguished from each other. Furthermore, the source driver circuits 43a in two rows and two columns are denoted as a source driver circuit 43a[1,1], a source driver circuit 43a[1,2], a source driver circuit 43a[2,1], and a source driver circuit 43a[2,2] to be distinguished from each other.

When the plurality of driver circuits 42a are provided, wirings electrically connecting the pixel circuits 51 and the gate driver circuits 42a can be shortened. Specifically, the maximum length of the wiring from the pixel circuit 51 to the gate driver circuit 42a can be reduced. In addition, when the plurality of source driver circuits 43a are provided, wirings electrically connecting the pixel circuits 51 and the source driver circuits 43a can be shortened. Specifically, the maximum length of the wiring from the pixel circuit 51 to the source driver circuit 43a can be reduced. Thus, wiring resistance and parasitic capacitance are reduced. Thus, for example, the time taken for charging and discharging a wiring can be shortened, so that the display device 41a can be driven at high speed. In addition, the power consumption of the electronic device 10 can be reduced because the power consumption of the display device 41a can be reduced.

Furthermore, the number of rows of the pixel circuits 51 to be scanned by one gate driver circuit 42a can be reduced, for example; thus, the frame frequency of the display device 41a can be increased.

Although FIG. 6B illustrates an example in which the gate driver circuit 42a includes a region overlapping with the source driver circuit 43a, the gate driver circuit 42a does not necessarily overlap with the source driver circuit 43a. When the gate driver circuit 42a includes a region overlapping with the source driver circuit 43a, the layout flexibility of the gate driver circuit 42a and the source driver circuit 43a can be increased. By contrast, when the gate driver circuit 42a and the source driver circuit 43a do not overlap with each other, the driving of the gate driver circuit 42a and the driving of the source driver circuit 43a can be inhibited from influencing each other.

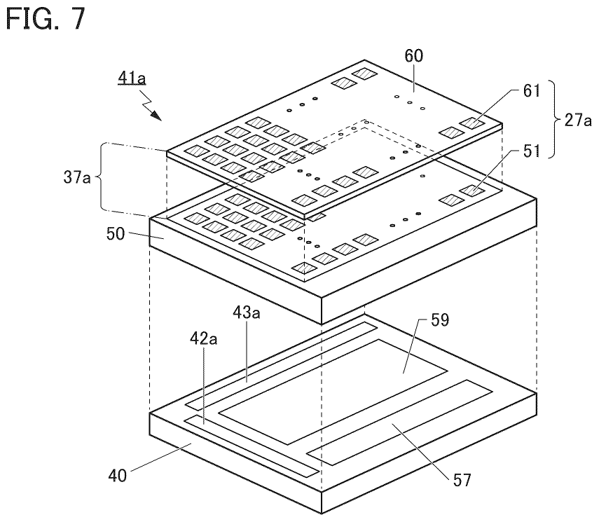

FIG. 7 illustrates a modification example of the structure illustrated in FIG. 6A, and illustrates an example in which the communication circuit 57 and the control circuit 59 illustrated in FIG. TA are provided in the layer 40 in addition to the gate driver circuit 42a and the source driver circuit 43a. That is, FIG. 7 illustrates an example in which the communication circuit 57 and the control circuit 59 are provided in the display device 41a so as to include a region overlapping with the display portion 37a. Accordingly, the area occupied by the display portion 37 can be increased as compared with the case where the communication circuit 57 and the control circuit 59 are provided outside the display device 41a. Note that the circuits other than the communication circuit 57 and the control circuit 59 provided in the electronic device 10 can also be provided in the layer 40.

In the display device 41a illustrated in FIG. 7, one or both of the gate driver circuit 42a and the source driver circuit 43a may be provided in the layer 50. In that case, the area occupied by a region where the communication circuit 57, the control circuit 59, and the like are provided can be increased.

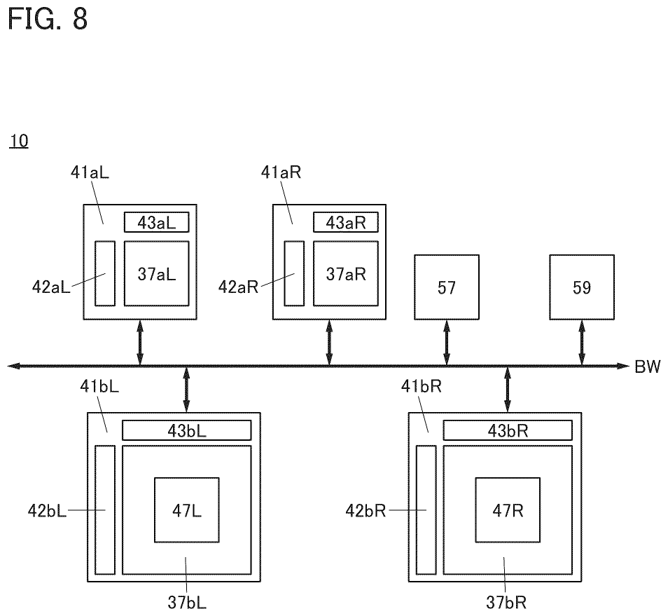

FIG. 8 is a block diagram illustrating a structure example of the electronic device 10. The display device 41a, the display device 41b, the communication circuit 57, and the control circuit 59 included in the electronic device 10 transmit and receive various kinds of data, signals, and the like to and from each other via a bus wiring BW. Here, the display portion 37L illustrated in FIG. 1A includes a display portion 37aL and a display portion 37bL, and the display portion 37R illustrated in FIG. 1A includes a display portion 37aR and a display portion 37bR. The display device 41a including the display portion 37aL is referred to as a display device 41aL, and the display device 41a including the display portion 37aR is referred to as a display device 41aR. The gate driver circuit 42a and the source driver circuit 43a included in the display device 41aL are respectively referred to as a gate driver circuit 42aL and a source driver circuit 43aL, and the gate driver circuit 42a and the source driver circuit 43a included in the display device 41aR are respectively referred to as agate driver circuit 42aR and a source driver circuit 43aR. The display device 41b including the display portion 37bL is referred to as a display device 41bL, and the display device 41b including the display portion 37bR is referred to as a display device 41bR. The gate driver circuit 42b, the source driver circuit 43b, and the region 47 included in the display device 41bL are respectively referred to as a gate driver circuit 42bL, a source driver circuit 43bL, and a region 47L, and the gate driver circuit 42b, the source driver circuit 43b, and the region 47 included in the display device 41bR are respectively referred to as a gate driver circuit 42bR, a source driver circuit 43bR, and a region 47R.

The communication circuit 57 has a function of communicating with an external device with or without a wire. The communication circuit 57 has a function of receiving image data from an external device, for example. The communication circuit 57 may have a function of transmitting data generated by the electronic device 10 to an external device.

The communication circuit 57 is provided with a high frequency circuit (RF circuit), for example, to transmit and receive an RF signal. The high frequency circuit is a circuit for performing mutual conversion between an electromagnetic signal and an electrical signal in a frequency band that is set by national laws to perform wireless communication with another communication apparatus using the electromagnetic signal. In the case of performing wireless communication, it is possible to use, as a communication protocol or a communication technology, a communication standard such as LTE (Long Term Evolution), GSM (Global System for Mobile Communication: registered trademark), EDGE (Enhanced Data Rates for GSM Evolution), CDMA 2000 (Code Division Multiple Access 2000), WCDMA (Wideband Code Division Multiple Access: registered trademark), or the like, or a communication standard developed by IEEE such as Wi-Fi (registered trademark), Bluetooth (registered trademark), or ZigBee (registered trademark). The third-generation mobile communication system (3G), the fourth-generation mobile communication system (4G), or the fifth-generation mobile communication system (5G) defined by the International Telecommunication Union (ITU) or the like can be used.

The communication circuit 57 may include an external port such as a LAN (Local Area Network) connection terminal, a digital broadcast-receiving terminal, or an AC adaptor connection terminal.

The control circuit 59 has a function of generating, on the basis of image data received by the communication circuit 57, data representing luminance of light emitted from a light-emitting element provided in the display portion 37a (first luminance data) and data representing luminance of light emitted from a light-emitting element provided in the display portion 37b (second luminance data). For example, when image data includes address information of a pixel and luminance information of each pixel, the control circuit 59 can determine in which the luminance information of each pixel is included in the first luminance data or in the second luminance data, on the basis of the address information. Note that the luminance data may be referred to as image data.

Here, the control circuit 59 can have a function of performing downconversion reducing the resolution of image data. The control circuit 59 may have a function of performing upconversion increasing the resolution of image data. For example, the control circuit 59 can perform downconversion on the second luminance data. The control circuit 59 may perform upconversion on the first luminance data.

The control circuit 59 has a function of supplying the first luminance data to the display device 41a, specifically, the source driver circuit 43a included in the display device 41a, and supplying the second luminance data to the display device 41b, specifically, the source driver circuit 43b included in the display device 41b.

A central processing unit (CPU) and other microprocessors such as a DSP (Digital Signal Processor) and a GPU (Graphics Processing Unit) can be used alone or in combination as the control circuit 59. A structure may be employed in which such a microprocessor is obtained with a PLD (Programmable Logic Device) such as an FPGA (Field Programmable Gate Array) or an FPAA (Field Programmable Analog Array).

The control circuit 59 interprets and executes instructions from various programs with a processor to process various kinds of data and control programs. The programs that can be executed by the processor may be stored in a memory region included in the processor or a memory circuit which is additionally provided. As the memory circuit, a memory device using a nonvolatile memory element, such as a flash memory, an MRAM (Magnetoresistive Random Access Memory), a PRAM (Phase change RAM), a ReRAM (Resistive RAM), or a FeRAM (Ferroelectric RAM); a memory device using a volatile memory element, such as a DRAM (Dynamic RAM) or an SRAM (Static RAM); or the like may be used, for example.

Although FIG. 8 illustrates an example in which the display device 41b does not include the display portion 37c, the display device 41b may include the display portion 37c. In this case, the gate driver circuit 42b and the source driver circuit 43b can control driving of not only the pixels included in the display portion 37b but also the pixels included in the display portion 37c. Although FIG. 8 illustrates an example in which the communication circuit 57 and the control circuit 59 are provided outside the display device 41a and the display device 41b, the communication circuit 57 and the control circuit 59 may be provided inside the display device 41a, for example.

### <Structure Example of Display Portion>

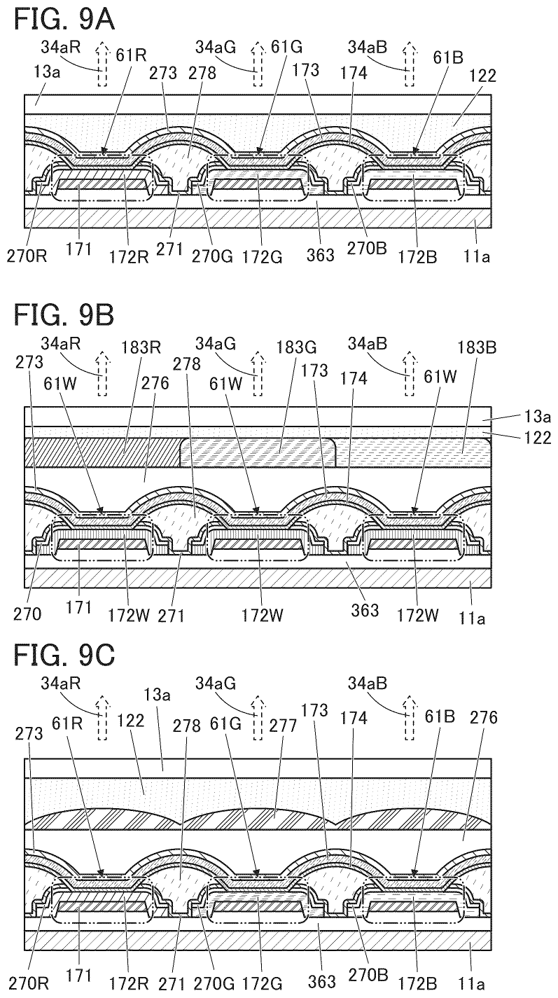

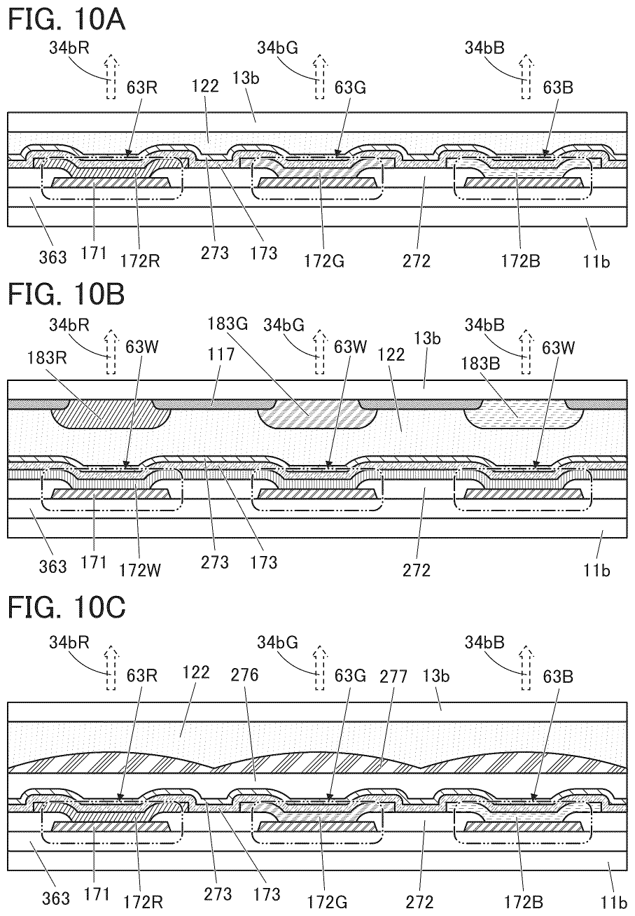

Structure examples of a display device included in the electronic device of one embodiment of the present invention will be described below with reference to FIG. 9A to FIG. 9C and FIG. 10A to FIG. 10C. Specifically, structure examples of a light-emitting element provided in a pixel included in a display portion of the display device are described. FIG. 9A to FIG. 9C illustrate structure examples of a display device that can be suitably used as the display device 41a, and FIG. 10A to FIG. 10C illustrate structure examples of a display device that can be suitably used as the display device 41b. Note that the display device illustrated in FIG. 9A to FIG. 9C may be used as the display device 41b or the display device illustrated in FIG. 10A to FIG. 10C may be used as the display device 41a.

FIG. 9A is a cross-sectional view illustrating a structure example of a light-emitting element 61R, alight-emitting element 61G, and alight-emitting element 61B. The light-emitting element 61R can emit light 34aR with intensity in the red wavelength range. The light-emitting element 61G can emit light 34aG with intensity in the green wavelength range. The light-emitting element 61B can emit light 34aB with intensity in the blue wavelength range. Here, one pixel can include one light-emitting element 61R, one light-emitting element 61G, and one light-emitting element 61B, for example. The pixel includes a subpixel, and one subpixel can include any one of the light-emitting element 61R, the light-emitting element 61G, and the light-emitting element 61B, for example. Accordingly, FIG. 9A illustrates an example in which one pixel includes three subpixels. Note that Embodiment 2 can be referred to for the pixel layout of the display device included in the electronic device of one embodiment of the present invention.

Here, red light can be, for example, light with a peak wavelength greater than or equal to 630 nm and less than or equal to 780 nm. Green light can be, for example, light with a peak wavelength greater than or equal to 500 nm and less than 570 nm. Blue light can be, for example, light with a peak wavelength greater than or equal to 450 nm and less than 480 nm.

In this specification and the like, the area occupied by the subpixel provided with a light-emitting element is defined as the area of an EL layer in a plan view. The sum of the areas occupied by the subpixels included in the pixel is defined as the area occupied by the pixel. For example, in the case where the pixel includes three subpixels, the area occupied by the pixel is defined as the sum of the areas occupied by the three subpixels.

In the display device illustrated in FIG. 9A, a layer 363 is provided over the substrate 11a. The layer 363 is provided with the pixel circuit 51 illustrated in FIG. 6A, for example. The layer 363 is provided with driver circuits of the display device 41a, such as the gate driver circuit 42a and the source driver circuit 43a. Since these circuits are provided with a transistor, for example, the layer 363 includes transistors.

An insulating layer is provided to cover the transistors provided in the layer 363. The insulating layer is also included in the layer 363. The insulating layer may have a single-layer structure or a stacked-layer structure. As the insulating layer, one or both of an inorganic insulating film and an organic insulating film can be used. As the inorganic insulating film, for example, an oxide insulating film and a nitride insulating film such as a silicon oxide film, a silicon oxynitride film, a silicon nitride oxide film, a silicon nitride film, an aluminum oxide film, an aluminum oxynitride film, or a hafnium oxide film can be given. Examples of the organic insulating film include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins.

Note that in this specification, a nitride oxide refers to a compound that contains more nitrogen than oxygen. An oxynitride refers to a compound that contains more oxygen than nitrogen. The content of each element can be measured by Rutherford backscattering spectrometry (RBS), for example.

The light-emitting element 61R, the light-emitting element 61G, and the light-emitting element 61B are provided over the layer 363. Specifically, the light-emitting element 61R, the light-emitting element 61G, and the light-emitting element 61B can be provided over the insulating layer provided in the layer 363.

The light-emitting element 61R includes a conductive layer 171 over the layer 363, an EL layer 172R over the conductive layer 171, and a conductive layer 173 over the EL layer 172R. The light-emitting element 61G includes the conductive layer 171 over the layer 363, an EL layer 172G over the conductive layer 171, and the conductive layer 173 over the EL layer 172G. The light-emitting element 61B includes the conductive layer 171 over the layer 363, an EL layer 172B over the conductive layer 171, and the conductive layer 173 over the EL layer 172B.

In this specification and the like, a structure in which at least light-emitting layers of light-emitting elements with different emission wavelengths are separately formed may be referred to as an SBS (Side By Side) structure. For example, the light-emitting element 61R, the light-emitting element 61G, and the light-emitting element 61B illustrated in FIG. 9A have an SBS structure. The SBS structure can optimize materials and structures of light-emitting elements and thus can increase the degree of freedom in selecting materials and structures, so that the luminance and the reliability can be easily improved.

The conductive layer 171 functions as a pixel electrode and is separated for each light-emitting element. The conductive layer 173 functions as a common electrode and is provided as a continuous layer shared by the light-emitting element 61R, the light-emitting element 61G, and the light-emitting element 61B.

The EL layer 172R, the EL layer 172G, and the EL layer 172B are separated for each light-emitting element. That is, the EL layer 172R, the EL layer 172G, and the EL layer 172B are each formed in an island shape. When the EL layer 172R, the EL layer 172G, and the EL layer 172B are each formed in an island shape and are not in contact with each other, unintentional light emission (also referred to as crosstalk) due to current flowing through two adjacent EL layers can be suitably prevented. As a result, the contrast can be increased to achieve a display device with high display quality. Note that the EL layer 172R, the EL layer 172G, and the EL layer 172B may each be formed in a band shape. That is, the EL layer 172R may be shared by a plurality of the light-emitting elements 61R arranged in the same direction, the EL layer 172G may be shared by a plurality of the light-emitting elements 61G arranged in the same direction, and the EL layer 172B may be shared by a plurality of the light-emitting elements 61B arranged in the same direction.

An end portion of the EL layer 172R, an end portion of the EL layer 172G, and an end portion of the EL layer 172B are positioned outward from end portions of the conductive layers 171, and the EL layer 172R, the EL layer 172G, and the EL layer 172B can each cover the end portion of the conductive layer 171. Note that the end portion of the EL layer 172R, the end portion of the EL layer 172G, and the end portion of the EL layer 172B may each be positioned inward from the end portion of the conductive layer 171.

The EL the layer 172R contains at least a light-emitting organic compound that emits light with intensity in the red wavelength range. The EL layer 172G contains at least a light-emitting organic compound that emits light with intensity in the green wavelength range. The EL layer 172B contains at least a light-emitting organic compound that emits light with intensity in the blue wavelength range.

The EL layer 172R, the EL layer 172G, and the EL layer 172B may each include one or more of an electron-injection layer, an electron-transport layer, a hole-injection layer, and a hole-transport layer in addition to the layer containing a light-emitting organic compound (the light-emitting layer). Embodiment 4 can be referred to for the details of structures and materials of the light-emitting element included in the electronic device of one embodiment of the present invention.

As described above, a structure in which the substrate 11a does not transmit visible light can be employed, and a structure in which the substrate 13a transmits visible light can be employed. Thus, when a conductive film having a reflecting property with respect to visible light is used as the conductive layer 171 and a conductive film having a transmitting property with respect to visible light is used as the conductive layer 173, the light 34aR, the light 34aG, and the light 34aB are emitted to the substrate 13a side. Such a display device can be referred to as a top-emission display device.

A protective layer 271 is provided between the light-emitting elements 61 (the light-emitting element 61R, the light-emitting element 61G, and the light-emitting element 61B) to cover the end portion of the EL layer 172R, the end portion of the EL layer 172G, and the end portion of the EL layer 172B. The protective layer 271 has a barrier property against water, for example. Thus, providing the protective layer 271 can inhibit entry of impurities (typically, water or the like) into the end portions of the EL layer 172R, the EL layer 172G, and the EL layer 172B. In addition, a leak current between adjacent light-emitting elements 61 is reduced, so that color saturation and contrast ratio are improved and power consumption is reduced.

The protective layer 271 can have, for example, a single-layer structure or a stacked-layer structure at least including an inorganic insulating film. As the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide (IGZO) may be used for the protective layer 271. Note that the protective layer 271 can be formed, for example, by an atomic layer deposition (ALD) method, a chemical vapor deposition (CVD) method, or a sputtering method. Although the protective layer 271 includes an inorganic insulating film in this example, one embodiment of the present invention is not limited thereto. For example, the protective layer 271 may have a stacked-layer structure of an inorganic insulating film and an organic insulating film.

In the case where an indium gallium zinc oxide is used for the protective layer 271, the indium gallium zinc oxide can be processed by a wet etching method or a dry etching method. For example, in the case where IGZO is used as the protective layer 271, a chemical solution of oxalic acid, phosphoric acid, a chemical solution such as a mixed chemical solution (e.g., a mixed chemical solution of phosphoric acid, acetic acid, nitric acid, and water, which is also referred to as a mixed acid aluminum etchant), or the like can be used. Note that the volume ratio of phosphoric acid, acetic acid, nitric acid, and water in the mixed acid aluminum etchant can be 53.3:6.7:3.3:36.7 or in the vicinity thereof.

In each of the light-emitting element 61R, the light-emitting element 61G, and the light-emitting element 61B, an EL layer 172 (the EL layer 172R, the EL layer 172G, or the EL layer 172B) includes a region overlapping with the protective layer 271 with a sacrificial layer 270 (a sacrificial layer 270R, a sacrificial layer 270G, or a sacrificial layer 270B) therebetween. The sacrificial layer 270 is formed because of the process of fabricating a display device described later. Note that the sacrificial layer 270 is not provided in some cases.

Note that in this specification and the like, a sacrificial layer may be referred to as a mask layer. In addition, a sacrificial film may be referred to as a mask film.

In a region between the light-emitting elements 61 that are adjacent to each other, an insulating layer 278 is provided over the protective layer 271. FIG. 9A illustrates an example in which the top surface of the insulating layer 278 has a convex curved surface shape. Although a plurality of cross sections of the protective layer 271 and a plurality of cross sections of the insulating layer 278 are illustrated in FIG. 9A, for example, the protective layer 271 and the insulating layer 278 are each a continuous layer when the display surface is seen from above. In other words, the display device can include one of the protective layers 271 and one of the insulating layers 278, for example. Note that the display device may include a plurality of the protective layers 271 that are separated from each other and a plurality of the insulating layers 278 that are separated from each other.

The insulating layer 278 with a convex curved surface shape provided in a region between the light-emitting elements 61 that are adjacent to each other can fill a gap formed by a step due to the EL layer 172 in the region. This can improve the coverage with the conductive layer 173. Thus, a connection defect due to disconnection of the conductive layer 173 and an increase in electric resistance due to local thinning of the conductive layer 173 can be inhibited. Note that when the top surface of the insulating layer 278 is flat, disconnection and local thinning of the conductive layer 173 can be further suitably inhibited. Even in the case where the insulating layer 278 has a concave curved surface shape, disconnection and local thinning of the conductive layer 173 can be inhibited.

In this specification and the like, disconnection refers to a phenomenon in which a layer, a film, an electrode, or the like is split because of the shape of the formation surface (e.g., a level difference).

Examples of the insulating layer 278 include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. Alternatively, a photoresist may be used as the insulating layer 278. The photoresist used as the insulating layer 278 may be a positive photoresist or a negative photoresist.

A common layer 174 can be provided between the conductive layer 173, and the EL layer 172R, the EL layer 172G, the EL layer 172B, and the insulating layer 278. The common layer 174 can include a region in contact with the EL layer 172R, a region in contact with the EL layer 172G, and a region in contact with the EL layer 172B. The common layer 174 is provided as a continuous layer shared by the light-emitting element 61R, the light-emitting element 61G, and the light-emitting element 61B.

In the case where the common layer 174 is provided in the display device, the conductive layer 173 functioning as the common electrode can be formed successively after the formation of the common layer 174, without interposing a step of etching or the like. For example, after the common layer 174 is formed in a vacuum, the conductive layer 173 can be formed in a vacuum without exposing the substrate 11a to the air. In other words, the common layer 174 and the conductive layer 173 can be successively formed in a vacuum. Accordingly, the lower surface of the conductive layer 173 can be a clean surface, as compared with the case where the common layer 174 is not provided in the display device.

As the common layer 174, one or more of a hole-injection layer, a hole-transport layer, a hole-blocking layer, an electron-blocking layer, an electron-transport layer, and an electron-injection layer can be used. For example, the common layer 174 may be a carrier-injection layer. The common layer 174 can also be regarded as part of the EL layer 172. Note that the common layer 174 is not necessarily provided; in this case, the fabricating process of the display device can be simplified. In the case where the common layer 174 is provided, a layer having the same function as the common layer 174 among the layers included in the EL layer 172 is not necessarily provided. For example, in the case where the common layer 174 includes an electron-injection layer, an electron-injection layer is not necessarily provided in the EL layer 172. For example, in the case where the common layer 174 includes a hole-injection layer, a hole-injection layer is not necessarily provided in the EL layer 172. Note that the EL layer 172 and the common layer 174 may be collectively referred to as an EL layer. That is, an “EL layer” may refer to only a layer formed in an island shape or a combination of a layer formed in an island shape and a common layer.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that the above-described carrier-injection layer, carrier-transport layer, and carrier-blocking layer cannot be distinguished from each other in some cases by the cross-sectional shape, the characteristics, or the like. One layer may have two or three functions of the carrier-injection layer, the carrier-transport layer, and the carrier-blocking layer in some cases.

A protective layer 273 is provided over the conductive layer 173 so as to cover the light-emitting element 61R, the light-emitting element 61G, and the light-emitting element 61B. The protective layer 273 has a function of preventing diffusion of impurities such as water into the light-emitting elements from above. For the protective layer 273, a material similar to the material that can be used for the protective layer 271 can be used. The protective layer 273 can be formed by an ALD method, a CVD method, or a sputtering method, for example.

The substrate 13a is bonded over the protective layer 273 with an adhesive layer 122. For the adhesive layer 122, a material similar to the material that can be used for the adhesive layer 14 illustrated in FIG. 3A can be used. In the case where a hollow sealing structure is employed to seal the light-emitting elements, the space filled with the adhesive layer 122 may be filled with an inert gas (e.g., nitrogen or argon). Note that the components from the layer 363 to the adhesive layer 122 can be the layer 12a illustrated in FIG. 2A, for example.

Furthermore, the color purity of emitted light can be further increased when the light-emitting element 61 has a microcavity structure. In order that the light-emitting element 61 has a microcavity structure, a product (optical path length) of a distance d between the conductive layer 171 and the conductive layer 173 and a refractive index n of the EL layer 172 is set to m times half of a wavelength λ (m is an integer of 1 or more). The distance d can be obtained by Formula 1.

$$d = m \times λ / ( 2 \times n ) . \qquad Formula 1$$

According to Formula 1, in the light-emitting element 61 having the microcavity structure, the distance d is determined in accordance with the wavelength (emission color) of emitted light. The distance d corresponds to the thickness of the EL layer 172. Thus, the EL layer 172G is provided to have a larger thickness than the EL layer 172B, and the EL layer 172R is provided to have a larger thickness than the EL layer 172G in some cases.

According to Formula 1, in the light-emitting element 61 having the microcavity structure, the distance d is determined in accordance with the wavelength (emission color) of emitted light. The distance d corresponds to the thickness of the EL layer 172. Thus, the EL layer 172G is provided to have a larger thickness than the EL layer 172B, and the EL layer 172R is provided to have a larger thickness than the EL layer 172G in some cases.

To be exact, the distance d is a distance from a reflection region in the conductive layer 171 functioning as a reflective electrode to a reflection region in the conductive layer 173 functioning as an electrode having properties of transmitting and reflecting emitted light (a semi-transmissive and semi-reflective electrode). For example, in the case where the conductive layer 171 is a stack of silver and ITO (Indium Tin Oxide) that is a transparent conductive film and the ITO is positioned on the EL layer 172 side, the distance d suitable for the emission color can be set by adjusting the thickness of the ITO. That is, even when the EL layer 172R, the EL layer 172G, and the EL layer 172B have the same thickness, the distance d suitable for the emission color can be obtained by adjusting the thickness of the ITO.

However, it is sometimes difficult to determine the exact position of the reflection region in each of the conductive layer 171 and the conductive layer 173. In this case, it is assumed that the effect of the microcavity structure can be obtained sufficiently with a certain position in the conductive layer 171 and the conductive layer 173 being supposed as the reflection region.

In order to increase the light extraction efficiency in the microcavity structure, the optical path length from the conductive layer 171 functioning as a reflective electrode to the light-emitting layer is preferably set to an odd multiple of λ/4. In order to achieve this optical distance, the thicknesses of the layers in the light-emitting element 61 are preferably adjusted as appropriate.

In the case where light is emitted from the conductive layer 173 side, the reflectance of the conductive layer 173 is preferably higher than the transmittance thereof. The transmittance of the conductive layer 173 is preferably higher than or equal to 2% and lower than or equal to 50%, further preferably higher than or equal to 2% and lower than or equal to 30%, still further preferably higher than or equal to 2% and lower than or equal to 10%. When the transmittance of the conductive layer 173 is set low (the reflectance is set high), the effect of the microcavity structure can be enhanced.

FIG. 9B illustrates a modification example of the structure illustrated in FIG. 9A. FIG. 9B illustrates an example in which light-emitting elements 61W that emit white light are provided over the layer 363 instead of the light-emitting element 61R, the light-emitting element 61G, and the light-emitting element 61B, for example. The light-emitting element 61W includes an EL layer 172W that emits white light, for example, as the EL layer 172. The EL layer 172W can have, for example, a structure in which two or more light-emitting layers that are selected so as to emit light of complementary colors are stacked. A stacked EL layer in which a charge-generation layer is provided between light-emitting layers can be used as the EL layer 172W.

Here, the EL layer 172W is separated for each of the light-emitting elements 61W. This can prevent unintentional light emission from being caused by current flowing through the EL layers 172W of the two adjacent light-emitting elements 61W. Particularly when the EL layer 172W has a structure in which a charge-generation layer is provided between two light-emitting layers is used, the influence of crosstalk becomes more noticeable as the resolution increases, i.e., as the distance between adjacent pixels decreases, leading to lower contrast. Thus, the above structure can achieve a display device having both high definition and high contrast. Note that the EL layer 172W is not necessarily separated for each of the light-emitting elements 61W and may be a continuous layer.

An example is illustrated in which an insulating layer 276 is provided over the protective layer 273 and a coloring layer 183R, a coloring layer 183G, and a coloring layer 183B are provided over the insulating layer 276. Specifically, the coloring layer 183R that transmits red light is provided at a position overlapping with the light-emitting element 61W on the left, the coloring layer 183G that transmits green light is provided at a position overlapping with the light-emitting element 61W in the middle, and the coloring layer 183B that transmits blue light is provided at a position overlapping with the light-emitting element 61W on the right. By including the coloring layer 183R, the coloring layer 183G, and the coloring layer 183B, the display device can display a color image even when all the light-emitting elements provided in the display device emit white light, for example.

The coloring layer 183 (the coloring layer 183R, the coloring layer 183G, or the coloring layer 183B) includes a region overlapping with the adjacent coloring layer 183. For example, in the cross section illustrated in FIG. 9B, one end portion of the coloring layer 183G overlaps with the coloring layer 183R, and the other end portion of the coloring layer 183G overlaps with the coloring layer 183B. Thus, light emitted from the light-emitting element 61W provided in a position overlapping with the coloring layer 183G, for example, can be inhibited from entering the coloring layer 183R or the coloring layer 183B and being emitted through the coloring layer 183R or the coloring layer 183B. Accordingly, the display device can have high display quality.

The insulating layer 276 functions as a planarization layer. For example, an organic material can be used for the insulating layer 276. For example, as the insulating layer 276, an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins or the like can be used.

When the insulating layer 276 is provided over the protective layer 273, the coloring layer 183 can be provided on a planar surface. This makes it easy to form the coloring layer 183. Note that the adhesive layer 122 is provided on the coloring layer 183, and the substrate 13a is bonded to the coloring layer 183 with the adhesive layer 122.

The light-emitting element 61W can have a microcavity structure like the light-emitting element 61R, the light-emitting element 61G, and the light-emitting element 61B. Thus, for example, the light-emitting element 61W overlapping with the coloring layer 183R can emit red-enhanced light, the light-emitting element 61W overlapping with the coloring layer 183G can emit green-enhanced light, and the light-emitting element 61W overlapping with the coloring layer 183B can emit blue-enhanced light. Thus, when the light-emitting element 61W has a microcavity structure, the color purity of the light 34aR, the light 34aG, and the light 34aB can be increased.

FIG. 9C illustrates a modification example of the structure illustrated in FIG. 9A in which the insulating layer 276 is provided over the protective layer 273 and a microlens array 277 is provided over the insulating layer 276. Note that the adhesive layer 122 is provided over the microlens array 277, and the substrate 13a is bonded to the microlens array 277 with the adhesive layer 122.

Note that when the refractive index of the adhesive layer 122 is lower than the refractive index of the microlens array 277, the microlens array 277 can condense light emitted from the light-emitting element 61R, the light-emitting element 61G, and the light-emitting element 61B in some cases. Condensing light emitted from the light-emitting element 61R, the light-emitting element 61G, and the light-emitting element 61B is suitable because a user can see bright images particularly when the user sees the display surface from the front of the display device.

Note that the microlens array 277 may be provided in the structure illustrated in FIG. 9B. For example, an insulating layer functioning as a planarization layer can be provided over the coloring layer 183R, the coloring layer 183G, and the coloring layer 183B, and the microlens array 277 can be provided over the insulating layer. In this case, the adhesive layer 122 is provided over the microlens array 277, and the substrate 13a is bonded to the microlens array 277 with the adhesive layer 122. The coloring layer 183R, the coloring layer 183G, and the coloring layer 183B may be provided in the structure illustrated in FIG. 9C. For example, an insulating layer functioning as a planarization layer may be provided over the microlens array 277, and the coloring layer 183R, the coloring layer 183G, and the coloring layer 183B may be provided over the insulating layer. In this case, the adhesive layer 122 is provided over the coloring layer 183, and the substrate 13a is bonded to the coloring layer 183 with the adhesive layer 122.

FIG. 10A illustrates a modification example of the structure illustrated in FIG. 9A and illustrates an example in which a light-emitting element 63R, a light-emitting element 63G, and a light-emitting element 63B are provided over the layer 363 instead of the light-emitting element 61R, the light-emitting element 61G, and the light-emitting element 61B. FIG. 10A illustrates an example in which the substrate 11b and the substrate 13b are provided instead of the substrate 11a and the substrate 13a. Note that in the example illustrated in FIG. 10A, the components from the layer 363 to the adhesive layer 122 can be the layer 12b illustrated in FIG. 2A, for example.

The light-emitting element 63R can emit the light 34bR with intensity in the red wavelength range. The light-emitting element 63G can emit the light 34bG with intensity in the green wavelength range. The light-emitting element 63B can emit the light 34bB with intensity in the blue wavelength range.

As described above, the substrate 11b and the substrate 13b can transmit visible light. Thus, when a conductive film having a reflecting property with respect to visible light is used as the conductive layer 171 and a conductive film having a transmitting property with respect to visible light is used as the conductive layer 173, the light 34bR, the light 34bG, and the light 34bB are emitted to the substrate 13b side. Such a display device can be referred to as a top-emission display device. When a conductive film having a reflecting property with respect to visible light is used as the conductive layer 173 and a conductive film having a transmitting property with respect to visible light is used as the conductive layer 171, the light 34bR, the light 34bG, and the light 34bB are emitted to the substrate 11b side. Such a display device can be referred to as a bottom-emission display device.

The light-emitting element 63R includes the conductive layer 171 over the layer 363, the EL layer 172R over the conductive layer 171, and the conductive layer 173 over the EL layer 172R. The light-emitting element 63G includes the conductive layer 171 over the layer 363, the EL layer 172G over the conductive layer 171, and the conductive layer 173 over the EL layer 172G. The light-emitting element 63B includes the conductive layer 171 over the layer 363, the EL layer 172B over the conductive layer 171, and the conductive layer 173 over the EL layer 172B.

FIG. 10A illustrates an example in which an insulating layer 272 is provided to cover the end portion of the conductive layer 171 functioning as a pixel electrode. Providing the insulating layer 272 can prevent an unintentional electrical short-circuit between the conductive layers 171 included in adjacent light-emitting elements 63 (the light-emitting element 63R, the light-emitting element 63G, and the light-emitting element 63B) and unintended light emission therefrom. Thus, a highly reliable display device can be provided.

In the light-emitting element 63R, the light-emitting element 63G, and the light-emitting element 63B, the EL layer 172R, the EL layer 172G, and the EL layer 172B each include a region in contact with the top surface of the conductive layer 171 and a region in contact with the surface of the insulating layer 272. The end portions of the EL layer 172R, the EL layer 172G, and the EL layer 172B are positioned over the insulating layer 272.

An end portion of the insulating layer 272 is preferably tapered. In the structure illustrated in FIG. 10A, the protective layer 271, the sacrificial layer 270, the insulating layer 278, and the common layer 174 are not provided. A color purity of the emission color can be increased when the light-emitting element 63 has a microcavity structure like the light-emitting element 61.

Note that in this specification and the like, a tapered shape refers to a shape such that at least part of the side surface of a structure is inclined with respect to a substrate surface or a formation surface. For example, a tapered shape preferably includes a region where the angle between the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

An organic material or an inorganic material can be used for the insulating layer 272, for example. Examples of an organic material that can be used for the insulating layer 272 include an acrylic resin, an epoxy resin, a polyimide resin, a polyamide resin, a polyimide-amide resin, a polysiloxane resin, a benzocyclobutene-based resin, and a phenol resin. Examples of an inorganic material that can be used for the insulating layer 272 include silicon oxide, aluminum oxide, gallium oxide, germanium oxide, yttrium oxide, zirconium oxide, lanthanum oxide, neodymium oxide, hafnium oxide, tantalum oxide, silicon nitride, aluminum nitride, silicon oxynitride, aluminum oxynitride, silicon nitride oxide, and aluminum nitride oxide.

FIG. 10B illustrates a modification example of the structure illustrated in FIG. 10A and illustrates an example in which a light-emitting element 63W that emits white light is provided over the layer 363 instead of the light-emitting element 63R, the light-emitting element 63G, and the light-emitting element 63B, for example. The light-emitting element 63W includes the EL layer 172W as the EL layer 172. Note that when the light-emitting element 63W has a microcavity structure like the light-emitting element 61W, the color purity of the light 34bR, the light 34bG, and the light 34bB can be increased.

FIG. 10B illustrates an example in which the coloring layer 183R, the coloring layer 183G, and the coloring layer 183B are provided on the surface of the substrate 13b on the substrate 11b side. FIG. 10B illustrates an example in which a light-blocking layer 117 is provided on the surface of the substrate 13b on the substrate 11b side in a region where the coloring layer 183R, the coloring layer 183G, and the coloring layer 183B are not provided. FIG. 10B illustrates an example in which end portions of the coloring layer 183R, the coloring layer 183G, and the coloring layer 183B overlap with the light-blocking layer 117. Note that in the example illustrated in FIG. 10B, the components from the layer 363 to the coloring layer 183R, the coloring layer 183G, the coloring layer 183B, and the light-blocking layer 117 can be the layer 12b illustrated in FIG. 2A, for example. Note that in the case where the display device illustrated in FIG. 10B is a bottom-emission display device, the coloring layer 183R, the coloring layer 183G, the coloring layer 183B, and the light-blocking layer 117 are provided on the layer 363.

Providing the light-blocking layer 117 can inhibit light emitted from the light-emitting element 63W from being emitted through the substrate 13b without passing through the desired coloring layer 183. Specifically, light emitted from the light-emitting element 63W overlapping with the coloring layer 183R can be inhibited from being emitted through the substrate 13b without passing through the coloring layer 183R, light emitted from the light-emitting element 63W overlapping with the coloring layer 183G can be inhibited from being emitted through the substrate 13b without passing through the coloring layer 183G, and light emitted from the light-emitting element 63W overlapping with the coloring layer 183B can be inhibited from being emitted through the substrate 13b without passing through the coloring layer 183B. Accordingly, the display device can display a high-quality image.

The light-blocking layer 117 can be provided in the display device illustrated in FIG. 10A, for example. In that case, light emitted from the light-emitting element 63R, the light-emitting element 63G, and the light-emitting element 63B can be inhibited from being reflected by the substrate 13b, for example, and diffused inside the display device. Thus, the display device can display high-quality images. Meanwhile, when the light-blocking layer 117 is not provided, the extraction efficiency of light emitted from the light-emitting element 63R, the light-emitting element 63G, and the light-emitting element 63B can be increased. Similarly, the light-blocking layer 117 can be provided in the display device illustrated in FIG. 9A or FIG. 9C, for example.

In the example illustrated in FIG. 10B, the adhesive layer 122 is provided between the protective layer 273 and the coloring layer 183R, the coloring layer 183G, the coloring layer 183B, and the light-blocking layer 117. Thus, the coloring layer 183R, the coloring layer 183G, the coloring layer 183B, and the light-blocking layer 117 that are provided to the substrate 13b are bonded over the protective layer 273.

When the coloring layer 183R, the coloring layer 183G, the coloring layer 183B, and the light-blocking layer 117 are provided to the substrate 13b and bonded to the protective layer 273, the degree of freedom of the fabrication conditions of the coloring layer 183R, the coloring layer 183G, the coloring layer 183B, and the light-blocking layer 117 can be increased. For example, heat treatment can be performed at a temperature higher than the upper temperature limit of the EL layer 172W. Meanwhile, misalignment occurs when the coloring layer 183R, the coloring layer 183G, the coloring layer 183B, and the light-blocking layer 117 are bonded to the protective layer 273 in some cases. Thus, in the case where a pixel is too minute to ignore the influence of the misalignment, it is preferable that the coloring layer 183R, the coloring layer 183G, and the coloring layer 183B be formed over the protective layer 273 as illustrated in FIG. 9B, and then the substrate 13b be bonded thereto, for example.

FIG. 10B illustrates an example in which the EL layer 172W is not separated on the light-emitting element 63W basis and is a continuous layer. When the EL layer 172W is a continuous layer, the fabricating process of the display device can be simplified. Note that the EL layer 172W may be separated on the light-emitting element 63W basis.

FIG. 10C illustrates a modification example of the structure illustrated in FIG. 10A, and illustrates an example in which the insulating layer 276 is provided over the protective layer 273 and the microlens array 277 is provided over the insulating layer 276. Note that the microlens array 277 may be provided in the structure illustrated in FIG. 10B. For example, the insulating layer 276 can be provided over the protective layer 273, and the microlens array 277 can be provided over the insulating layer 276. In this case, the adhesive layer 122 is provided between the microlens array 277 and the coloring layer 183R, the coloring layer 183G, the coloring layer 183B, and the light-blocking layer 117. Note that in the example illustrated in FIG. 10C, the components from the layer 363 to the adhesive layer 122 can be the layer 12b illustrated in FIG. 2A, for example.

The display device having the structure illustrated in FIG. 9A, FIG. 9B, or FIG. 9C can have higher resolution without a reduction in the contrast than the display device having the structure illustrated in FIG. 10A, FIG. 10B, or FIG. 10C. For example, the distance between adjacent light-emitting elements 61 can be reduced. Specifically, the distance between the light-emitting elements 61 can be less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, a region where the distance between an end portion of one of two adjacent EL layers 172 and an end portion of the other EL layer 172 is less than or equal to 1 μm, preferably less than or equal to 0.5 μm (500 nm), further preferably less than or equal to 100 nm is provided.

Meanwhile, the display device having the structure illustrated in FIG. 10A, FIG. 10B, or FIG. 10C can be fabricated by a simple method as compared with the display device having the structure illustrated in FIG. 9A, FIG. 9B, or FIG. 9C. Thus, the display device having the structure illustrated in FIG. 10A, FIG. 10B, or FIG. 10C can be fabricated at low cost.

As described above, the resolution of the display device 41a including the display portion 37a is higher than the resolution of the display device 41b including the display portion 37b. Thus, as described above, the structure illustrated in FIG. 9A, FIG. 9B, or FIG. 9C can be suitably used for the display device 41a. Specifically, the light-emitting element 61 can be suitably used as a light-emitting element included in the pixel 27a provided in the display portion 37a. Meanwhile, as described above, the display device having the structure illustrated in FIG. 10A, FIG. 10B, or FIG. 10C can be fabricated at low cost. Thus, the structure illustrated in FIG. 10A, FIG. 10B, or FIG. 10C is preferably used for the display device 41b because the electronic device 10 can be an inexpensive electronic device. Specifically, the light-emitting element 63 can be suitably used as a light-emitting element included in the pixel 27b provided in the display portion 37b.

Note that as described above, the structure illustrated in FIG. 9A, FIG. 9B, or FIG. 9C may be used for the display device 41b. In this case, for example, the substrate 11a and the substrate 13a are replaced with the substrate 11b and the substrate 13b. As described above, the structure illustrated in FIG. 10A, FIG. 10B, or FIG. 10C may be used for the display device 41a. In this case, for example, the substrate 11b and the substrate 13b are replaced with the substrate 11a and the substrate 13a.

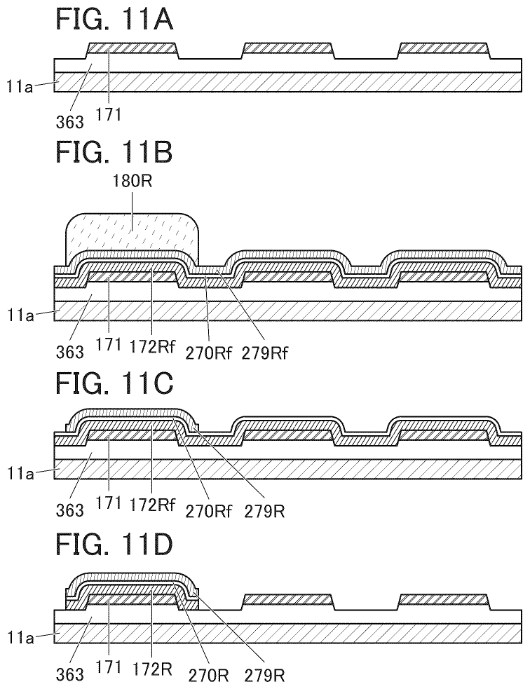

An example of a method for fabricating the display device having the structure illustrated in FIG. 9A will be described below with reference to FIG. 11A to FIG. 13D.

First, as illustrated in FIG. 11A, the layer 363 is formed over the substrate 11a. Specifically, for example, a transistor is formed over the substrate 11a, and an insulating layer is formed to cover the transistor. Next, as illustrated in FIG. 11A, the conductive layer 171 is formed over the layer 363. For example, a film to be the conductive layer 171 is formed by a sputtering method or a vacuum evaporation method, and the film is processed by a photolithography method and an etching method, whereby the conductive layer 171 can be formed. Note that a depressed portion is sometimes formed in the layer 363 when the film to be the conductive layer 171 is processed by an etching method, for example. Specifically, in a region not overlapping with the conductive layer 171, a depressed portion is sometimes formed in the insulating layer positioned on the outermost surface of the layer 363.

Next, as illustrated in FIG. 11B, an EL film 172Rf to be the EL layer 172R later is formed over the conductive layer 171 and over the layer 363. The EL film 172Rf can be formed by an evaporation method, specifically a vacuum evaporation method, for example. The EL film 172Rf may be formed by a transfer method, a printing method, an inkjet method, a coating method, or the like.

Next, as illustrated in FIG. 11B, a sacrificial film 270Rf to be the sacrificial layer 270R later and a sacrificial film 279Rf to be a sacrificial layer 279R later are formed in this order over the EL film 172Rf.

Although an example where the sacrificial film is formed to have a two-layer structure of the sacrificial film 270Rf and the sacrificial film 279Rf will be described below, the sacrificial film may have a single-layer structure or a stacked-layer structure of three or more layers.

Providing the sacrificial film over the EL film 172Rf can reduce damage to the EL film 172Rf in the fabricating process of the display device, resulting in improved reliability of the light-emitting element.

As the sacrificial film 270Rf, a film that is highly resistant to the processing conditions for the EL film 172Rf, specifically, a film having high etching selectivity with the EL film 172Rf is used. As the sacrificial film 279Rf, a film having high etching selectivity with respect to the sacrificial film 270Rf is used.

The sacrificial film 270Rf and the sacrificial film 279Rf are formed at a temperature lower than the upper temperature limit of the EL film 172Rf. The typical substrate temperatures in formation of the sacrificial film 270Rf and the sacrificial film 279Rf are each lower than or equal to 200° C., preferably lower than or equal to 150° C., further preferably lower than or equal to 120° C., still further preferably lower than or equal to 100° C., and yet still further preferably lower than or equal to 80° C.

As the sacrificial film 270Rf and the sacrificial film 279Rf, it is preferable to use a film that can be removed by a wet etching method. Using a wet etching method can reduce damage to the EL film 172Rf in processing the sacrificial film 270Rf and the sacrificial film 279Rf, as compared to the case of using a dry etching method.

The sacrificial film 270Rf and the sacrificial film 279rf can be formed by a sputtering method, an ALD method (a thermal ALD method, a PEALD method, or the like), a CVD method, or a vacuum evaporation method, for example.

Note that the sacrificial film 270Rf, which is formed over and in contact with the EL film 172Rf, is preferably formed by a formation method that causes less damage to the EL film 172Rf than a formation method for the sacrificial film 279Rf. For example, the sacrificial film 270Rf is preferably formed by an ALD method or a vacuum evaporation method rather than a sputtering method.

As the sacrificial film 270Rf and the sacrificial film 279Rf, it is possible to use one or more of a metal film, an alloy film, a metal oxide film, a semiconductor film, an organic insulating film, and an inorganic insulating film, for example.

For each of the sacrificial film 270Rf and the sacrificial film 279Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet rays for one or both of the sacrificial film 270Rf and the sacrificial film 279Rf is preferable, in which case the EL film 172Rf can be inhibited from being irradiated with ultraviolet rays and deteriorating.

For each of the sacrificial film 270Rf and the sacrificial film 279Rf, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

Note that an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium described above. Specifically, M is preferably one or more kinds selected from gallium, aluminum, and yttrium.

As the sacrificial film, a film containing a material having a light-blocking property with respect to light, particularly ultraviolet rays, can be used. For example, a film having a reflecting property with respect to ultraviolet rays or a film absorbing ultraviolet rays can be used. Although a variety of materials such as a metal, an insulator, a semiconductor, and a metalloid that have a property of blocking ultraviolet rays can be used as the material having a light-blocking property, the sacrificial film is preferably a film capable of being processed by etching and is particularly preferably a film having good processability because part or the whole of the sacrificial film is removed in a later step.

When a film containing a material having a light-blocking property with respect to ultraviolet rays is used as the sacrificial film, the EL layer can be inhibited from being irradiated with ultraviolet rays in a light exposure step, for example. The EL layer is inhibited from being damaged by ultraviolet rays, so that the reliability of the light-emitting element can be improved.

Note that the film containing a material having a light-blocking property with respect to ultraviolet rays can have the same effect even when used as a material of an protective film 271f that is described later.

For the sacrificial film, a material with excellent compatibility with the semiconductor manufacturing process can be used. As a material with an affinity for a semiconductor manufacturing process, a semiconductor material such as silicon or germanium can be used, for example. Alternatively, an oxide or a nitride of the semiconductor material can be used. Alternatively, a non-metallic material such as carbon or a compound thereof can be used. A metal such as titanium, tantalum, tungsten, chromium, or aluminum or an alloy containing at least one of these metals can be used. Alternatively, an oxide containing the above-described metal, such as titanium oxide or chromium oxide, or a nitride such as titanium nitride, chromium nitride, or tantalum nitride can be used.

As the sacrificial film 270Rf and the sacrificial film 279Rf, a variety of inorganic insulating films that can be used as the protective layer 273 can be used. In particular, an oxide insulating film is preferable because its adhesion to the EL film 172Rf is higher than that of a nitride insulating film. For example, an inorganic insulating material such as aluminum oxide, hafnium oxide, or silicon oxide can be used for the sacrificial film 270Rf and the sacrificial film 279Rf. As the sacrificial film 270Rf or the sacrificial film 279Rf, an aluminum oxide film can be formed by an ALD method, for example. The use of an ALD method is preferable, in which case damage to a base (in particular, the EL layer) can be reduced.

For example, an inorganic insulating film (e.g., an aluminum oxide film) formed by an ALD method can be used as the sacrificial film 270Rf, and an inorganic film (e.g., an In—Ga—Zn oxide film, an aluminum film, or a tungsten film) formed by a sputtering method can be used as the sacrificial film 279Rf.

Note that the same inorganic insulating film can be used for both the sacrificial film 270Rf and the protective layer 271 that is to be formed later. For example, an aluminum oxide film formed by an ALD method can be used for both the sacrificial film 270Rf and the protective layer 271. Here, for the sacrificial film 270Rf and the protective layer 271, the same film-formation condition may be used or different film-formation conditions may be used. For example, when the sacrificial film 270Rf is formed under conditions similar to those of the protective layer 271, the sacrificial film 270Rf can be an insulating layer having a high barrier property against at least one of water and oxygen. Meanwhile, the sacrificial film 270Rf is a layer most or all of which is to be removed in a later step, and thus is preferably easy to process. Therefore, the sacrificial film 270Rf is preferably formed with a substrate temperature lower than that for formation of the protective layer 271.

One or both of the sacrificial film 270Rf and the sacrificial film 279Rf may be formed using an organic material. For example, as the organic material, a material that can be dissolved in a solvent chemically stable with respect to at least the uppermost film of the EL film 172Rf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed in a reduced-pressure atmosphere, in which case the solvent can be removed at a low temperature in a short time and thermal damage to the EL film 172Rf can be reduced accordingly.

For each of the sacrificial film 270Rf and the sacrificial film 279Rf, an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin such as perfluoropolymer may be used.

For example, an organic film (e.g., a PVA film) formed by an evaporation method or the above wet film formation method can be used as the sacrificial film 270Rf, and an inorganic film (e.g., a silicon nitride film) formed by a sputtering method can be used as the sacrificial film 279Rf.

Note that in the display device of one embodiment of the present invention, part of the sacrificial film remains as the sacrificial layer in some cases.

Then, a resist mask 180R is formed over the sacrificial film 279Rf, as illustrated in FIG. 11B. The resist mask 180R can be formed by application of a photosensitive material (photoresist), light exposure, and development. Either a positive resist material or a negative resist material may be used to form the resist mask 180R.

Next, as illustrated in FIG. 11B and FIG. 11C, part of the sacrificial film 279Rf is removed using the resist mask 180R, whereby the sacrificial layer 279R is formed. Then, the resist mask 180R is removed.

Next, as illustrated in FIG. 11C and FIG. 11D, part of the sacrificial film 270Rf is removed using the sacrificial layer 279R as a mask (also referred to as a hard mask), whereby the sacrificial layer 270R is formed.

The sacrificial film 270Rf and the sacrificial film 279Rf can be processed by a wet etching method or a dry etching method.

Using a wet etching method can reduce damage to the EL film 172Rf in processing the sacrificial film 270Rf and the sacrificial film 279Rf, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a mixed solution containing two or more of these acids, for example. In the case of using a wet etching method, a mixed acid chemical solution containing water, phosphoric acid, diluted hydrofluoric acid, and nitric acid may be used. A chemical solution used for the wet etching treatment may be alkaline or acid. By contrast, using a dry etching method can increase anisotropy as compared to the case of using a wet etching method; thus, finer processing can be performed in the case of using a dry etching method than in the case of using a wet etching method.

Since the EL film 172Rf is not exposed in processing the sacrificial film 279Rf, the range of choices of the processing method is wider than that for processing the sacrificial film 270Rf. Specifically, even in the case where a gas containing oxygen is used as the etching gas in the processing of the sacrificial film 279Rf, deterioration of the EL film 172Rf can be inhibited.

The resist mask 180R can be removed by ashing using oxygen plasma, for example. Alternatively, an oxygen gas and CF₄, C₄F₈, SF₆, CHF₃, Cl₂, H₂O, BCl₃, or a Group 18 element may be used. He can be used as the Group 18 element, for example. Alternatively, the resist mask 180R may be removed by wet etching. At this time, the sacrificial film 279Rf is positioned on the outermost surface and the EL film 172Rf is not exposed; thus, the EL film 172Rf can be inhibited from being damaged in the step of removing the resist mask 180R. In addition, the range of choices of the method for removing the resist mask 180R can be widened.

Next, as illustrated in FIG. 11C and the FIG. 11D, the EL film 172Rf is processed to form the EL layer 172R. For example, etching treatment is performed using the sacrificial layer 279R and the sacrificial layer 270R as a mask to remove part of the EL film 172Rf, so that the EL layer 172R is formed. Although not illustrated in FIG. 11D, the etching treatment performed on the EL film 172Rf sometimes forms a depressed portion in a region of the layer 363 not overlapping with the EL layer 172R.

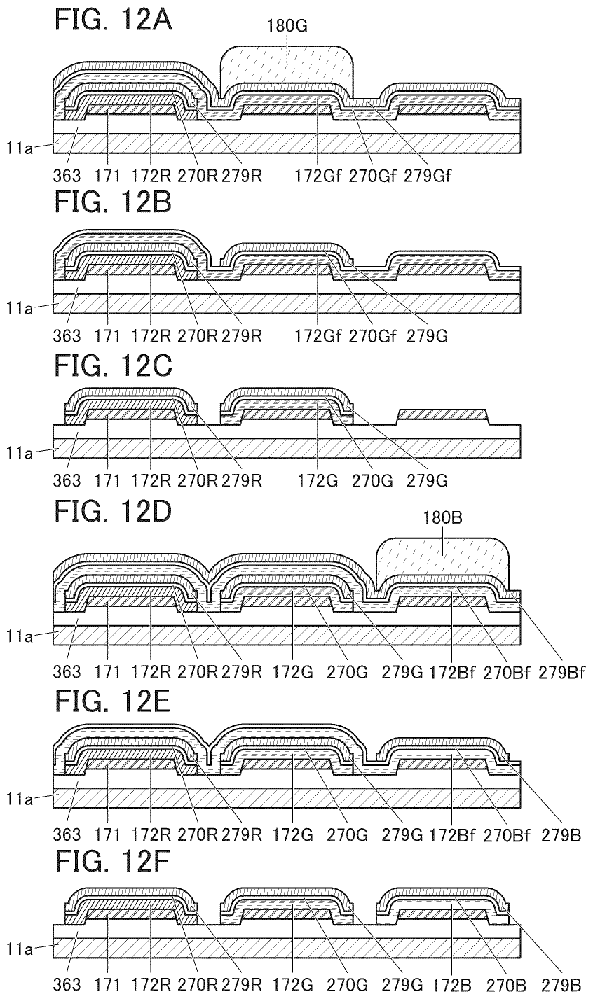

Next, as illustrated in FIG. 12A, an EL film 172Gf to be the EL layer 172G later is formed over the conductive layer 171, the sacrificial layer 279R, and the layer 363. The EL film 172Gf can be formed by a method similar to a method that can be employed to form the EL film 172Rf.

Next, as illustrated in FIG. 12A, a sacrificial film 270Gf to be the sacrificial layer 270G later and a sacrificial film 279Gf to be a sacrificial layer 279G later are sequentially formed over the EL film 172Gf. Next, a resist mask 180G is formed. The materials and the formation methods of the sacrificial film 270Gf and the sacrificial film 279Gf are similar to conditions applicable to the sacrificial film 270Rf and the sacrificial film 279Rf. The materials and the formation method of the resist mask 180G are similar to conditions applicable to the resist mask 180R.

Subsequently, as illustrated in FIG. 12A and FIG. 12B, part of the sacrificial film 279Gf is removed using the resist mask 180G, whereby the sacrificial layer 279G is formed. Then, the resist mask 180G is removed. The formation of the sacrificial layer 279G and the removal of the resist mask 180G can be performed by a method similar to that for the formation of the sacrificial layer 279R and the removal of the resist mask 180R.

Next, as illustrated in FIG. 12B and FIG. 12C, part of the sacrificial film 270Gf is removed using the sacrificial layer 279G as a mask, whereby the sacrificial layer 270G is formed. Next, the EL film 172Gf is processed to form the EL layer 172G. For example, part of the EL film 172Gf is removed by etching using the sacrificial layer 279G and the sacrificial layer 270G as a mask, whereby the EL layer 172G is formed. The formation of the sacrificial layer 270G and the formation of the EL layer 172G can be performed by a method similar to that for the formation of the sacrificial layer 270R and the formation of the EL layer 172R.

Next, as illustrated in FIG. 12D, an EL film 172Bf to be the EL layer 172B later is formed over the conductive layer 171, the sacrificial layer 279R, the sacrificial layer 279G, and the layer 363. The EL film 172Bf can be formed by a method similar to a method that can be employed to form the EL film 172Rf.

Next, as illustrated in FIG. 12D, a sacrificial film 270Bf to be the sacrificial layer 270B later and a sacrificial film 279Bf to be a sacrificial layer 279B later are formed in this order over the EL film 172Bf. Next, a resist mask 180B is formed. The materials and the formation methods of the sacrificial film 270Bf and the sacrificial film 279Bf are similar to conditions applicable to the sacrificial film 270Rf and the sacrificial film 279Rf. The materials and the formation method of the resist mask 180B are similar to conditions applicable to the resist mask 180R.

Next, as illustrated in FIG. 12D and FIG. 12E, part of the sacrificial film 279Bf is removed using the resist mask 180B, whereby the sacrificial layer 279B is formed. Then, the resist mask 180B is removed. The formation of the sacrificial layer 279B and the removal of the resist mask 180B can be performed by a method similar to the method for the formation of the sacrificial layer 279R and the removal of the resist mask 180R.

Next, as illustrated in FIG. 12E and FIG. 12F, part of the sacrificial film 270Bf is removed using the sacrificial layer 279B as a mask, whereby the sacrificial layer 270B is formed. Next, the EL film 172Bf is processed to form the EL layer 172B. For example, part of the EL film 172Bf is removed by etching using the sacrificial layer 279B and the sacrificial layer 270B as a mask, whereby the EL layer 172B is formed. The formation of the sacrificial layer 270B and the formation of the EL layer 172B can be performed by a method similar to that for the formation of the sacrificial layer 270R and the formation of the EL layer 172R.

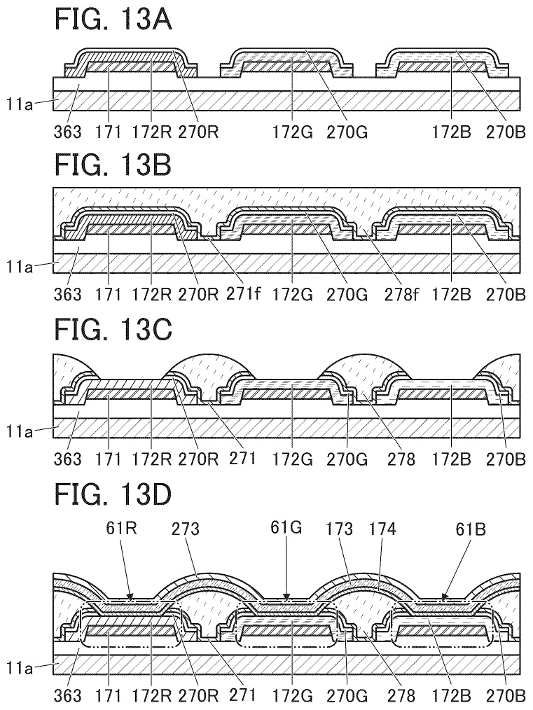

Next, as illustrated in FIG. 12F and FIG. 13A, the sacrificial layer 279R, the sacrificial layer 279G, and the sacrificial layer 279B are preferably removed. The sacrificial layer 270R, the sacrificial layer 270G, the sacrificial layer 270B, the sacrificial layer 279R, the sacrificial layer 279G, and the sacrificial layer 279B remain in the display device in some cases, depending on the later steps. Removing the sacrificial layer 279R, the sacrificial layer 279G, and the sacrificial layer 279B at this stage can prevent the sacrificial layer 279R, the sacrificial layer 279G, and the sacrificial layer 279B from remaining in the display device. For example, in the case where a conductive material is used for the sacrificial layer 279R, the sacrificial layer 279G, and the sacrificial layer 279B, removing the sacrificial layer 279R, the sacrificial layer 279G, and the sacrificial layer 279B in advance can inhibit generation of a leakage current, formation of a capacitor, and the like due to the remaining sacrificial layer 279R, sacrificial layer 279G, and sacrificial layer 279B.

Although this embodiment describes an example in which the sacrificial layer 279R, the sacrificial layer 279G, and the sacrificial layer 279B are removed, the sacrificial layer 279R, the sacrificial layer 279G, and the sacrificial layer 279B are not necessarily removed.

The step of removing the sacrificial layers can be performed by a method similar to that for the step of processing the sacrificial layers. In particular, using a wet etching method can reduce damage to the EL layer 172R, the EL layer 172G, and the EL layer 172B in removing the sacrificial layers, as compared to the case of using a dry etching method.

The sacrificial layers may be removed by being dissolved in a solvent such as water or alcohol. Examples of alcohol include ethyl alcohol, methyl alcohol, isopropyl alcohol (IPA), and glycerin.

Next, as illustrated in FIG. 13B, the protective film 271f to be the protective layer 271 later is formed to cover the EL layer 172R, the EL layer 172G, the EL layer 172B, the sacrificial layer 270R, the sacrificial layer 270G, and the sacrificial layer 270B. The protective film 271f can be formed by an ALD method, a sputtering method, a CVD method, or a PECVD method, for example, and is preferably formed by an ALD method achieving less deposition damage to the EL layer 172 and high coverage.

Then, as illustrated in FIG. 13B, an insulating film 278f to be the insulating layer 278 later is formed over the protective film 271f. For example, the insulating film 278f is preferably formed by spin coating using a photosensitive material.

Next, as illustrated in FIG. 13B and FIG. 13C, the insulating film 278f is processed to form the insulating layer 278 between the EL layers 172. Specifically, the insulating layer 278 is formed so that it overlaps with parts of the top surfaces of two EL layers 172 and includes a region positioned between the side surfaces of the two EL layers 172, for example.

When a photosensitive material such as a photoresist is used for the insulating film 278f, the insulating layer 278 can be formed by light exposure and development of the insulating film 278f In the case where a positive photosensitive material is used for the insulating film 278f, a region where the insulating layer 278 is not formed is irradiated with ultraviolet or visible light rays in the light exposure step. In the case where a negative photosensitive material is used for the insulating film 278f, a region where the insulating layer 278 is formed is irradiated with ultraviolet or visible light rays in the light exposure step.

Note that after the formation of the insulating layer 278, a residue (what is called scum) due to the development may be removed. For example, the residue can be removed by ashing using oxygen plasma. Etching may be performed so that the surface level of the insulating layer 278 is adjusted. The insulating layer 278 may be processed by ashing using oxygen plasma, for example.

Next, as illustrated in FIG. 13B and FIG. 13C, part of the protective film 271f is removed using the insulating layer 278 as a mask, whereby the protective layer 271 is formed. Part of the sacrificial layer 270R, part of the sacrificial layer 270G, and part of the sacrificial layer 270B are removed, so that openings are formed in the sacrificial layer 270R, the sacrificial layer 270G, and the sacrificial layer 270B. Thus, the top surfaces of the EL layer 172R, the EL layer 172G, and the EL layer 172B are exposed. As illustrated in FIG. 13C, the sacrificial layer 270R, the sacrificial layer 270G, and the sacrificial layer 270B remain in a region overlapping with the insulating layer 278 or the protective layer 271 in some cases.

Next, as illustrated in FIG. 13D, the common layer 174 is formed over the EL layer 172R, the EL layer 172G, the EL layer 172B, and the insulating layer 278. The common layer 174 can be formed by a method such as an evaporation method (including a vacuum evaporation method), a transfer method, a printing method, an inkjet method, or a coating method.

Next, as illustrated in FIG. 13D, the conductive layer 173 is formed over the common layer 174. The conductive layer 173 can be formed by a method such as a sputtering method or a vacuum evaporation method. Alternatively, the conductive layer 173 may be formed by stacking a film formed by a vacuum evaporation method and a film formed by a sputtering method.

Here, the conductive layer 173 can be formed successively without a process such as etching between formations of the common layer 174 and the conductive layer 173. For example, the common layer 174 and the conductive layer 173 can be successively formed in a vacuum. Accordingly, the lower surface of the conductive layer 173 can be a clean surface, as compared to the case where the common layer 174 is not provided in the display device.

Next, as illustrated in FIG. 13D, the protective layer 273 is formed over the conductive layer 173. The protective layer 273 can be formed by a method such as a vacuum evaporation method, a sputtering method, a CVD method, or an ALD method.

Then, the substrate 13a is bonded onto the protective layer 273 with the adhesive layer 122. Through the above steps, the display device having the structure illustrated in FIG. 9A can be fabricated.

In the method for fabricating the display device, the EL layer 172R, the EL layer 172G, and the EL layer 172B are formed by forming an EL film over the entire surface and then processing the EL film by a photolithography method and an etching method, for example, and a fine metal mask is not used in this fabrication method. Formation of an EL layer with a fine metal mask causes a deviation from the designed shape and position of an island-shaped light-emitting layer due to various influences such as a low accuracy of the metal mask, misalignment between the metal mask and a substrate, a warp of the metal mask, and vapor-scattering-induced expansion of the outline of a formed film; consequently, increasing the resolution and aperture ratio of a display device is difficult. As described above, a display device in which an EL layer is formed without using a fine metal mask can have higher resolution than a display device in which an EL layer is formed using a fine metal mask. In addition, the display device can have a high aperture ratio.

In this specification and the like, a device fabricated using a metal mask or an FMM (fine metal mask) is sometimes referred to as a device having an MM (metal mask) structure. In this specification and the like, a device fabricated without using a metal mask or an FMM is sometimes referred to as a device having an MML (metal maskless) structure.

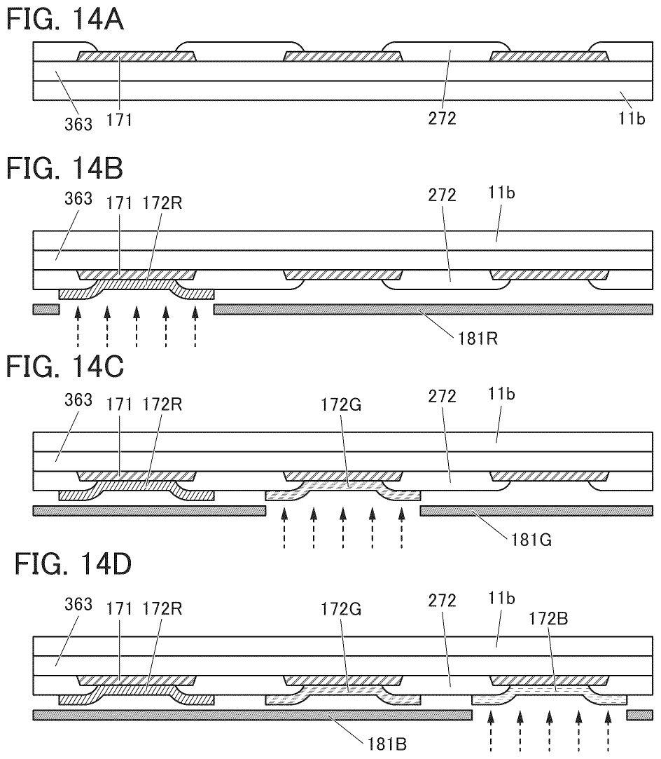

Next, an example of a method for fabricating the display device having the structure illustrated in FIG. 10A is described with reference to FIG. 14A to FIG. 14D.

First, as illustrated in FIG. 14A, the layer 363 is provided over the substrate 11b. Next, the conductive layer 171 is formed by a method similar to the method described with reference to FIG. 11A. Next, the insulating layer 272 is formed to cover the end portion of the conductive layer 171. For example, a film to be the insulating layer 272 is formed and then processed, whereby the insulating layer 272 can be formed. The film to be the insulating layer 272 can be formed by a spin coating method, a spray coating method, a screen printing method, a CVD method, a sputtering method, or a vacuum evaporation method, for example. The film to be the insulating layer 272 can be processed by a photolithography method and an etching method, for example.

Next, as illustrated in FIG. 14B, the EL layer 172R is formed using an FMM 181R. For example, the EL layer 172R is formed by a vacuum evaporation method or a sputtering method using the FMM 181R. Note that the EL layer 172R may be formed by an inkjet method. FIG. 14B illustrates a state where film formation is performed under a condition that the substrate is inverted so that a film formation surface faces downward, i.e., film formation is performed with a face-down system.

Next, as illustrated in FIG. 14C, the EL layer 172G is formed using an FMM 181G. The EL layer 172G can be formed by a method similar to that for the EL layer 172R. Similarly, as illustrated in FIG. 14D, the EL layer 172B is formed using an FMM 181B.

Here, since the EL layer 172R, the EL layer 172G, and the EL layer 172B are formed after forming the insulating layer 272, it is possible to decrease the distance between an FMM 181 (the FMM 181R, the FMM 181G, and the FMM 181B) and the conductive layer 171 while preventing contact between the FMM 181 and the conductive layer 171. Thus, the EL layer 172 can be inhibited from being larger than the opening in the FMM 181. Thus, adjacent EL layers 172 can be prevented from being in contact with each other. As described above, the reliability of the display device can be increased as compared to the case where the EL layer 172 is formed using the FMM 181 without forming the insulating layer 272.

In the case where the EL layer 172R, the EL layer 172G, and the EL layer 172B are formed using the FMM 181, formation of a sacrificial layer, processing of an EL film by a photolithography method and an etching method, and the like do not need to be performed. Thus, the display device can be fabricated by a simple method in the case where the EL layer 172R, the EL layer 172G, and the EL layer 172B are formed using the FMM 181 as compared to the case where the EL layer 172R, the EL layer 172G, and the EL layer 172B are formed without using the FMM 181. Thus, the display device can be fabricated at a low cost.

Next, the conductive layer 173 is formed over the EL layer 172R, the EL layer 172G, the EL layer 172B, and the insulating layer 272. As described above, the conductive layer 173 can be formed by a sputtering method, a vacuum evaporation method, or the like. Alternatively, the conductive layer 173 may be formed by stacking a film formed by an evaporation method and a film formed by a sputtering method.

Next, the protective layer 273 is formed over the conductive layer 173. As described above, the protective layer 273 can be formed by a method such as a vacuum evaporation method, a sputtering method, a CVD method, or an ALD method. Through the above steps, the display device illustrated in FIG. 10A can be fabricated.

Note that the EL layer 172R, the EL layer 172G, and the EL layer 172B included in the display device provided with the insulating layer 272 may be formed without the FMM 181. For example, as illustrated in FIG. 11B to FIG. 12F, the EL layer 172R, the EL layer 172G, and the EL layer 172B may be formed by forming an EL film over the entire surface and then processing the EL film by a photolithography method and an etching method, for example. In the case where the EL layer 172R, the EL layer 172G, and the EL layer 172B are formed without the FMM 181, the protective layer 271, the insulating layer 278, and the common layer 174 may be formed. Furthermore, when the continuous EL layer 172W illustrated in FIG. 10B is formed as the EL layer 172, the fabricating process of the display device can be simplified because the EL layer 172W can be formed without the FMM 181, as compared with the case where the EL layer 172W is separately formed on the light-emitting element 63W basis using the FMM 181.

At least part of the structure examples, the drawings corresponding thereto, and the like described in this embodiment can be combined with the other structure examples, the other drawings, and the like as appropriate.

At least part of this embodiment can be implemented in appropriate combination with the other embodiments described in this specification.

### Embodiment 2

In this embodiment, examples of pixel layouts of a display device of the electronic device of one embodiment of the present invention will be described.

There is no particular limitation on the arrangement of subpixels forming a pixel of the display device, and any of a variety of methods can be employed. Examples of the arrangement of the subpixels include stripe arrangement, S-stripe arrangement, matrix arrangement, delta arrangement, Bayer arrangement, and PenTile arrangement.

The top surface shape of the subpixel illustrated in a diagram in this embodiment corresponds to the top surface shape of a light-emitting region.

Examples of the top surface shape of the subpixel include polygons such as a triangle, a tetragon (including a rectangle and a square), and a pentagon; polygons with rounded corners; an ellipse; and a circle.

The range of the circuit layout for forming the subpixels is not limited to the range of the subpixels illustrated in a diagram and circuits may be placed outside the subpixels.

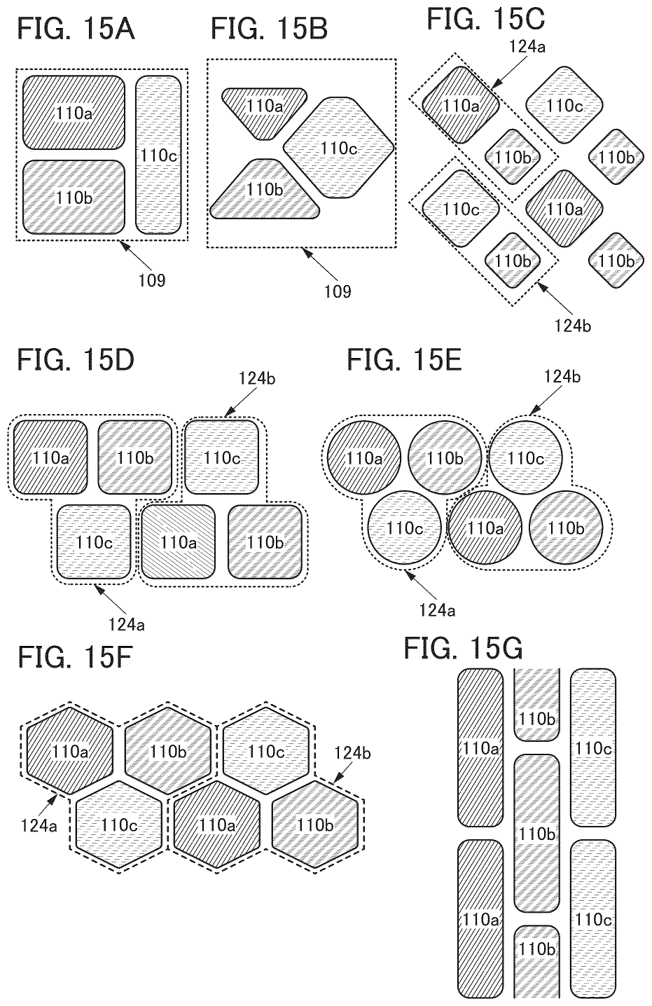

A pixel 109 illustrated in FIG. 15A employs S-stripe arrangement. The pixel 109 illustrated in FIG. 15A is composed of three subpixels: a subpixel 110a, a subpixel 110b, and a subpixel 110c.

The pixel 109 illustrated in FIG. 15B includes the subpixel 110a whose top surface has a substantial triangle with rounded corners, the subpixel 110b whose top surface has a substantial trapezoid with rounded corners, and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including alight-emitting element with higher reliability can be smaller.

A pixel 124a and a pixel 124b illustrated in FIG. 15C employ PenTile arrangement. FIG. 15C illustrates an example in which the pixels 124a each including the subpixel 110a and the subpixel 110b and the pixels 124b each including the subpixel 110b and the subpixel 110c are alternately arranged.

The pixel 124a and the pixel 124b illustrated in FIG. 15D, FIG. 15E, and FIG. 15F employ delta arrangement. The pixel 124a includes two subpixels (the subpixel 110a and the subpixel 110b) in the upper row (first row) and one subpixel (the subpixel 110c) in the lower row (second row). The pixel 124b includes one subpixel (the subpixel 110c) in the upper row (first row) and two subpixels (the subpixel 110a and the subpixel 110b) in the lower row (second row).

FIG. 15D illustrates an example in which the top surface of each subpixel has a rough tetragonal shape with rounded corners, FIG. 15E illustrates an example in which the top surface of each subpixel has a circular shape, and FIG. 15F illustrates an example in which the top surface of each subpixel has a rough hexagonal shape with rounded corners.

FIG. 15G illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the plan view.

For example, in each pixel illustrated in FIG. 15A to FIG. 15G, it is preferable that the subpixel 110a be a subpixel R emitting red light, the subpixel 110b be a subpixel G emitting green light, and the subpixel 110c be a subpixel B emitting blue light. Note that the structure of the subpixels is not limited thereto, and the colors and arrangement order of the subpixels can be determined as appropriate. For example, the subpixel 110b may be the subpixel R emitting red light and the subpixel 110a may be the subpixel G emitting green light.

In a photolithography method, as a pattern to be formed by processing becomes finer, the influence of light diffraction becomes more difficult to ignore; accordingly, the fidelity in transferring a photomask pattern by light exposure is degraded, and it becomes difficult to process a resist mask into a desired shape. Thus, a pattern with rounded corners is likely to be formed even when a photomask pattern is rectangular. Consequently, the top surface of a subpixel may have a polygonal shape with rounded corners, an elliptical shape, a circular shape, or the like.

Furthermore, in the method for fabricating the display device of one embodiment of the present invention, the EL layer is processed into an island shape using a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape after being processed. As a result, the top surface of the EL layer may have a polygonal shape with rounded corners, an elliptical shape, a circular shape, or the like. For example, when a resist mask whose top surface has a square shape is intended to be formed, a resist mask whose top surface has a circular shape may be formed, and the top surface of the EL layer may have a circular shape.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

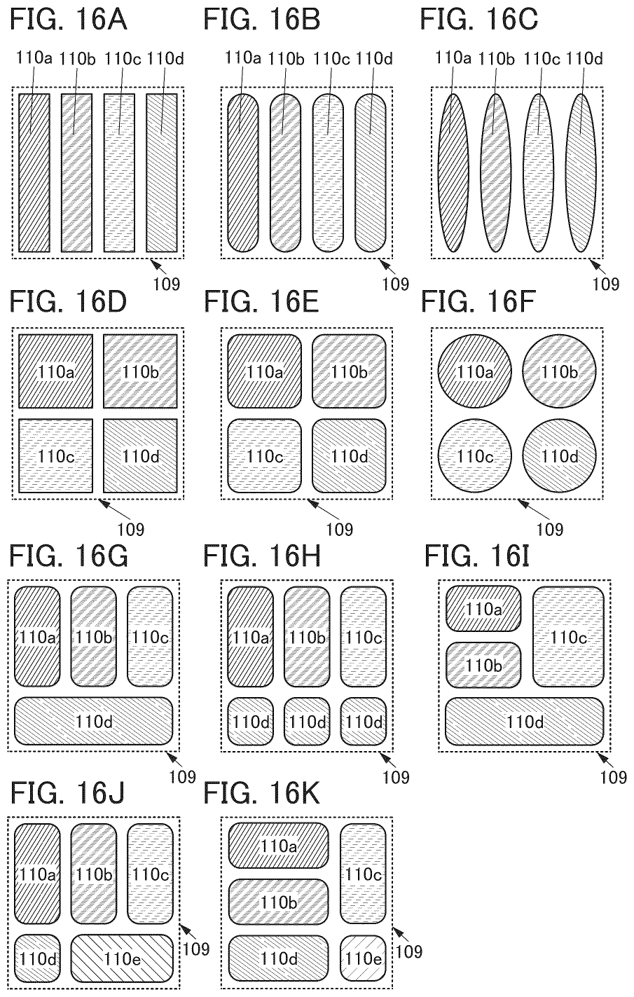

As illustrated in FIG. 16A to FIG. 16I, the pixel can include four types of subpixels.

The pixel 109 illustrated in each of FIG. 16A to FIG. 16C employs stripe arrangement.

FIG. 16A illustrates an example in which each subpixel has a rectangular top surface shape, FIG. 16B illustrates an example in which each subpixel has a top surface shape formed by combining two half circles and a rectangle, and FIG. 16C illustrates an example in which each subpixel has an elliptical top surface shape.

The pixel 109 illustrated in each of FIG. 16D to FIG. 16F employs matrix arrangement.

FIG. 16D illustrates an example in which each subpixel has a square top surface shape, FIG. 16E illustrates an example in which each subpixel has a rough square top surface shape with rounded corners, and FIG. 16F illustrates an example in which each subpixel has a circular top surface shape.

FIG. 16G and FIG. 16H each illustrate an example in which each of the pixel 109 is composed of two rows and three columns.

The pixel 109 illustrated in FIG. 16G includes three subpixels (the subpixel 110a, the subpixel 110b, and the subpixel 110c) in the upper row (first row) and one subpixel (a subpixel 110d) in the lower row (second row). In other words, the pixel 109 includes the subpixel 110a in the left column (first column), the subpixel 110b in the center column (second column), the subpixel 110c in the right column (third column), and the subpixel 110d across these three columns.

The pixel 109 illustrated in FIG. 16H includes three subpixels (the subpixel 110a, the subpixel 110b, and the subpixel 110c) in the upper row (first row) and three subpixels 110d in the lower row (second row). In other words, the pixel 109 includes the subpixel 110a and the subpixel 110d in the left column (first column), the subpixel 110b and the subpixel 110d in the center column (second column), and the subpixel 110c and the subpixel 110d in the right column (third column). Matching the positions of the subpixels in the upper row and the lower row as illustrated in FIG. 16H enables dust that would be produced in the manufacturing process, for example, to be removed efficiently. Thus, a display device with high display quality can be provided.

FIG. 16I illustrates an example in which one pixel 109 is composed of three rows and two columns.

The pixel 109 illustrated in FIG. 16I includes the subpixel 110a in the upper row (first row), the subpixel 110b in the center row (second row), the subpixel 110c across the first and second rows, and one subpixel (the subpixel 110d) in the lower row (third row). In other words, the pixel 109 includes the subpixel 110a and the subpixel 110b in the left column (first column), the subpixel 110c in the right column (second column), and the subpixel 110d across these two columns.

The pixels 109 illustrated in FIG. 16A to FIG. 16I are each composed of four subpixels: the subpixel 110a, the subpixel 110b, the subpixel 110c, and the subpixel 110d.

The subpixel 110a, the subpixel 110b, the subpixel 110c, and the subpixel 110d can include light-emitting elements emitting light of different colors. The subpixel 110a, the subpixel 110b, the subpixel 110c, and the subpixel 110d can be subpixels of four colors of R, G, B, and white (W), subpixels of four colors of R, G, B, and Y, subpixels of four colors of R, G, B, and infrared light (IR), or the like, for example.

In the pixels 109 illustrated in FIG. 16A to FIG. 16I, it is preferable that the subpixel 110a be the subpixel exhibiting red light, the subpixel 110b be the subpixel exhibiting green light, the subpixel 110c be the subpixel exhibiting blue light, and the subpixel 110d be any of a subpixel exhibiting white light, a subpixel exhibiting yellow light, and a subpixel exhibiting near-infrared light, for example. In the case of such a structure, stripe arrangement is employed as the layout of R, G, and B in the pixels 109 illustrated in FIG. 16G and FIG. 16H, leading to higher display quality. In addition, what is called S-stripe arrangement is employed as the layout of R, G, and B in the pixel 109 illustrated in FIG. 16I, leading to higher display quality.

As illustrated in FIG. 16J and FIG. 16K, the pixel can include five types of subpixels. Examples of subpixels of five colors include subpixels of five colors of R, G, B, Y, and W.

FIG. 16J illustrates an example in which one pixel 109 is composed of two rows and three columns.

The pixel 109 illustrated in FIG. 16J includes three subpixels (the subpixel 110a, the subpixel 110b, and the subpixel 110c) in the upper row (first row) and two subpixels (the subpixel 110d and a subpixel 110e) in the lower row (second row). In other words, the pixel 109 includes the subpixel 110a and the subpixel 110d in the left column (first column), the subpixel 110b in the center column (second column), the subpixel 110c in the right column (third column), and the subpixel 110e across the second and third columns.

FIG. 16K illustrates an example in which one pixel 109 is composed of three rows and two columns.

The pixel 109 illustrated in FIG. 16K includes the subpixel 110a in the upper row (first row), the subpixel 110b in the center row (second row), the subpixel 110c across the first and second rows, and two subpixels (the subpixel 110d and the subpixel 110e) in the lower row (third row). In other words, the pixel 109 includes the subpixel 110a, the subpixel 110b, and the subpixel 110d in the left column (first column), and the subpixel 110c and the subpixel 110e in the right column (second column).

As described above, the pixel composed of the subpixels each including the light-emitting element can employ any of a variety of layouts in the display device of one embodiment of the present invention.

At least part of the structure examples, the drawings corresponding thereto, and the like described in this embodiment can be combined with the other structure examples, the other drawings, and the like as appropriate.

At least part of this embodiment can be implemented in appropriate combination with the other embodiments described in this specification.

### Embodiment 3

In this embodiment, display devices of embodiments of the present invention will be described.

### [Display Module]

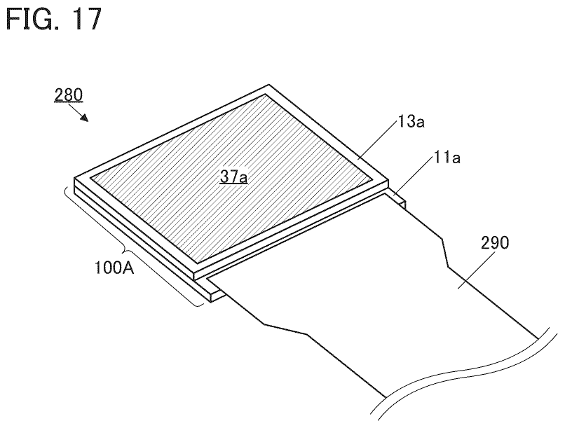

FIG. 17 is a perspective view of a display module 280. The display module 280 includes a display device 100A and an FPC 290. Note that the display device included in the display module 280 is not limited to the display device 100A and may be any of a display device 100B to a display device 100G described later. The display device 100A to the display device 100G can be suitably used for the display device 41a described in Embodiment 1. FIG. 17 illustrates the substrate 11a, the display portion 37a, and the substrate 13a among components of the display device 100A.

The FPC 290 functions as a wiring for supplying a data signal, a power supply potential, or the like to the display device 100A from the outside. An IC may be mounted on the FPC 290.

### [Display Device 100A]

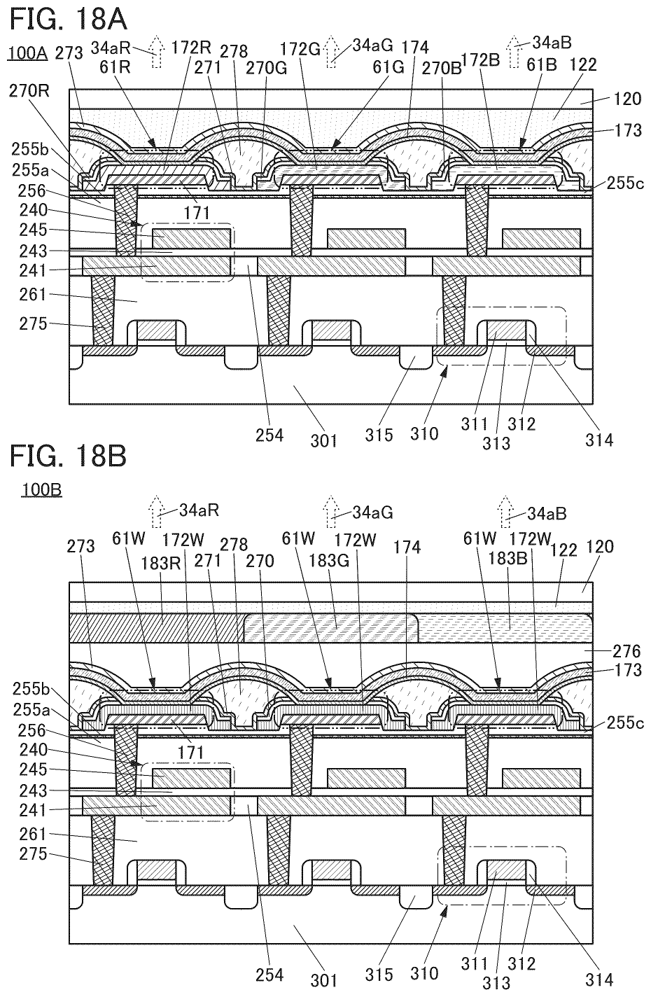

FIG. 18A is a cross-sectional view illustrating a structure example of the display device 100A, specifically, a cross-sectional view illustrating a structure example of a pixel included in the display device 100A. The display device 100A includes a substrate 301, the light-emitting element 61R, the light-emitting element 61G, the light-emitting element 61B, a capacitor 240, and a transistor 310.

The substrate 301 corresponds to the substrate 11a in FIG. 17. The transistor 310 is a transistor including a channel formation region in the substrate 301. The transistor 310 includes part of the substrate 301, a conductive layer 311, a pair of low-resistance regions 312, an insulating layer 313, and an insulating layer 314. The conductive layer 311 functions as a gate electrode. The insulating layer 313 is positioned between the substrate 301 and the conductive layer 311 and functions as agate insulating layer. The pair of low-resistance regions 312 are regions where the substrate 301 is doped with an impurity, and function as a source and a drain. The insulating layers 314 are provided to cover side surfaces of the conductive layer 311.

An element isolation layer 315 is provided between two adjacent transistors 310 so as to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned between these conductive layers. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 275 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b. The light-emitting element 61R, the light-emitting element 61G, and the light-emitting element 61B are provided over the insulating layer 255c. FIG. 18A illustrates an example where the light-emitting element 61R, the light-emitting element 61G, and the light-emitting element 61B have a structure similar to the stacked-layer structure illustrated in FIG. 9A. The light-emitting element 61R emits the light 34aR, the light-emitting element 61G emits the light 34aG, and the light-emitting element 61B emits the light 34aB. Note that the display device 100A may include, for example, the light-emitting element 63R, the light-emitting element 63G, and the light-emitting element 63B illustrated in FIG. 10A instead of the light-emitting element 61R, the light-emitting element 61G, and the light-emitting element 61B. The same applies to the display devices described below.

An insulator is provided in a region between adjacent light-emitting elements 61. For example, in FIG. 18A, the protective layer 271 and the insulating layer 278 over the protective layer 271 are provided in the region.

The EL layer 172R is provided to cover the top surface and the side surfaces of the conductive layer 171 included in the light-emitting element 61R, the EL layer 172G is provided to cover the top surface and the side surfaces of the conductive layer 171 included in the light-emitting element 61G, and the EL layer 172B is provided to cover the top surface and the side surfaces of the conductive layer 171 included in the light-emitting element 61B. The sacrificial layer 270R is positioned over the EL layer 172R, the sacrificial layer 270G is positioned over the EL layer 172G, and the sacrificial layer 270B is positioned over the EL layer 172B.

The conductive layer 171 is electrically connected to one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 275 embedded in the insulating layer 261. The top surface of the insulating layer 255c and the top surface of the plug 256 are level or substantially level with each other. A variety of conductive materials can be used for the plugs.

The protective layer 273 is provided over the light-emitting element 61R, the light-emitting element 61G, and the light-emitting element 61B. A substrate 120 is bonded to the protective layer 273 with the adhesive layer 122. The substrate 120 corresponds to the substrate 13a in FIG. 17. Note that the components from the insulating layer 261 to the adhesive layer 122 can be the layer 12a described in Embodiment 1. In addition, the components from the insulating layer 261 to the insulating layer 255c can be the layer 363 described in Embodiment 1.

A light-blocking layer may be provided on the surface of the substrate 120 on the adhesive layer 122 side. A variety of optical members can be provided on the outer surface of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer or a silica layer (SiOₓ layer) is preferably provided as the surface protective layer to inhibit the surface contamination and generation of a scratch. The surface protective layer may be formed using DLC (diamond like carbon), aluminum oxide (AlOₓ), a polyester-based material, a polycarbonate-based material, or the like. For the surface protective layer, a material having a high visible light transmittance is preferably used. The surface protective layer is preferably formed using a material with high hardness.

In the case where a circularly polarizing plate overlaps with the display device, a highly optically isotropic substrate is preferably used as the substrate included in the display device. A highly optically isotropic substrate has a low birefringence. Note that a highly optically isotropic substrate can be regarded as having a small amount of birefringence.

The absolute value of a retardation (phase difference) of a highly optically isotropic substrate is preferably less than or equal to 30 nm, further preferably less than or equal to 20 nm, still further preferably less than or equal to 10 nm.

Examples of the films having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display device might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

### [Display Device 100B]

The display device 100B illustrated in FIG. 18B includes the substrate 301, the light-emitting element 61W, the capacitor 240, and the transistor 310. FIG. 18B illustrates an example in which the light-emitting element 61W has the stacked-layer structure illustrated in FIG. 9B. In addition, the display device 100B includes the coloring layer 183R, the coloring layer 183G, and the coloring layer 183B, and one of the light-emitting elements 61W includes a region overlapping with one of the coloring layer 183R, the coloring layer 183G, and the coloring layer 183B. In the display device 100B, the light-emitting element 61W can emit white light, for example. For example, the coloring layer 183R can transmit red light, the coloring layer 183G can transmit green light, and the coloring layer 183B can transmit blue light. In this manner, the display device 100B can emit the red light 34aR, the green light 34aG, and the blue light 34aB, for example, to perform full color display.

### [Display Device 100C]

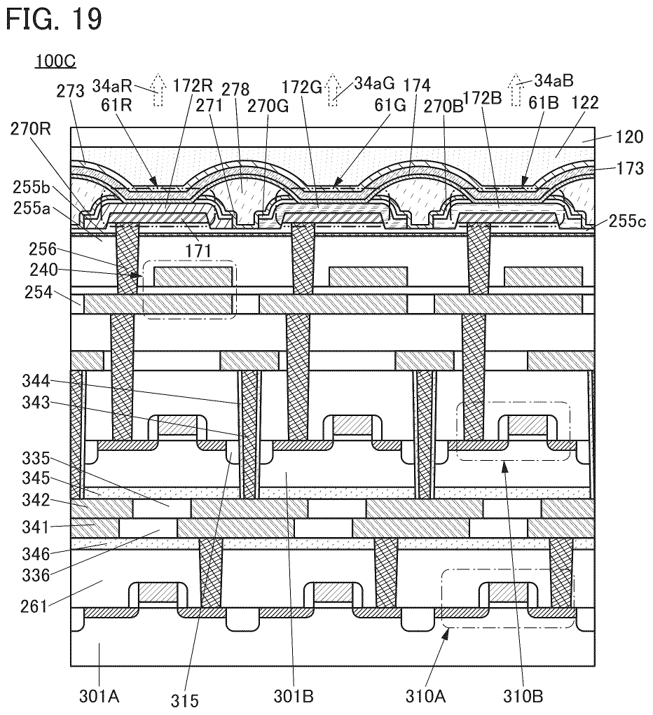

The display device 100C illustrated in FIG. 19 has a structure where a transistor 310A and a transistor 310B in each of which a channel is formed in a semiconductor substrate are stacked. Note that in the description of the display device below, portions similar to those of the above-described display device are not described in some cases.

The display device 100C has a structure in which a substrate 301B provided with the transistor 310B, the capacitor 240, and the light-emitting elements 61 is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layer 345 and the insulating layer 346 are insulating layers functioning as protective layers and can inhibit diffusion of impurities into the substrate 301B and the substrate 301A. For the insulating layer 345 and the insulating layer 346, an inorganic insulating film that can be used for the protective layer 273 can be used.

The substrate 301B is provided with a plug 343 that penetrates the substrate 301B and the insulating layer 345. An insulating layer 344 is preferably provided to cover the side surface of the plug 343. The insulating layer 344 functions as a protective layer and can inhibit diffusion of impurities into the substrate 301B. As the insulating layer 344, an inorganic insulating film that can be used as the protective layer 273 can be used.

A conductive layer 342 is provided under the insulating layer 345 on the rear surface of the substrate 301B (the surface of the substrate 301A). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Between the substrate 301A and the substrate 301B, a conductive layer 341 is provided over the insulating layer 346. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (e.g., a titanium nitride film, a molybdenum nitride film, or a tungsten nitride film). Copper is particularly preferably used for the conductive layer 341 and the conductive layer 342. In that case, it is possible to employ Cu-to-Cu (copper-to-copper) direct bonding technique (a technique for achieving electrical continuity by connecting Cu (copper) pads).

### [Display Device 100D]

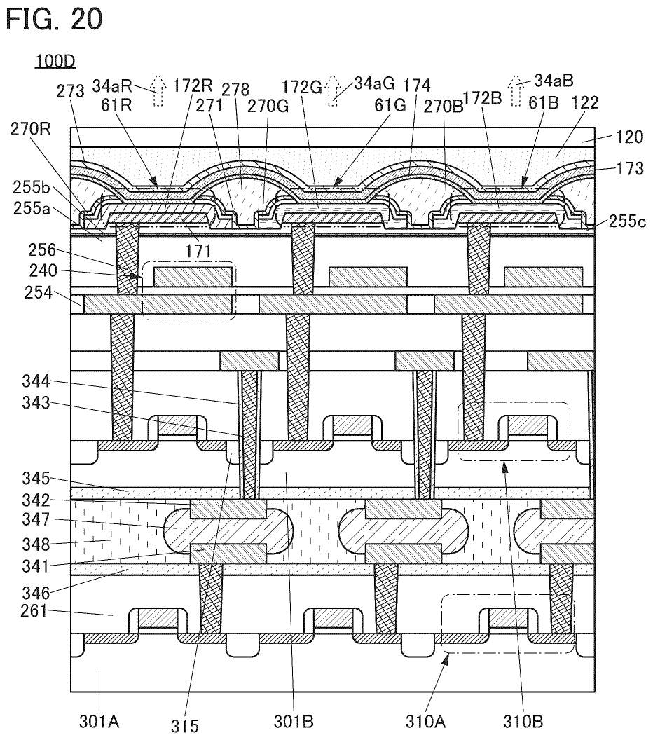

The display device 100D illustrated in FIG. 20 has a structure in which the conductive layer 341 and the conductive layer 342 are bonded to each other through a bump 347.

As illustrated in FIG. 20, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Device 100E]

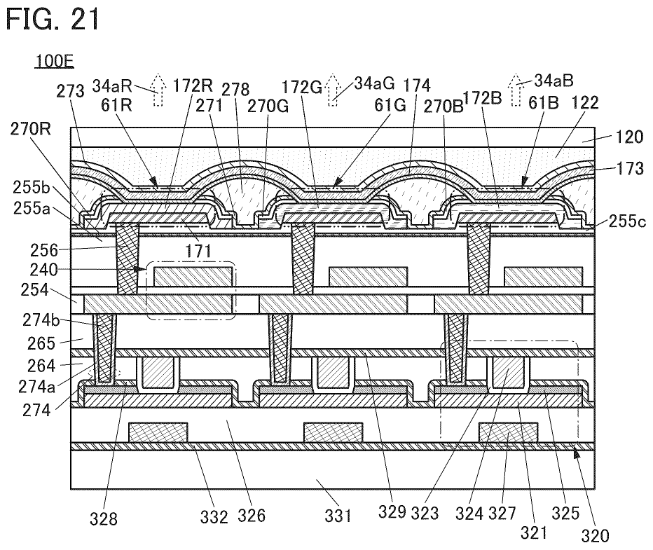

The display device 100E illustrated in FIG. 21 differs from the display device 100A mainly in a structure of a transistor.

A transistor 320 is an OS transistor. The transistor 320 includes a semiconductor layer 321, an insulating layer 323, a conductive layer 324, a pair of conductive layers 325, an insulating layer 326, and a conductive layer 327.

A substrate 331 corresponds to the substrate 11a in FIG. 17. As the substrate 331, an insulating substrate or a semiconductor substrate can be used.

An insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided so as to cover the conductive layer 327. The conductive layer 327 functions as a first gate electrode of the transistor 320, and part of the insulating layer 326 functions as a first gate insulating layer. An oxide insulating film such as a silicon oxide film is preferably used for a region of the insulating layer 326 that is in contact with at least the semiconductor layer 321. The top surface of the insulating layer 326 is preferably planarized.

The semiconductor layer 321 is provided over the insulating layer 326. The semiconductor layer 321 preferably includes a metal oxide film having semiconductor characteristics. The pair of conductive layers 325 is provided over and in contact with the semiconductor layer 321 and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The inside of the opening is filled with the insulating layer 323 that is in contact with the side surfaces of the insulating layer 264, the insulating layer 328, and the conductive layer 325 and the top surface of the semiconductor layer 321, and the conductive layer 324 over the insulating layer 323. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level or substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 and the like into the transistor 320. For the insulating layer 329, an insulating film similar to the insulating layer 328 and the insulating layer 332 can be used.

A plug 274 electrically connected to one of the pair of conductive layers 325 is provided so as to be embedded in the insulating layer 265, the insulating layer 329, the insulating layer 264, and the insulating layer 328. Here, the plug 274 preferably includes a conductive layer 274a covering the side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

Note that in the display device 100E, the components from the insulating layer 332 to the adhesive layer 122 can be the layer 12a described in Embodiment 1. In addition, the components from the insulating layer 332 to the insulating layer 255c can be the layer 363 described in Embodiment 1.

### [Display Device 100F]

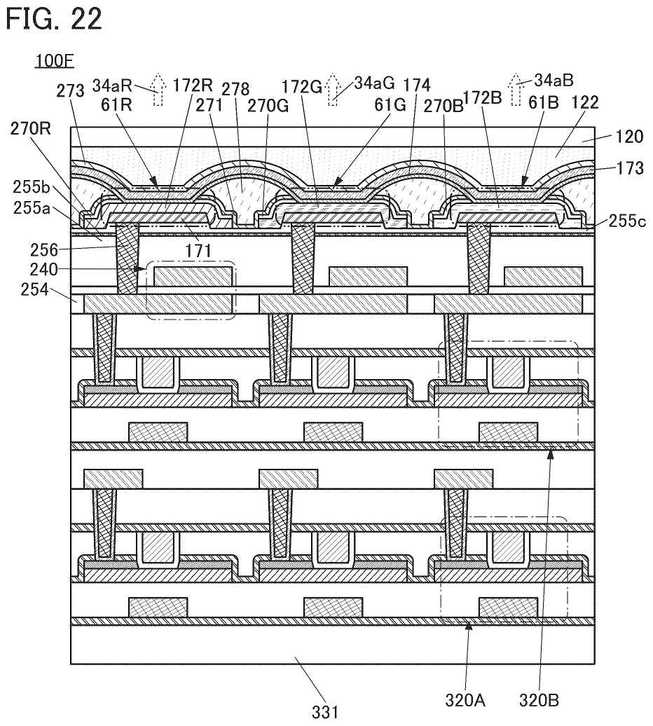

The display device 100F illustrated in FIG. 22 has a structure in which the transistor 320A and the transistor 320B each including an oxide semiconductor in a semiconductor where a channel is formed are stacked.

The description of the display device 100E can be referred to for the transistor 320A, the transistor 320B, and the components around them.

Note that although the structure where two transistors including an oxide semiconductor are stacked is described here, the present invention is not limited thereto. For example, three or more transistors may be stacked.

### [Display Device 100G]

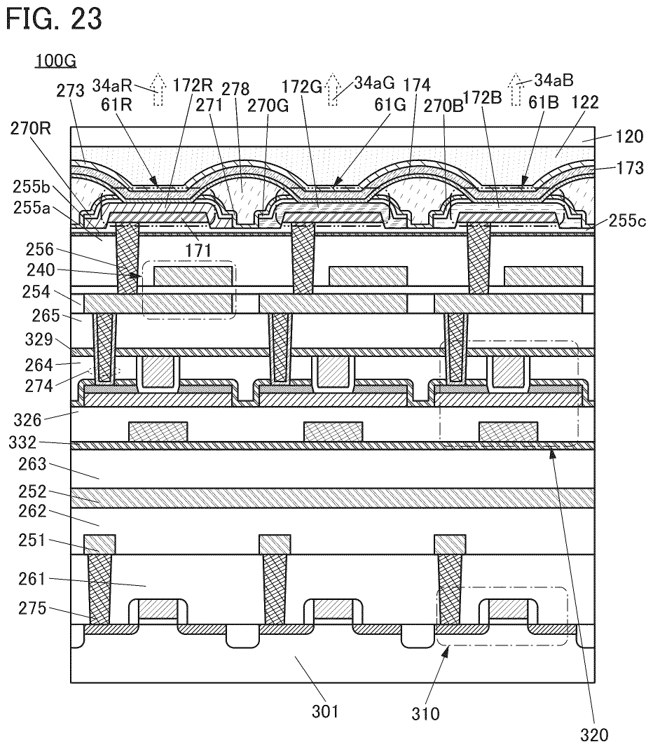

The display device 100G illustrated in FIG. 23 has a structure in which the transistor 310 having a channel formed in the substrate 301 and the transistor 320 containing a metal oxide in a semiconductor layer where a channel is formed are stacked.

The insulating layer 261 is provided so as to cover the transistor 310, and a conductive layer 251 is provided over the insulating layer 261. An insulating layer 262 is provided so as to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. An insulating layer 265 is provided so as to cover the transistor 320, and a capacitor 240 is provided over the insulating layer 265. The capacitor 240 and the transistor 320 are electrically connected to each other through the plug 274.

The transistor 320 can be used as a transistor included in the pixel circuit. In addition, the transistor 310 can be used as a transistor included in a pixel circuit or a transistor included in a driver circuit for driving the pixel circuit (e.g., a gate driver circuit or a source driver circuit). The transistor 310 and the transistor 320 can also be used as transistors included in a variety of circuits such as an arithmetic circuit and a memory circuit.

With such a structure, not only the pixel circuit but also the driver circuit, for example, can be formed directly under the light-emitting elements; thus, the display device can be downsized as compared with the case where a driver circuit is provided around a display region.

### [Display Device 100H]

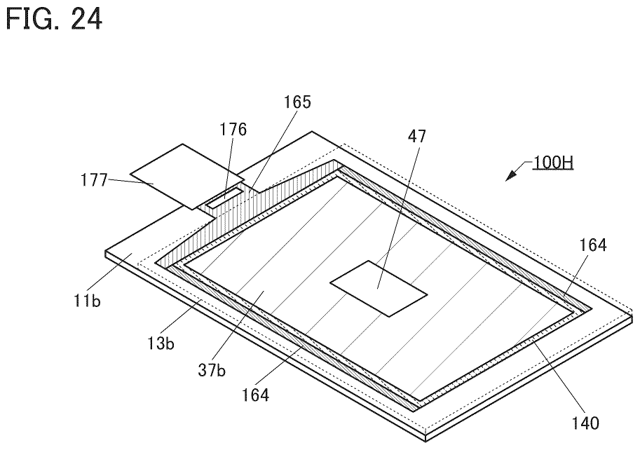

FIG. 24 is a perspective view of a display device 100H. The display device 100H can be suitably used for the display device 41b described in Embodiment 1. The same applies to a display device 100I to a display device 100M described later.

The display device 100H has a structure in which the substrate 13b and the substrate 11b are bonded to each other. In FIG. 24, the substrate 13b is denoted by a dashed line.

The display device 100H includes the display portion 37b, a connection portion 140, a circuit 164, a wiring 165, and the like. FIG. 24 illustrates an example in which an IC 176 and an FPC 177 are mounted on the display device 100H. Thus, the structure illustrated in FIG. 24 can also be regarded as a display module including the display device 100H, the IC (integrated circuit), and the FPC. Here, a display device in which a substrate is equipped with a connector such as an FPC or mounted with an IC is referred to as a display module.

The display portion 37b is provided to surround the region 47. Here, the display portion 37c described in Embodiment 1 may be provided in the region 47. The display portion 37c may be provided instead of the display portion 37b, and the display portion 37c may also be provided in the region 47.

The connection portion 140 is provided outside the display portion 37b. The connection portion 140 can be provided along one side or a plurality of sides of the display portion 37b. The number of the connection portions 140 may be one or more. FIG. 24 illustrates an example in which the connection portion 140 is provided to surround the four sides of the display portion 37b. A common electrode of a light-emitting element is electrically connected to a conductive layer in the connection portion 140, so that a potential can be supplied to the common electrode.

As the circuit 164, a gate driver circuit can be used, for example.

A signal and power can be supplied to the pixel portion 37b and the circuit 164 through the wiring 165. The signal and power are input to the wiring 165 from the outside through the FPC 177 or from the IC 176.

FIG. 24 illustrates an example where the IC 176 is provided over the substrate 11b by a COG (Chip On Glass) method, a COF (Chip On Film) method, or the like. As the IC 176, an IC functioning as a gate driver circuit, a source driver circuit, or the like can be used. Note that the display device 100H and the display module are not necessarily provided with an IC. The IC may be mounted on the FPC by a COF method, for example.

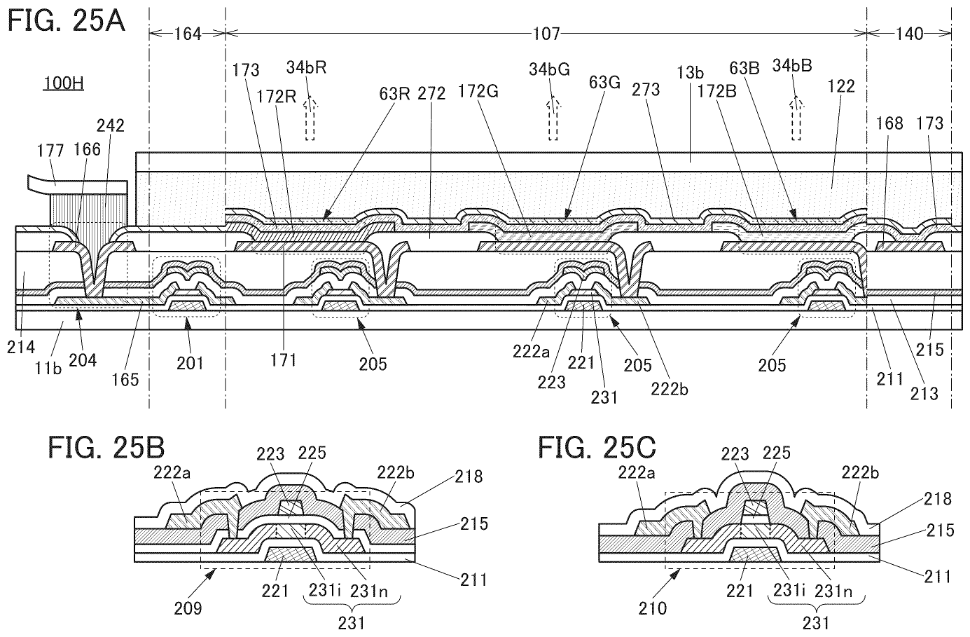

FIG. 25A illustrates an example of cross sections of part of a region including the FPC 177, part of the circuit 164, part of a display portion 107, part of the connection portion 140, and part of a region including an end portion of the display device 100H. Here, the structure of the display portion 107 can be applied to the display portion 37b illustrated in FIG. 24. In the case where the display portion 37c described in Embodiment 1 is provided in the region 47, the structure of the display portion 107 can be applied to the display portion 37c.

The display device 100H illustrated in FIG. 25A includes a transistor 201, a transistor 205, the light-emitting element 63R that emits red light 34bR, the light-emitting element 63G that emits green light 34bG, the light-emitting element 63B that emits blue light 34bB, and the like between the substrate 11b and the substrate 13b. Note that any of a variety of optical members can be arranged on the outer side of the substrate 13b. Examples of the optical members include a polarizing plate, a retardation plate, a light diffusion layer (e.g., a diffusion film), an anti-reflective layer, and a light-condensing film.

The light-emitting element 63R, the light-emitting element 63G, and the light-emitting element 63B each have the stacked-layer structure illustrated in FIG. 10A. For details of the light-emitting element 63, Embodiment 1 can be referred to.

Note that the display device 100H may include, for example, the light-emitting element 61R, the light-emitting element 61G, and the light-emitting element 61B illustrated in FIG. 9A instead of the light-emitting element 63R, the light-emitting element 63G, and the light-emitting element 63B. The same applies to the display devices described below.

The conductive layer 171 which functions as a pixel electrode and is included in the light-emitting element 63 is electrically connected to a conductive layer 222b included in the transistor 205 through an opening provided in an insulating layer 214. The conductive layer 171 is provided along the opening in the insulating layer 214. Thus, a depressed portion is provided in the conductive layer 171.

FIG. 25A illustrates an example in which the insulating layer 272 is provided to cover an end portion of the conductive layer 171. The insulating layer 272 can be provided to fill the depression portion of the conductive layer 171.

The protective layer 273 is provided over the light-emitting element 63R, the light-emitting element 63G, and the light-emitting element 63B. The protective layer 273 and the substrate 13b are bonded to each other with an adhesive layer 122. A solid sealing structure, a hollow sealing structure, or the like can be employed to seal the light-emitting elements 63. In FIG. 25A, a solid sealing structure is employed in which a space between the substrate 13b and the protective layer 273 is filled with the adhesive layer 122. Alternatively, a hollow sealing structure in which the space is filled with an inert gas (e.g., nitrogen or argon) may be employed. Here, the adhesive layer 122 may be provided not to overlap with the light-emitting elements. The space may be filled with a resin different from that of the frame-shaped adhesive layer 122.

FIG. 25A illustrates an example in which the connection portion 140 includes a conductive layer 168 obtained by processing the same conductive film as the conductive film to be the conductive layer 171. The conductive layer 168 is supplied with a power supply potential and is electrically connected to the conductive layer 173 functioning as a common electrode. Thus, a power supply potential can be supplied to the conductive layer 173 through the conductive layer 168.

The display device 100H has a top-emission structure. Light emitted from the light-emitting element is emitted toward the substrate 13b side. The conductive layer 171 functioning as a pixel electrode contains a material that reflects visible light, and the conductive layer 173 functioning as a common electrode contains a material that transmits visible light.

The transistor 201 and the transistor 205 are formed over the substrate 11b. These transistors can be fabricated using the same material in the same process. Note that the components from the transistor 201 and the transistor 205 to the adhesive layer 122 can be the layer 12b described in Embodiment 1. In addition, the components from the transistor 201 and the transistor 205 to the insulating layer 214 can be the layer 363 described in Embodiment 1.

An insulating layer 211, an insulating layer 213, an insulating layer 215, and the insulating layer 214 are provided in this order over the substrate 11b. Part of the insulating layer 211 functions as a first gate insulating layer of each transistor. Part of the insulating layer 213 functions as a second gate insulating layer of each transistor. The insulating layer 215 is provided to cover the transistors. The insulating layer 214 is provided to cover the transistors and has a function of a planarization layer. Note that there is no limitation on the number of gate insulating layers and the number of insulating layers covering the transistors, and each insulating layer may have either a single layer or two or more layers.

A material in which impurities such as water and hydrogen do not easily diffuse is preferably used for at least one of the insulating layers covering the transistors. This is because such an insulating layer can function as a barrier layer. Such a structure can effectively inhibit diffusion of impurities into the transistors from the outside and can increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. Thus, the formation of a depression portion in the insulating layer 214 can be inhibited in processing a conductive film to be the conductive layer 171, for example. Note that the insulating layer 214 may be provided with a depressed portion in processing the conductive film to be the conductive layer 171, for example.

Each of the transistor 201 and the transistor 205 includes a conductive layer 221 functioning as a gate, the insulating layer 211 functioning as a first gate insulating layer, a conductive layer 222a and a conductive layer 222b functioning as a source and a drain, a semiconductor layer 231, the insulating layer 213 functioning as a second gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The transistor 201 and the transistor 205 employ a structure where the semiconductor layer where a channel is formed is provided between two gates. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor layer of the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes a metal oxide. That is, an OS transistor is preferably used as the transistor included in the display device of this embodiment.

Examples of the metal oxide that can be used for the semiconductor layer include indium oxide, gallium oxide, and zinc oxide. The metal oxide preferably includes two or three selected from indium, an element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

When the metal oxide used for the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and InM:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. Gallium or aluminum is preferably used as the element M.

Alternatively, a stacked-layer structure of one selected from indium oxide, indium gallium oxide, and IGZO, and one selected from IAZO, IAGZO, and ITZO (registered trademark) may be employed, for example.

As the oxide semiconductor having crystallinity, a CAAC (c-axis aligned crystalline)-OS, an nc (nanocrystalline)-OS, and the like can be given.

Alternatively, a transistor containing silicon in its channel formation region (a Si transistor) may be used. As silicon, single crystal silicon, polycrystalline silicon, amorphous silicon, and the like can be given. In particular, a transistor containing low-temperature polysilicon (LTPS) in a semiconductor layer (such a transistor is referred to as an LTPS transistor below) can be used. The LTPS transistor has high field-effect mobility and excellent frequency characteristics.

With the use of a Si transistor such as an LTPS transistor, a circuit required to be driven at a high frequency (e.g., a source driver circuit) can be formed on the same substrate as the display portion. Thus, external circuits mounted on the display device can be simplified, and parts costs and mounting costs can be reduced.

An OS transistor has much higher field-effect mobility than a transistor using amorphous silicon. In addition, an OS transistor has an extremely low leakage current between a source and a drain in an off state (hereinafter also referred to as off-state current), and charge accumulated in a capacitor that is connected in series to the transistor can be retained for a long period. Furthermore, power consumption of the display device can be reduced with the use of an OS transistor.

To increase the emission luminance of the light-emitting element included in the pixel circuit, the amount of current fed through the light-emitting element needs to be increased. For this, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When a transistor is driven in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be minutely determined by controlling the gate-source voltage. Thus, the amount of current flowing through the light-emitting element can be controlled. Accordingly, the number of gray levels in the pixel circuit can be increased.

Regarding saturation characteristics of current flowing when a transistor is driven in a saturation region, even in the case where the source-drain voltage of an OS transistor increases gradually, more stable current (saturation current) can be made flow through an OS transistor than through a Si transistor. Thus, by using an OS transistor as the driving transistor, a stable current can be fed through light-emitting elements even when the current-voltage characteristics of the organic EL devices vary, for example. In other words, when the OS transistor is driven in the saturation region, the source-drain current hardly changes with an increase in the source-drain voltage. Hence, the luminance of the light-emitting element can be stable.

As described above, with the use of an OS transistor as a driving transistor included in the pixel circuit, it is possible to achieve “inhibition of black-level degradation,” “increase in emission luminance,” “increase in gray level,” “inhibition of variation in light-emitting elements,” and the like.

The transistor included in the circuit 164 and the transistor included in the display portion 107 may have the same structure or different structures. A plurality of transistors included in the circuit 164 may have the same structure or two or more kinds of structures. Similarly, one structure or two or more types of structures may be employed for a plurality of transistors included in the display portion 107.

All the transistors included in the display portion 107 may be OS transistors or all the transistors included in the display portion 107 may be Si transistors. Alternatively, some of the transistors included in the display portion 107 may be OS transistors and the others may be Si transistors.

For example, when both an LTPS transistor and an OS transistor are used in the display portion 107, the display device can have low power consumption and high driving capability. A structure in which an LTPS transistor and an OS transistor are used in combination is referred to as LTPO in some cases. For example, preferably, an OS transistor is used as a transistor functioning as a switch for controlling conduction and non-conduction between wirings and an LTPS transistor is used as a transistor for controlling current.

For example, one of the transistors included in the display portion 107 functions as a transistor for controlling a current flowing through the light-emitting element and can be referred to as a driving transistor. One of a source and a drain of the driving transistor is electrically connected to the pixel electrode of the light-emitting element. An LTPS transistor is preferably used as the driving transistor. In that case, the amount of current flowing through the light-emitting element can be increased in the pixel circuit.

Another transistor included in the display portion 107 functions as a switch for controlling selection and non-selection of the pixel and can also be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting element having an MML structure. With this structure, the leakage current that might flow through the transistor and the leakage current that might flow between adjacent light-emitting elements can be extremely low. With the structure, a viewer can notice any one or more of the image crispness, the image sharpness, a high chroma, and a high contrast ratio in an image displayed on the display device. When the leakage current that would flow through the transistor and the lateral leakage current between the light-emitting elements are extremely low, light leakage that might occur in black display (what is called black-level degradation) or the like can be minimized, for example.

In particular, in the case where a light-emitting element having the MML structure employs the above-described SBS structure, a layer provided between light-emitting elements is disconnected; accordingly, side leakage can be prevented or be made extremely low.

FIG. 25B and FIG. 25C illustrate other structure examples of transistors.

Each of a transistor 209 and a transistor 210 includes the conductive layer 221 functioning as a gate, the insulating layer 211 functioning as a first gate insulating layer, the semiconductor layer 231 including a channel formation region 231i and a pair of low-resistance regions 231n, the conductive layer 222a electrically connected to one of the pair of low-resistance regions 231n, the conductive layer 222b electrically connected to the other of the pair of low-resistance regions 231n, an insulating layer 225 functioning as a second gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 25B illustrates an example of the transistor 209 in which the insulating layer 225 covers the top and side surfaces of the semiconductor layer 231. The conductive layer 222a and the conductive layer 222b are electrically connected to the low-resistance regions 231n through openings provided in the insulating layer 225 and the insulating layer 215. One of the conductive layer 222a and the conductive layer 222b functions as a source, and the other of the conductive layer 222a and the conductive layer 222b functions as a drain.

Meanwhile, in the transistor 210 illustrated in FIG. 25C, the insulating layer 225 overlaps with the channel formation region 231i of the semiconductor layer 231 and does not overlap with the low-resistance regions 231n. The structure illustrated in FIG. 25C can be fabricated by processing the insulating layer 225 using the conductive layer 223 as a mask, for example. In FIG. 25C, the insulating layer 215 is provided to cover the insulating layer 225 and the conductive layer 223, and the conductive layer 222a and the conductive layer 222b are electrically connected to the low-resistance regions 231n through the openings in the insulating layer 215.

A connection portion 204 is provided in a region of the substrate 11b not overlapping with the substrate 13b. In the connection portion 204, the wiring 165 is electrically connected to the FPC 177 through a conductive layer 166 and a connection layer 242. The conductive layer 166 can be a conductive layer obtained by processing the same conductive film as the conductive film to be the conductive layer 171. On the top surface of the connection portion 204, the conductive layer 166 is exposed. Thus, the connection portion 204 and the FPC 177 can be electrically connected to each other through the connection layer 242.

The material that can be used for the substrate 120 can be used for each of the substrate 11b and the substrate 13b.

As the connection layer 242, an anisotropic conductive film (ACF), an anisotropic conductive paste (ACP), or the like can be used.

### [Display Device 100I]

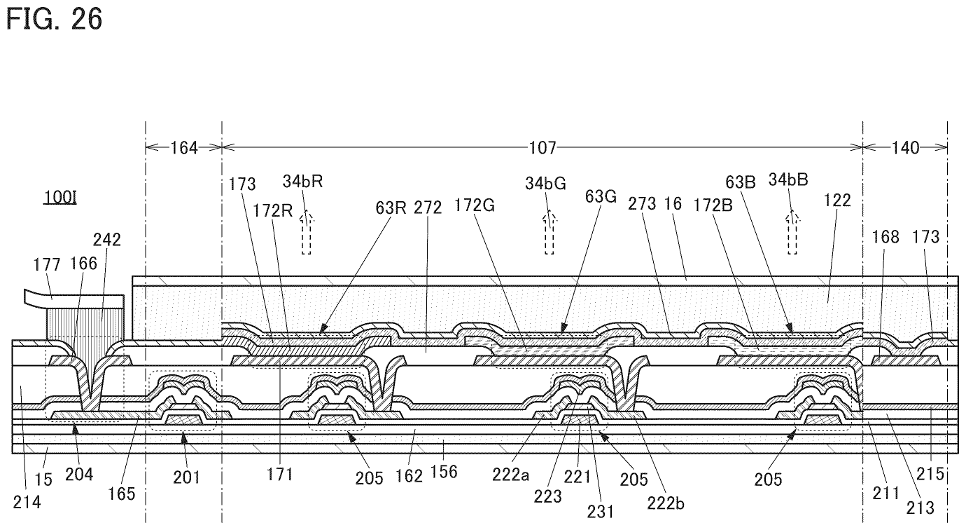

The display device 100I illustrated in FIG. 26 is a modification example of the display device 100H illustrated in FIG. 25A, which is different from the display device 100H in that the substrate 15 is provided instead of the substrate 11b and the substrate 16 is provided instead of the substrate 13b.

The substrate 15 and the substrate 16 have flexibility. Accordingly, the display device 100I has flexibility. That is, the display device 100I is a flexible display. The substrate 15 is bonded to an insulating layer 162 with an adhesive layer 156, and the transistor 201 and the transistor 205 are provided over the insulating layer 162. For the adhesive layer 156, a material similar to the material that can be used for the adhesive layer 122 can be used. For the insulating layer 162, the same material as the material that can be used for the insulating layer 211, the insulating layer 213, or the insulating layer 215 can be used. Note that in the display device 100I, the components from the adhesive layer 156 to the adhesive layer 122 can be the layer 12b described in Embodiment 1. The components from the adhesive layer 156 to the insulating layer 214 can be the layer 363 described in Embodiment 1.

As a method for fabricating the display device 100I illustrated in FIG. 26, first, the insulating layer 162 is formed over a formation substrate, and transistors, the light-emitting elements 63, and the like are formed over the insulating layer 162. Next, the substrate 16 is bonded to the light-emitting elements 63 with the adhesive layer 122, for example. Then, the substrate 15 is bonded to a surface exposed by separation of the formation substrate with the adhesive layer 156, whereby the components formed over the formation substrate are transferred onto the substrate 15. In the above manner, the display device 100I can be fabricated.

### [Display Device 100J]

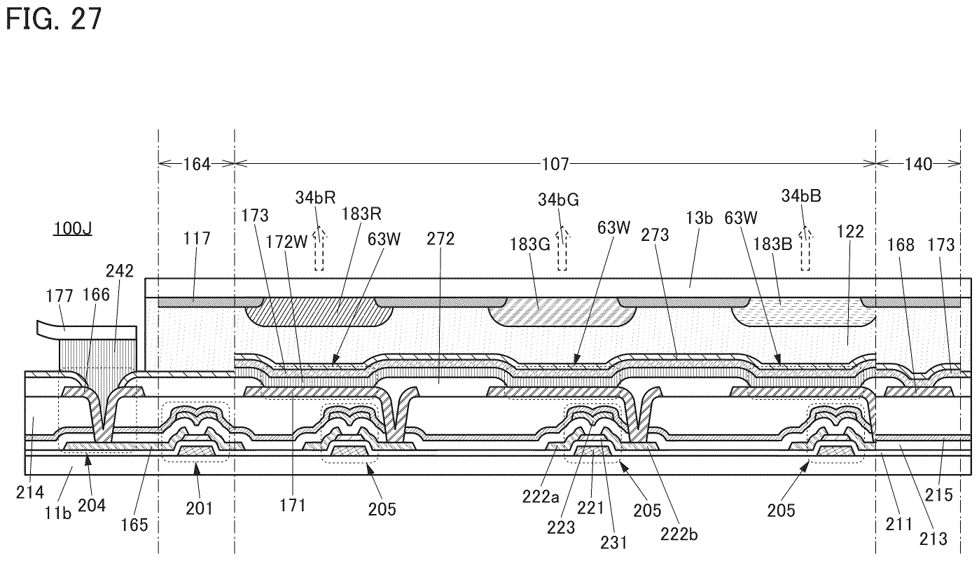

The display device 100J illustrated in FIG. 27 is a modification example of the display device 100H illustrated in FIG. 25A and differs from the display device 100H mainly in that the light-emitting element 63W is provided as a light-emitting element and the coloring layer 183R, the coloring layer 183G, and the coloring layer 183B are included. FIG. 27 illustrates an example in which the light-emitting element 63W has the stacked-layer structure illustrated in FIG. 10B.

In the display device 100J, one light-emitting element 63W includes a region overlapping with one of the coloring layer 183R, the coloring layer 183G, and the coloring layer 183B. The coloring layer 183R, the coloring layer 183G, and the coloring layer 183B can be provided on a surface of the substrate 13b on the substrate 11b side.

In the display device 100J, the light-blocking layer 117 is provided in a region of the display portion 107 where the coloring layer 183R, the coloring layer 183G, and the coloring layer 183B are not provided. Furthermore, in the display device 100J, the light-blocking layer 117 can also be provided in the connection portion 140 and the circuit 164. Note that the light-blocking layer 117 can also be provided in the display device 100H or the display device 100I.

In the display device 100J, the light-emitting element 63W can emit white light, for example. For example, the coloring layer 183R can transmit red light, the coloring layer 183G can transmit green light, and the coloring layer 183B can transmit blue light. In this manner, the display device 100J can emit the red light 34bR, the green light 34bG, and the blue light 34bB, for example, to perform full color display.

### [Display Device 100K]

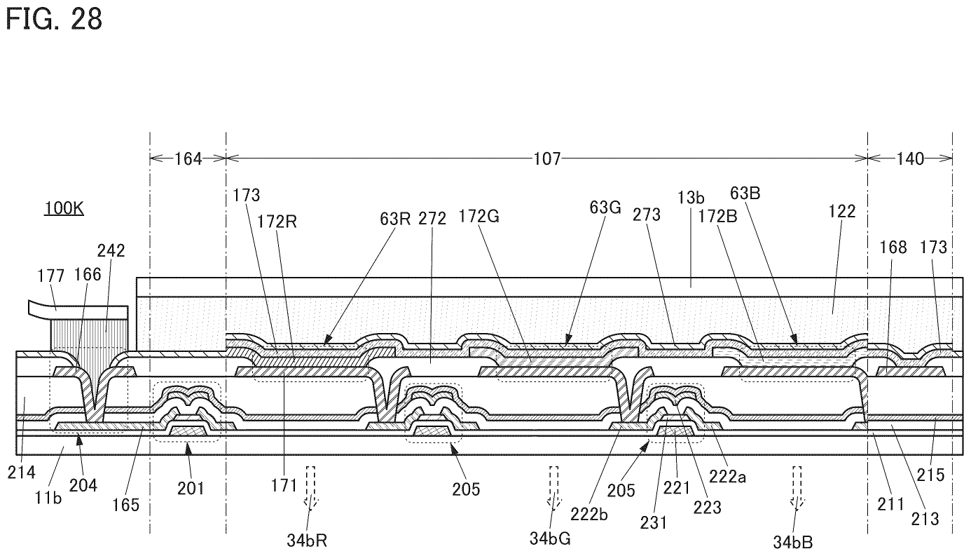

The display device 100K illustrated in FIG. 28 is a modification example of the display device 100H illustrated in FIG. 25A and differs from the display device 100H mainly in being a bottom-emission display device.

The light 34bR, the light 34bG, and the light 34bB are emitted to the substrate 11b side. For the conductive layer 171, a material having a high transmitting property with respect to visible light is used. By contract, a material reflecting visible light is preferably used for the conductive layer 173.

### [Display Device 100L]

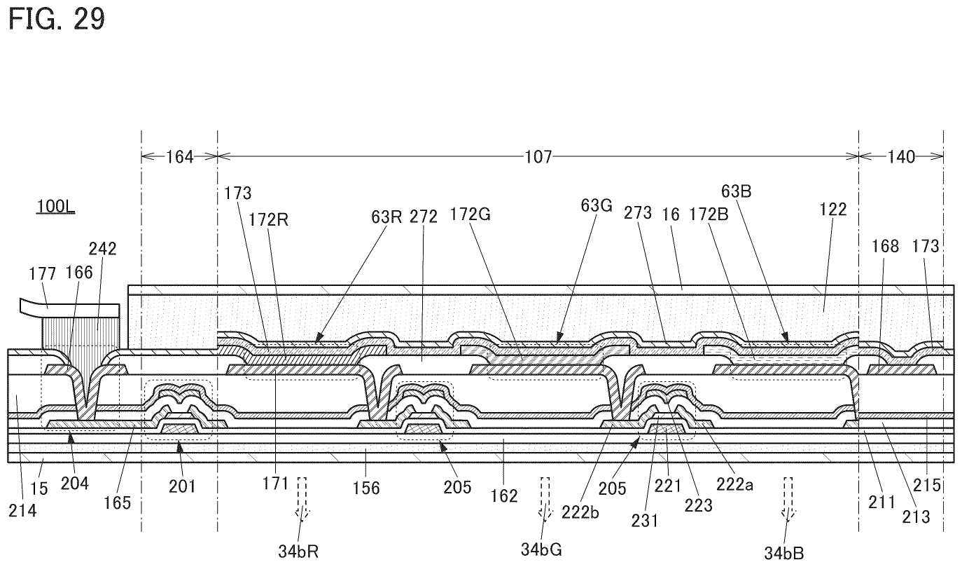

The display device 100L illustrated in FIG. 29 is a modification example of the display device 100I illustrated in FIG. 26 and differs from the display device 100I mainly in being a bottom-emission display device like the display device 100K illustrated in FIG. 28.

In the display device 100L, the components from the adhesive layer 156 to the adhesive layer 122 can be the layer 12b described in Embodiment 1. The components from the adhesive layer 156 to the insulating layer 214 can be the layer 363 described in Embodiment 1.

Here, in the case where the display portion 107 of the display device 100K or the display device 100L is used in the display portion 37c described in Embodiment 1, the conductive layer 173 has a transmitting property with respect to visible light. In addition, at least some of the layers included in the transistor 205 preferably have a transmitting property with respect to visible light. For example, the conductive layer 222a and the conductive layer 222b preferably have a transmitting property with respect to visible light. In the case where the substrate 11b, the insulating layer 211, the insulating layer 213, the insulating layer 215, the insulating layer 214, the insulating layer 272, the protective layer 273, the adhesive layer 122, and the substrate 13b have a transmitting property with respect to visible light, the display portion 107 included in the display device 100K transmits external light. In the case where the substrate 15, the adhesive layer 156, the insulating layer 162, the insulating layer 211, the insulating layer 213, the insulating layer 215, the insulating layer 214, the insulating layer 272, the protective layer 273, the adhesive layer 122, and the substrate 16 have a transmitting property with respect to visible light, the display portion 107 included in the display device 100L transmits external light. Specifically, the display portion 107 included in the display device 100K or the display device 100L can transmit the light 34a emitted from the display portion 37a included in the display device 41a described in Embodiment 1. Thus, the user of the electronic device 10 can see an image displayed on the display portion 37a described in Embodiment 1 through the display portion 107.

The conductive layer 221 and the conductive layer 223 may have a transmitting property with respect to visible light and a reflecting property with respect to visible light. When the conductive layer 221 and the conductive layer 223 have a transmitting property with respect to visible light, the transmittance of visible light in the display portion 107 can be increased. Meanwhile, when the conductive layer 221 and the conductive layer 223 have a reflecting property with respect to visible light, the visible light can be inhibited from entering the semiconductor layer 231. Thus, damage to the semiconductor layer 231 can be reduced, leading to an increase in the reliability of the display device 100K or the display device 100L.

Even in a top-emission display device such as the display device 100H or the display device 100I, at least some of the layers included in the transistor 205 may have a transmitting property with respect to visible light. In that case, the conductive layer 171 also has a transmitting property with respect to visible light. As a result, the visible-light transmittance of the display portion 107 can be increased.

### [Display Device 100M]

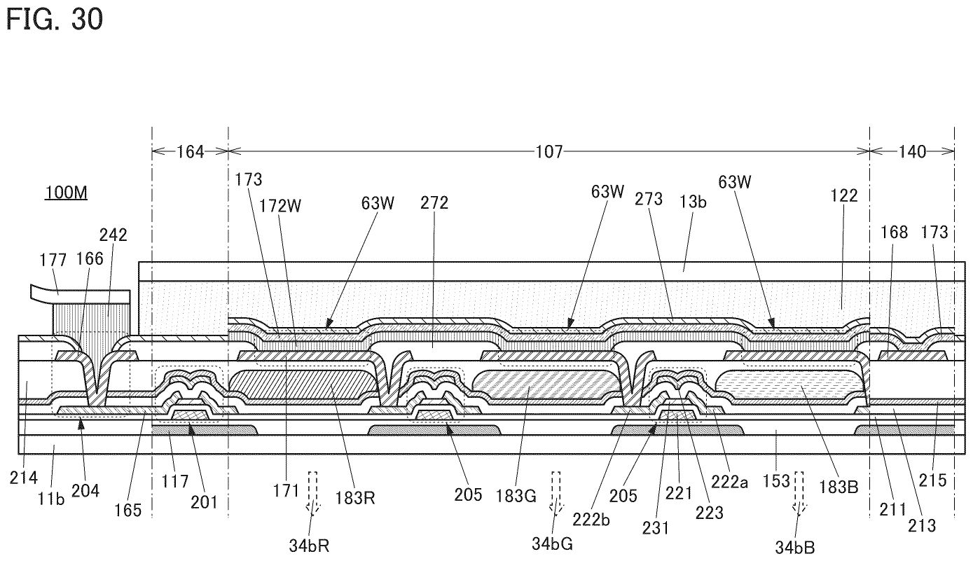

The display device 100M illustrated in FIG. 30 is a modification example of the display device 100J illustrated in FIG. 27 and differs from the display device 100J mainly in being a bottom-emission display device like the display device 100K illustrated in FIG. 28.

The coloring layer 183R, the coloring layer 183G, and the coloring layer 183B are provided between the light-emitting element 63W and the substrate 11b. FIG. 30 illustrates an example in which the coloring layer 183R, the coloring layer 183G, and the coloring layer 183B are provided between the insulating layer 215 and the insulating layer 214.

In the display device 100M, the light-blocking layer 117 is provided between the substrate 11b and the transistor 205. The light-blocking layer 117 can be provided in a region not overlapping with a light-emitting region of the light-emitting element 63W. FIG. 30 illustrates an example in which the light-blocking layer 117 is provided over the substrate 11b, an insulating layer 153 is provided over the light-blocking layer 117, and the transistor 201, the transistor 205, and the like are provided over the insulating layer 153. Note that as illustrated in FIG. 30, the light-blocking layer 117 can also be provided in the connection portion 140 and the circuit 164.

The light-blocking layer 117 can also be provided in the display device 100K or the display device 100L. In that case, light emitted from the light-emitting element 63R, the light-emitting element 63G, and the light-emitting element 63B can be inhibited from being reflected by the substrate 11b and being diffused inside the display device 100K or the display device 100L, for example. Accordingly, the display device 100K and the display device 100L can be display devices with high display quality. Meanwhile, when the light-blocking layer 117 is not provided, the extraction efficiency of light emitted from the light-emitting element 63R, the light-emitting element 63G, and the light-emitting element 63B can be increased.

In the display device 100H to the display device 100M, the pixel density is more difficult to increase while the area occupied by the display portion can be larger than in the display device 100A to the display device 100G. Thus, the display device 100A to the display device 100G are preferably used as the display device 41a described in Embodiment 1, and the display device 100H to the display device 100M are preferably used as the display device 41b. Note that the display device 100A to the display device 100G may be used as the display device 41b. The display device 100H to the display device 100M may be used as the display device 41a. For example, in the case where the occupied area required for the display portion 37b included in the display device 41b is the size which can be achieved with the display device 100A to the display device 100G, the display device 100A to the display device 100G can be used as the display device 41b. In the case where the pixel density required for the display portion 37a included in the display device 41a can be achieved with the display device 100H to the display device 100M, the display device 100H to the display device 100M can be used as the display device 41a.

At least part of the structure examples, the drawings corresponding thereto, and the like described in this embodiment can be combined with the other structure examples, the other drawings, and the like as appropriate.

At least part of this embodiment can be implemented in appropriate combination with the other embodiments described in this specification.

### Embodiment 4

In this embodiment, a light-emitting element that can be used for a display device of one embodiment of the present invention will be described with reference to drawings.

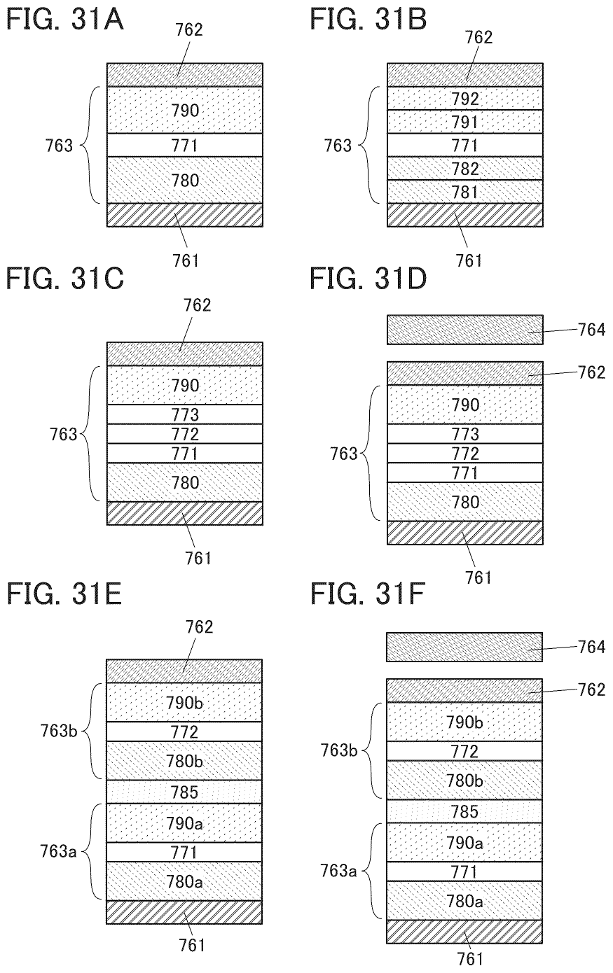

As illustrated in FIG. 31A, the light-emitting element includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance.

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 31A is referred to as a single structure in this specification and the like.

FIG. 31B is a modification example of the EL layer 763 included in the light-emitting elements illustrated in FIG. 31A. Specifically, the light-emitting element illustrated in FIG. 31B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 as illustrated in FIG. 31C and FIG. 31D are variations of the single structure. Although FIG. 31C and FIG. 31D illustrate the examples where three light-emitting layers are included, the light-emitting device with a single structure may include two or four or more light-emitting layers. In addition, the light-emitting element with a single structure may include a buffer layer between two light-emitting layers.

A structure where a plurality of light-emitting units (a light-emitting unit 763a and a light-emitting unit 763b) are connected in series with a charge-generation layer 785 (also referred to as an intermediate layer) therebetween as illustrated in FIG. 31E and FIG. 31F is referred to as a tandem structure in this specification and the like. Note that a tandem structure may be referred to as a stack structure. The tandem structure enables a light-emitting element capable of high-luminance light emission. Furthermore, the tandem structure can reduce the amount of current needed for obtaining the same luminance as compared with a single structure, and thus can improve the reliability.

Note that FIG. 31D and FIG. 31F illustrate examples where the display device includes a layer 764 overlapping with the light-emitting element. FIG. 31D illustrates an example in which the layer 764 overlaps with the light-emitting element illustrated in FIG. 31C, and FIG. 31F illustrates an example in which the layer 764 overlaps with the light-emitting element illustrated in FIG. 31E. In FIG. 31D and FIG. 31F, a conductive film transmitting visible light is used for the upper electrode 762 to extract light to the upper electrode 762 side.

One or both of a color conversion layer and a color filter (a coloring layer) can be used as the layer 764.

In FIG. 31C and FIG. 31D, light-emitting substances emitting light of the same color, or moreover, the same light-emitting substance may be used for the light-emitting layer 771, the light-emitting layer 772, and the light-emitting layer 773. For example, a light-emitting substance exhibiting blue light may be used for each of the light-emitting layer 771, the light-emitting layer 772, and the light-emitting layer 773. In a subpixel exhibiting blue light, blue light emitted from the light-emitting element can be extracted. In a subpixel exhibiting red light and a subpixel exhibiting green light, by providing a color conversion layer as the layer 764 illustrated in FIG. 31D, blue light emitted from the light-emitting element can be converted into light with a longer wavelength and thus red light or green light can be extracted. As the layer 764, both a color conversion layer and a coloring layer are preferably used. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

In FIG. 31C and FIG. 31D, light-emitting substances emitting light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. The light-emitting element with a single structure preferably includes a light-emitting layer containing a light-emitting substance emitting blue light and a light-emitting layer containing a light-emitting substance emitting visible light having a longer wavelength than blue light, for example.

A color filter may be provided as the layer 764 illustrated in FIG. 31D. When white light passes through the color filter, light of a desired color can be obtained.

In the case where the light-emitting element with a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB from an anode side or RBG from an anode side, for example. In that case, a buffer layer may be provided between R and G or between R and B.

For example, in the case where the light-emitting element with a single structure includes two light-emitting layers, the light-emitting device preferably includes a light-emitting layer containing a light-emitting substance that emits blue (B) light and a light-emitting layer containing a light-emitting substance that emits yellow (Y) light. Such a structure may be referred to as a BY single structure.

The light-emitting element that emits white light preferably contains two or more kinds of light-emitting substances. To obtain white light emission, two or more light-emitting substances may be selected such that their emission colors are complementary colors. For example, when an emission color of a first light-emitting layer and an emission color of a second light-emitting layer are complementary colors, the light-emitting element can be configured to emit white light as a whole. The same applies to a light-emitting element including three or more light-emitting layers.

Also in FIG. 31C and FIG. 31D, the layer 780 and the layer 790 may each independently have a stacked-layer structure of two or more layers as illustrated in FIG. 31B.

In FIG. 31E and FIG. 31F, light-emitting substances emitting light of the same color, or moreover, the same light-emitting substance may be used for the light-emitting layer 771 and the light-emitting layer 772. For example, in light-emitting elements included in subpixels emitting light of different colors, a light-emitting substance that emits blue light may be used for each of the light-emitting layer 771 and the light-emitting layer 772. In a subpixel exhibiting blue light, blue light emitted from the light-emitting element can be extracted. In the subpixel exhibiting red light and the subpixel exhibiting green light, by providing a color conversion layer as the layer 764 illustrated in FIG. 31F, blue light emitted from the light-emitting element can be converted into light with a longer wavelength and thus red light or green light can be extracted. As the layer 764, both a color conversion layer and a coloring layer are preferably used.

In the case where the light-emitting element having the structure illustrated in FIG. 31E or FIG. 31F is used for the subpixels emitting different colors, the subpixels may use different light-emitting substances. Specifically, in the light-emitting element included in the subpixel emitting red light, a light-emitting substance that emits red light can be used for each of the light-emitting layer 771 and the light-emitting layer 772. Similarly, in the light-emitting element included in the subpixel emitting green light, a light-emitting substance that emits green light can be used for each of the light-emitting layer 771 and the light-emitting layer 772. In the light-emitting element included in the subpixel emitting blue light, a light-emitting substance that emits blue light can be used for each of the light-emitting layer 771 and the light-emitting layer 772. A display device with such a structure includes a light-emitting element with a tandem structure and can be regarded as having an SBS structure. Thus, the display device can take advantages of both the tandem structure and the SBS structure. Accordingly, a light-emitting element being capable of high-luminance light emission and having high reliability can be obtained.

In FIG. 31E and FIG. 31F, light-emitting substances emitting light of different colors may be used for the light-emitting layer 771 and the light-emitting layer 772. White light emission can be obtained when the light-emitting layer 771 and the light-emitting layer 772 emit light of complementary colors. A color filter may be provided as the layer 764 illustrated in FIG. 31F. When white light passes through the color filter, light of a desired color can be obtained.

Although FIG. 31E and FIG. 31F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 31E and FIG. 31F illustrate the light-emitting element including two light-emitting units, one embodiment of the present invention is not limited thereto. The light-emitting element may include three or more light-emitting units. Note that a structure including two light-emitting units and a structure including three light-emitting units may be referred to as a two-unit tandem structure and a three-unit tandem structure, respectively.

In FIG. 31E and FIG. 31F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer overthe electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing a light-emitting element having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

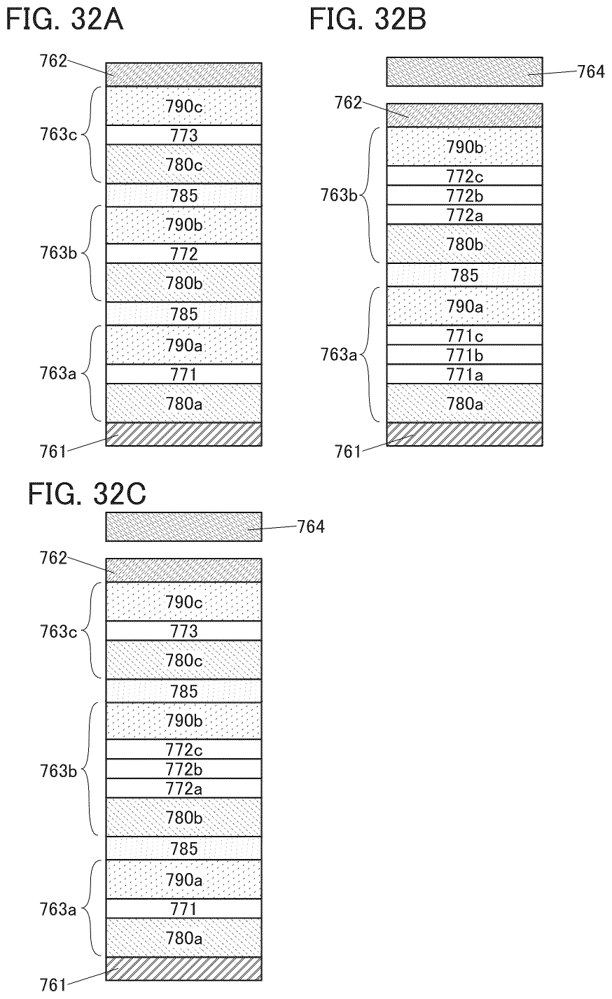

Structures illustrated in FIG. 32A to FIG. 32C can be given as examples of the light-emitting element with a tandem structure.

FIG. 32A illustrates a structure including three light-emitting units. In FIG. 32A, a plurality of light-emitting units (the light-emitting unit 763a, the light-emitting unit 763b, and a light-emitting unit 763c) are each connected in series through charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 32A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a light-emitting substance that emits red (R) light (a so-called R\R\R three-unit tandem structure); the light-emitting layer 771, the light-emitting layer 772, and the light-emitting layer 773 can each contain a light-emitting substance that emits green (G) light (a so-called a G\G\G three-unit tandem structure); or the light-emitting layer 771, the light-emitting layer 772, and the light-emitting layer 773 can each contain a light-emitting substance that emits blue (B) light (a so-called B\B\B three-unit tandem structure). Note that “a∛b” means that a light-emitting unit containing a light-emitting substance that emits light of b is provided over a light-emitting unit containing a light-emitting substance that emits light of a with a charge-generation layer therebetween, where a and b represent colors.

In FIG. 32A, light-emitting substances emitting light of different colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure of the light-emitting unit is not limited to the structure illustrated in FIG. 32A. For example, a light-emitting element with a tandem structure may be employed in which light-emitting units each including a plurality of light-emitting layers are stacked as illustrated in FIG. 32B. FIG. 32B illustrates a structure in which two light-emitting units (the light-emitting unit 763a and the light-emitting unit 763b) are connected in series with the charge-generation layer 785 therebetween. The light-emitting unit 763a includes the layer 780a, alight-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 32B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 32B is a two-unit tandem structure of W\W. Note that there is no particular limitation on the stacking order of the light-emitting substances having complementary emission colors. The practitioner can select the optimal stacking order as appropriate. Although not illustrated, a three-unit tandem structure of W\W\W or a tandem structure with four or more units may be employed.

In the case where the light-emitting element with a tandem structure is used, the following structure can be given: a B\Y or Y\B two-unit tandem structure including a light-emitting unit that emits yellow (Y) light and a light-emitting unit that emits blue (B) light; an R×G\B or B\R×G two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order, for example. Note that “a\b” means that one light-emitting unit contains a light-emitting substance that emits light of a and a light-emitting substance that emits light of b.

As illustrated in FIG. 32C, a light-emitting unit including one light-emitting layer and a light-emitting unit including a plurality of light-emitting layers may be used in combination.

in the structure illustrated in FIG. 32C, a plurality of light-emitting units (the light-emitting unit 763a, the light-emitting unit 763b, and the light-emitting unit 763c) are each connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 32C, for example, a three-unit tandem structure of BR×G×YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of the stacked light-emitting units and the order of colors from the anode side include a two-unit structure of B and Y, a two-unit structure of B and the light-emitting unit X, a three-unit structure of B, Y, and B, and a three-unit structure of B, X, and B. Examples of the number of layers stacked in the light-emitting unit X and the order of colors from the anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting element are described.

A conductive film transmitting visible light is used for the electrode through which light is extracted, which is either the lower electrode 761 or the upper electrode 762. A conductive film reflecting visible light is preferably used for the electrode through which light is not extracted. In the case where a display device includes a light-emitting element that emits infrared light, it is preferable that a conductive film that transmits visible light and infrared light be used for the electrode through which light is extracted and a conductive film that reflects visible light and infrared light be used for the electrode through which light is not extracted.

A conductive film that transmits visible light may be used also for the electrode through which light is not extracted. In that case, the electrode is preferably placed between a reflective layer and the EL layer 763. In other words, light emitted from the EL layer 763 may be reflected by the reflective layer to be extracted from the display device.

As a material that forms the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide, indium tin oxide containing silicon, indium zinc oxide, and indium zinc oxide containing tungsten. Other examples of the material include an aluminum-containing alloy such as an alloy of aluminum, nickel, and lanthanum (Al—Ni—La), an alloy of silver and magnesium, and an alloy containing silver such as an alloy of silver, palladium, and copper (APC). Other example of the material include elements belonging to Group 1 or Group 2 of the periodic table, which are not exemplified above (e.g., lithium, cesium, calcium, or strontium), rare earth metals such as europium and ytterbium, an alloy containing any of these metals in appropriate combination, and graphene.

In addition, the light-emitting element preferably also employs a microcavity structure. Therefore, one of the pair of electrodes included in the light-emitting element preferably includes an electrode having properties of transmitting and reflecting visible light (a transflective electrode), and the other preferably includes an electrode having a visible-light-reflecting property (a reflective electrode). When the light-emitting element has a microcavity structure, light obtained from the light-emitting layer can be resonated between the electrodes, whereby light emitted from the light-emitting element can be intensified.

Note that the transflective electrode can have a stacked-layer structure of a conductive layer that can be used as a reflective electrode and a conductive layer that can be used as an electrode having a visible-light-transmitting property (also referred to as a transparent electrode), for example.

The transparent electrode has a light transmittance higher than or equal to 40%. For example, an electrode having a visible light (light with a wavelength greater than or equal to 400 nm and less than 750 nm) transmittance higher than or equal to 40% is preferably used as the transparent electrode of the light-emitting element. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity of 1×10⁻² Ωcm or lower.

The light-emitting element includes at least the light-emitting layer. In addition, the light-emitting element may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting element can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting element, and an inorganic compound may also be contained. Each layer included in the light-emitting element can be formed by any of the following methods: an evaporation method (including a vacuum evaporation method), a transfer method, a printing method, an ink-jet method, a coating method, and the like.

The light-emitting layer contains one or more kinds of light-emitting substances. As the light-emitting substance, a substance exhibiting an emission color of blue, violet, bluish violet, green, yellowish green, yellow, orange, red, or the like is used as appropriate. Alternatively, a substance that emits near-infrared light can be used as the light-emitting substance.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property that can be used for the hole-transport layer and will be described later. As the electron-transport material, it is possible to use a material with a high electron-transport property that can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination is selected to form an exciplex that exhibits light emission whose wavelength overlaps with the wavelength of the lowest-energy-side absorption band of the light-emitting substance, energy can be transferred smoothly and light emission can be obtained efficiently. With this structure, the high efficiency, low-voltage driving, and long lifetime of the light-emitting element can be achieved at the same time.

The hole-injection layer is a layer injecting holes from an anode to a hole-transport layer and containing a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property that can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material with a high hole-injection property, a material that contains a hole-transport material and the above-described oxide of a metal belonging to any of Group 4 to Group 8 of the periodic table (typically, molybdenum oxide) may be used, for example.

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a material with a high hole-transport property, such as a π-electron rich heteroaromatic compound (e.g., a carbazole derivative, a thiophene derivative, or a furan derivative) or an aromatic amine (a compound having an aromatic amine skeleton), is preferable.

The electron-blocking layer is provided in contact with the light-emitting layer. The electron-blocking layer is a layer having a hole-transport property and containing a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, any of the following materials with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer is a layer having an electron-transport property and containing a material that can block holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer and containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The difference between the LUMO level of the material with a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, whereXis a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material that can be used for the above-described hole-injection layer.

The charge-generation layer preferably includes a layer containing a material with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer containing a material with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can suppress an increase in driving voltage.

At least part of the structure examples, the drawings corresponding thereto, and the like described in this embodiment can be combined with the other structure examples, the other drawings, and the like as appropriate.

At least part of this embodiment can be implemented in appropriate combination with the other embodiments described in this specification.

### REFERENCE NUMERALS

10: electronic device, 11a: substrate, 11b: substrate, 12a: layer, 12b: layer, 13a: substrate, 13b: substrate, 14: adhesive layer, 15: substrate, 16: substrate, 27a: pixel, 27b: pixel, 27: pixel, 31: housing, 32: fixing unit, 34a: light, 34aB: light, 34aG: light, 34aR: light, 34b: light, 34bB: light, 34bG: light, 34bR: light, 34c: light, 34: light, 35L: lens, 35R: lens, 35: lens, 36L: frame, 36R: frame, 36: frame, 37a: display portion, 37aL: display portion, 37aR: display portion, 37b: display portion, 37bL: display portion, 37bR: display portion, 37c: display portion, 37L: display portion, 37R: display portion, 37: display portion, 40: layer, 41a: display device, 41aL: display device, 41aR: display device, 41b: display device, 41bL: display device, 41bR: display device, 42a: gate driver circuit, 42aL: gate driver circuit, 42aR: gate driver circuit, 42b: gate driver circuit, 42bL: gate driver circuit, 42bR: gate driver circuit, 43a: source driver circuit, 43aL: source driver circuit, 43aR: source driver circuit, 43b: source driver circuit, 43bL: source driver circuit, 43bR: source driver circuit, 44: light, 47L: region, 47R: region, 47: region, 50: layer, 51: pixel circuit, 57: communication circuit, 59: control circuit, 60: layer, 61B: light-emitting element, 61G: light-emitting element, 61R: light-emitting element, 61W: light-emitting element, 61: light-emitting element, 63B: light-emitting element, 63G: light-emitting element, 63R: light-emitting element, 63W: light-emitting element, 63: light-emitting element, 100A: display device, 100B: display device, 100C: display device, 100D: display device, 100E: display device, 100F: display device, 100G: display device, 100H: display device, 100I: display device, 100J: display device, 100K: display device, 100L: display device, 100M: display device, 107: display portion, 109: pixel, 110a: subpixel, 110b: subpixel, 110c: subpixel, 110d: subpixel, 110e: subpixel, 117: light-blocking layer, 120: substrate, 122: adhesive layer, 124a: pixel, 124b: pixel, 140: connection portion, 153: insulating layer, 156: adhesive layer, 162: insulating layer, 164: circuit, 165: wiring, 166: conductive layer, 168: conductive layer, 171: conductive layer, 172B: EL layer, 172Bf: EL film, 172G: EL layer, 172Gf: EL film, 172R: EL layer, 172Rf: EL film, 172W: EL layer, 172: EL layer, 173: conductive layer, 174: common layer, 176: IC, 177: FPC, 180B: resist mask, 180G: resist mask, 180R: resist mask, 181B: FMM, 181G: FMM, 181R: FMM, 181: FMM, 183B: coloring layer, 183G: coloring layer, 183R: coloring layer, 183: coloring layer, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 270B: sacrificial layer, 270Bf: sacrificial film, 270G: sacrificial layer, 270Gf: sacrificial film, 270R: sacrificial layer, 270Rf: sacrificial film, 270: sacrificial layer, 271f: protective film, 271: protective layer, 272: insulating layer, 273: protective layer, 274a: conductive layer, 274b: conductive layer, 274: plug, 275: plug, 276: insulating layer, 277: microlens array, 278f insulating film, 278: insulating layer, 279B: sacrificial layer, 279Bf: sacrificial film, 279G: sacrificial layer, 279Gf sacrificial film, 279R: sacrificial layer, 279Rf: sacrificial film, 280: display module, 290: FPC, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 363: layer, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer

1. An electronic device comprising:
a first display device and a second display device,
wherein the first display device comprises a first display portion,
wherein the second display device comprises a second display portion,
wherein a plurality of first pixels are arranged in the first display portion,
wherein a plurality of second pixels are arranged in the second display portion,
wherein the first display device overlaps with the second display device,
wherein the second display portion is provided to surround at least part of the first display portion in a plan view, and
wherein an area occupied by each of the first pixels is smaller than an area occupied by each of the second pixels.

2. An electronic device comprising:
a first display device and a second display device,
wherein the first display device comprises a first substrate, a first display portion over the first substrate, and a second substrate over the first display portion,
wherein the second display device comprises a third substrate, a second display portion over the third substrate, and a fourth substrate over the second display portion,
wherein a plurality of first pixels are arranged in the first display portion,
wherein a plurality of second pixels are arranged in the second display portion,
wherein the second substrate overlaps with the third substrate,
wherein the second substrate, the third substrate, and the fourth substrate transmit light emitted from the first pixel,
wherein the second display portion is provided to surround at least part of the first display portion in a plan view, and
wherein an area occupied by each of the first pixels is smaller than an area occupied by each of the second pixels.

3. The electronic device according to claim 2,
wherein the first substrate is a semiconductor substrate.

4. The electronic device according to claim 2,
wherein a thickness of the third substrate is smaller than a thickness of the first substrate.

5. The electronic device according to claim 2,
wherein the third substrate has flexibility.

6. The electronic device according to claim 2,
wherein an adhesive layer is provided between the second substrate and the third substrate.

7. The electronic device according to claim 1,
wherein the second display portion includes a region not overlapping with the first display portion.

8. The electronic device according to claim 1,
wherein the second display device further comprises a third display portion,
wherein the third display portion overlaps with the first display portion, and
wherein the third display portion transmits light emitted from the first pixel.

9. The electronic device according to claim 1,
wherein the electronic device further comprises a communication circuit, a control circuit, a first source driver circuit, and a second source driver circuit,
wherein the first source driver circuit is electrically connected to the first pixel,
wherein the second source driver circuit is electrically connected to the second pixel,
wherein the communication circuit is configured to receive image data, and
wherein the control circuit is configured to generate first data representing luminance of light emitted from the first pixel and second data representing luminance of light emitted from the second pixel in accordance with the image data, and to supply the first data to the first source driver circuit and the second data to the second source driver circuit.

10. The electronic device according to claim 1,
wherein the first pixel comprises a first light-emitting element,
wherein the second pixel comprises a second light-emitting element,
wherein the first light-emitting element comprises a first pixel electrode and a first EL layer over the first pixel electrode,
wherein the first EL layer covers an end portion of the first pixel electrode,
wherein the second light-emitting element comprises a second pixel electrode and a second EL layer over the second pixel electrode, and
wherein an insulating layer covering an end portion of the second pixel electrode is provided between the second pixel electrode and the second EL layer.

11. The electronic device according to claim 2,
wherein the second display portion includes a region not overlapping with the first display portion.

12. The electronic device according to claim 2,
wherein the second display device further comprises a third display portion,
wherein the third display portion overlaps with the first display portion, and
wherein the third display portion transmits light emitted from the first pixel.

13. The electronic device according to claim 2,
wherein the electronic device further comprises a communication circuit, a control circuit, a first source driver circuit, and a second source driver circuit,
wherein the first source driver circuit is electrically connected to the first pixel,
wherein the second source driver circuit is electrically connected to the second pixel,
wherein the communication circuit is configured to receive image data, and
wherein the control circuit is configured to generate first data representing luminance of light emitted from the first pixel and second data representing luminance of light emitted from the second pixel in accordance with the image data, and to supply the first data to the first source driver circuit and the second data to the second source driver circuit.

14. The electronic device according to claim 2,
wherein the first pixel comprises a first light-emitting element,
wherein the second pixel comprises a second light-emitting element,
wherein the first light-emitting element comprises a first pixel electrode and a first EL layer over the first pixel electrode,
wherein the first EL layer covers an end portion of the first pixel electrode,
wherein the second light-emitting element comprises a second pixel electrode and a second EL layer over the second pixel electrode, and
wherein an insulating layer covering an end portion of the second pixel electrode is provided between the second pixel electrode and the second EL layer.
